(19) United States
(12) Patent Application Publication
(10) Pub. No.: US 2014/0312335 A1
(43) Pub. Date: Oct. 23, 2014

(54) MANUFACTURING METHOD OF ORGANIC SEMICONDUCTOR ELEMENT, ORGANIC SEMICONDUCTOR ELEMENT, GROWTH METHOD OF ORGANIC SINGLE CRYSTAL THIN FILM, ORGANIC SINGLE CRYSTAL THIN FILM, ELECTRONIC DEVICE, AND ORGANIC SINGLE CRYSTAL THIN FILM GROUP

(71) Applicant: Sony Corporation, Tokyo (JP)

(72) Inventors: Osamu Goto, Kanagawa (JP); Daisuke Hobara, Kanagawa (JP); Yosuke Murakami, Kanagawa (JP)

(73) Assignee: Sony Corporation, Tokyo (JP)

(21) Appl. No.: 14/354,069

(22) PCT Filed: Oct. 25, 2012
(86) PCT No.: PCT/JP2012/077633

§ 371 Date: Apr. 24, 2014

(30) Foreign Application Priority Data
Nov. 4, 2011 (JP) 2011-242460
Jan. 19, 2012 (JP) 2012-008666

(51) Int. Cl. H01L 51/00; H01L 51/42; H01L 51/50; H01L 51/05

(52) U.S. Cl. CPC H01L 51/0003; H01L 51/0558; H01L 51/42; H01L 51/50
USPC 257/40; 438/99

(57) ABSTRACT

Provided is a manufacturing method of an organic semiconductor element, the method including supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and allowing an organic semiconductor single crystal thin film composed of the organic compound to grow by evaporating the solvent of the organic solution.

### TECHNICAL FIELD

The present disclosure relates to a manufacturing method of an organic semiconductor element, an organic semiconductor element, a growth method of an organic single crystal thin film, an organic single crystal thin film, an electronic device, and an organic single crystal thin film group.

### BACKGROUND ART

Recent years, research and development of organic semiconductor elements is being widely conducted using organic semiconductor crystal thin films. It is important for the organic semiconductor elements to control the position, dimensions, crystal orientation and the like of the organic semiconductor crystal thin films.

Conventionally, the following method has been proposed for a growth method of an organic semiconductor crystal thin film (see Non-Patent Literature 1). Namely, a silicon piece which is a barrage is provided on an impurity-doped silicon substrate on whose surface a SiO₂ film is formed. A droplet composed of a raw material solution containing a [1]benzothieno[3,2-b]benzothiophene derivative (C₈-BTBT) is held on the lower edge of the silicon piece in a state where the silicon substrate inclines relative to the horizontal plane. Then, the droplet is being dried, and thereby, an organic semiconductor crystal thin film composed of C₈-BTBT is allowed to grow on the silicon substrate toward the upper side of the droplet from the lower side thereof. It is reported that this organic semiconductor crystal thin film attains high electron mobility (5 cm²/Vs).

### CITATION LIST

### Patent Literature

Patent Literature 1: JP 2010-6794A

### Non-Patent Literature

Non-Patent Literature 1: T. Uemura, Y. Hirose, M. Uno, K. Takimiya and J. Takeya: Applied Physics Express 2 (2009)111501

Non-Patent Literature 2: N. Kobayashi, M. Sasaki and K. Nomoto: Chem. Mater. 21 (2009)552

### SUMMARY OF INVENTION

### Technical Problem

However, the conventional growth method of an organic semiconductor crystal thin film proposed in Non-Patent Literature 1 has a demerit of incapability of controlling the position, dimensions and crystal orientation at all.

Therefore, a problem to be solved according to the present disclosure is to provide a growth method of an organic single crystal thin film and an organic single crystal thin film, the method being capable of controlling the position, dimensions, crystal orientation and the like of various kinds of organic single crystal thin films such as an organic semiconductor single crystal thin film.

Another problem to be solved according to the present disclosure is to provide a manufacturing method of an organic semiconductor element using the above-mentioned growth method of an organic single crystal thin film, and an organic semiconductor element using an organic semiconductor single crystal thin film allowed to grow by the growth method.

Still another problem to be solved according to the present disclosure is to provide an electronic device using the above-mentioned organic semiconductor element.

Still another problem to be solved according to the present disclosure is to provide an organic single crystal thin film group in which the crystal orientations of various kinds of organic single crystal thin films such as organic semiconductor single crystal thin films coincide with one another.

### Solution to Problem

In order to solve the above-mentioned issues, the present disclosure provides a manufacturing method of an organic semiconductor element, including a step of supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and a step of allowing an organic semiconductor single crystal thin film composed of the organic compound to grow by evaporating the solvent of the organic solution.

Further, the present disclosure provides an organic semiconductor element manufactured by supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and allowing an organic compound single crystal thin film composed of the organic semiconductor to grow by evaporating the solvent of the organic solution.

Further, the present disclosure provides electronic device having an organic semiconductor element manufactured by supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and allowing an organic semiconductor single crystal thin film composed of the organic compound to grow by evaporating the solvent of the organic solution.

In the above-mentioned manufacturing method of an organic semiconductor element, organic semiconductor element and electronic device, typically, by evaporating the solvent of the organic solution, the state of the organic solution is configured as the metastable region between the solubility curve and the supersolubility curve in the solubility-supersolubility diagram of the organic solution in the growth control region (or the growth region) and the state of the organic solution is configured as the unstable region on the lower side of the supersolubility curve in the solubility-supersolubility diagram in the nucleation control region (or the crystal nuclei forming region). Namely, the organic solution immediately after supplied to the growth control region and the nucleation control region is in the stable region on the upper side of the solubility curve in the solubility-supersolubility diagram. During the process of evaporating the solvent of the organic solution, the state of the organic solution is configured as the metastable region between the solubility curve and the supersolubility curve in the growth control region and the state of the organic solution is configured as the unstable region on the lower side of the supersolubility curve in the nucleation control region. Such states can be easily attained by selecting the area of the nucleation control region to be sufficiently smaller compared with the area of the growth control region. Namely, since the amount of the organic solution retained in the nucleation control region is sufficiently smaller compared with the amount of the organic solution retained in the growth control region, the evaporation rate of the solvent from the organic solution retained in the nucleation control region is sufficiently larger compared with the evaporation rate of the solvent from the organic solution retained in the growth control region. Therefore, the state of the organic solution comes to the unstable region in the nucleation control region due to the concentration increasing along with the rapid evaporation of the solvent. Meanwhile, simultaneously in the growth control region, the state of the organic solution can be allowed to come to the metastable region due to the increase of the concentration being slow along with the slow evaporation of the solvent. In this case, the nucleation from the organic solution can be allowed to take place only in the nucleation control region in which the state of the organic solution is in the unstable region. At this stage, a number of crystal nuclei of the organic compound are formed in the organic solution on the nucleation control region. Eventually, only one crystal having grown from the crystal nuclei formed due to the nucleation from the organic solution in the nucleation control region closes the nucleation control region. Then, originating from this crystal, a crystal grows on the growth control region, and thereby, a crystal with a single domain (single crystal) is allowed to grow. Thus, the organic semiconductor single crystal thin film has grown on the growth control region. In this case, typically, the organic solution is held at a constant temperature, for example, of 15° C. or more and 20° C. or less but not necessarily limited to the above.

Generally, the lower the temperature of the organic solution is, the more the evaporation of the solvent is suppressed. Therefore, the solute molecules, that is, molecules of the organic compound are tend to be sufficiently supplied to the crystal. Moreover, the lower the temperature of the organic solution is, the more the evaporation of the solvent is suppressed. Therefore, the degree of supersaturation on the surface of the organic solution hardly increases and the growth in the lateral direction is suppressed to the more extent. This allows the growth to proceed in the film thickness direction, causing the tendency of the film thickness of the organic semiconductor single crystal thin film being large.

Preferably, the growth control region and the nucleation control region have the lyophilic surfaces. Further preferably, the surface of the base body in the periphery of the growth control region and the nucleation control region has the lyophobic surface. Due to the above, when the organic solution is supplied to the growth control region and the nucleation control region, the organic solution can be retained securely only on the growth control region and the nucleation control region.

Typically, the nucleation control region has the first part in a straight line shape which is coupled with the growth control region and inclines by 90°±10° relative to the above-mentioned one side of the growth control region, or further has the second part in a straight line shape which is coupled with the first part and inclines relative to the above-mentioned one side. Or, the nucleation control region has the third part in a triangular shape which is coupled with the growth control region and has the first side on the above-mentioned one side and the fourth part in a straight line shape which is coupled with the third part and inclines relative to the above-mentioned one side. The first part inclines preferably by 90°±5°, still preferably by 90°±2°, most preferably by 90°±1°, relative to the one side of the growth control region. The second part inclines by 0° or more (or greater than 0°) and less than 90°, for example, 25° or more and 65° or less, preferably by 30° or more and 60° or less relative to the one side of the growth control region but is not limited to the above. The fourth part inclines by 0° or more (or greater than 0°) and 90° or less, for example, 25° or more and 65° or less, preferably by 30° or more and 60° or less relative to the one side of the growth control region but is not limited to the above. The angle between the second side and the third side of the third part is selected, for example, as an angle of a polygon defined by the crystal structure of the organic semiconductor single crystal thin film. The widths of the first part, the second part and the fourth part are generally 0.1 μm or more and 50 μm or less, preferably 1 μm or more and 50 μm or less, still preferably 1 μm or more and 30 μm or less, further preferably 1 μm or more and 20 μm or less or 1 μm or more and 10 μm or less but are not limited to the above. The shape of the growth control region is selected as needed and typically a rectangular or square shape.

Typically, the dimensions of the growth control region are selected sufficiently larger compared with the dimensions of the nucleation control region. For example, the growth control region typically has a rectangular shape with a length of the above-mentioned one side being 1000 μm or more and 10000 μm or less and a length of the other side being 100 μm or more and 800 μm or less, for example, sufficiently larger compared with the nucleation control region. In one typical example, the growth control region is a rectangle and the first part of the nucleation control region is a smaller rectangle than the growth control region which part is provided on one long side of the growth control region to be perpendicular to the long side.

In one typical example, the organic semiconductor single crystal thin film has a π-electron stacking structure in a direction substantially parallel to one principal plane of the base body. The organic semiconductor single crystal thin film has, for example, a triclinic, monoclinic, orthorhombic, or tetragonal crystal structure and has the above-mentioned π-electron stacking structure in the a-axis direction or the b-axis direction. In this case, the a-axis and the b-axis of the organic semiconductor single crystal thin film are parallel to the one principal plane of the base body. Typically, the organic semiconductor single crystal thin film grows such that its {110} plane is parallel to the above-mentioned first part, the second part, one side other than the first side of the third part or the fourth part. Moreover, the organic semiconductor single crystal thin film typically has a tetragonal or pentagonal shape having the first vertex with a vertical angle of 82° and the second vertex with a vertical angle of 98°. The second side and the third side of the third part are parallel to the {110} plane of the organic semiconductor single crystal thin film, for example.

Only one or a plurality of nucleation control regions may be provided on the one side of the growth control region. Moreover, only one or a plurality of growth control regions may be provided on the one principal plane of the base body to separate from one another. Preferably, when the plurality of growth control regions are provided to separate from one another, at least two growth control regions of these growth control regions are provided opposite to each other and a plurality of nucleation control regions are provided on each of sides of the two growth control regions which sides oppose each other not to overlap with one another.

The organic compound can employ various kinds of conventionally known ones and, for example, can employ the followings.

(1) polypyrrol and its derivatives
(2) polythiophene and its derivatives
(3) isothianaphthenes such as polyisothianaphthene
(4) thienylene vinylenes such as poly(thienylene vinylene)
(5) polymers with p-phenylene vinylenes such as poly(p-phenylene vinylene)
(6) polyaniline and its derivatives
(7) polyacetylenes
(8) polydiacetylenes
(9) polyazulenes
(10) polypyrenes
(11) polycarbazoles
(12) polyselenophenes
(13) polyfurans
(14) polymers with p-phenylenes
(15) polyindoles
(16) polypyridazines
(17) acenes such as naphthacene, pentacene, hexacene, heptacene, dibenzopentacene, tetrabenzopentacene, pyrene, dibenzopyrene, chrysene, perylene, coronene, terrylene, ovalene, quaterrylene and circumanthracene
(18) derivatives having an atom such as nitrogen, sulfur and oxygen or a functional group such as carbonyl group substituted for a part of carbons in acenes, for example, triphenodioxazine, triphenodiazine, hexacene-6,15-quinone and the like
(19) macromolecular materials such as polyvinylcarbazole, polyphenylenesulfide and polyvinylenesulfide and their polycyclic fused rings
(20) oligomers having repeating units same as those of the macromolecular materials in item (19)
(21) metal phthalocyanines
(22) tetrathiafulvalene and its derivatives
(23) tetrathiapentalene and its derivatives
(24) naphthalene-1,4,5,8-tetracarboxylic diimide, N,N′-bis(4-trifluoromethylbenzyl)naphthalene-1,4,5,8-tetracarboxylic diimide, N,N′-bis(1H,1H-perfluorooctyl), N,N′-bis(1H,1H-perfuluorobutyl) and N,N′-dioctylnaphthalene-1,4,5,8-tetracarboxylic diimide derivatives
(25) naphthalenetetracarboxylic diimides such as naphthalene-2,3,6,7-tetracarboxylic diimide
(26) fused-ring tetracarboxylic diimides represented by anthracenetetracarboxylic diimides such as anthracene-2,3,6,7-tetracarboxylic diimide
(27) dyes such as merocyanine dyes and hemicyanine dyes

Preferably, the organic compound employs aromatic compounds or their derivatives. The aromatic compounds are categorized into benzene-based aromatic compounds, heterocyclic aromatic compounds and non-benzene-based benzene-based aromatic compounds. The benzene-based aromatic compounds are fused-ring aromatic compounds, for example, benzo-fused-ring compounds and the like. The heterocyclic aromatic compounds are furan, thiophene, pyrrole, imidazole and the like, for example. The non-benzene-based aromatic compounds are annulene, azulene, cyclopentadienyl anion, cycloheptatrienyl cation (tropylium ion), tropone, metallocene, acepleiadylene and the like, for example.

Preferably, fused-ring compounds are used from among the above-mentioned aromatic compounds. Examples of the fused-ring compounds can include acenes (naphthalene, anthracene, tetracene, pentacene and the like), phenanthlene, chrysene, triphenylene, tetraphene, pyrene, picene, pentaphene, perylene, helicene, coronene and the like, whereas they are not limited to the above.

Preferably, the aromatic compounds also employ dioxaanthanthrene-based compounds such as 6,12-dioxaanthanthrene (so-called perixanthenoxanthene or 6,12-dioxaanthanthrene; sometimes abbreviated as “PXX”) (see Non-Patent Literature 2 and Patent Literature 1).

The organic semiconductor element may employ anything basically as long as it uses the organic semiconductor single crystal thin film. For example, examples thereof include an organic transistor, an organic photoelectric transducer and the like. One or two or more organic semiconductor single crystal thin films may be used for the organic semiconductor element and the two or more organic semiconductor single crystal thin films may include a same kind of those or different kinds of those. In the organic transistor, the organic semiconductor single crystal thin film is a semiconductor layer in which channels are formed, for example. In the organic photoelectric transducer, the organic semiconductor single crystal thin film is an organic photoelectric conversion layer. For example, for organic transistors, the crystal orientation of the organic semiconductor single crystal thin film is configured such that a direction of electrons traveling coincides with the direction high in mobility of carriers in the organic semiconductor single crystal thin film, and thereby, an organic transistor high in mobility can be attained. Moreover, for organic photoelectric transducers, the crystal orientation of the organic semiconductor single crystal thin film is configured to be in the direction of the polarization axis, and thereby, a polarization organic photoelectric transducer high in sensitivity to polarized light can be attained. The polarization organic photoelectric transducer can be used, for example, for a polarization organic imaging device, a ranging functional device and the like.

The electronic device may employ various kinds of electronic devices using one or two or more electronic elements such as organic semiconductor elements and may be either mobile or settled regardless of functions or purposes. Specific examples of the electronic device include a display such as a liquid crystal display and an organic electroluminescent display, a mobile phone, a mobile device, a personal computer, a game machine, in-car devices, home appliances, industrial products and the like. Moreover, the polarization organic photoelectric transducer is applied to various kinds of electronic devices using polarized light, for example, a three-dimensional camera using a polarization organic imaging device composed of polarization organic photoelectric transducers.

Further, the present disclosure provides a growth method of an organic single crystal thin film including supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and allowing an organic single crystal thin film composed of the organic compound to grow by evaporating the solvent of the organic solution.

Further, the present disclosure provides an organic single crystal thin film allowed to grow by supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and allowing the organic single crystal thin film composed of the organic compound to grow by evaporating the solvent of the organic solution.

Further, the present disclosure provides a growth method of an organic single crystal thin film including supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region, and closing the nucleation control region with only one crystal obtained by growth of a crystal nucleus formed due to nucleation from the organic solution in the nucleation control region by evaporating the solvent of the organic solution to allow the crystal to grow on the growth control region, and thereby, allowing an organic single crystal thin film composed of the organic compound to grow.

Further, the present disclosure provides an organic single crystal thin film group including a plurality of organic single crystal thin films which are allowed to grow on one principal plane of a base body and composed of an organic compound. Organic single crystal thin films not less than 17% and not more than 47% in terms of number among the organic single crystal thin film group have pentagonal shapes each having a first vertex with a vertical angle of 82° and a second vertex with a vertical angle of 98°. Organic single crystal thin films not less than 16% and not more than 41% in terms of number among the organic single crystal thin film group have tetragonal shapes each having the first vertex with the vertical angle of 82° and the second vertex with the vertical angle of 98°.

In the above-mentioned organic single crystal thin film, growth method of an organic single crystal thin film, and organic single crystal thin film group, examples of the organic single crystal thin film include not only the organic semiconductor single crystal thin film but also various kinds of organic single crystal thin films other than the organic semiconductor single crystal thin film, for example, an organic insulator single crystal thin film and the like. The organic compound forming the organic single crystal thin film is properly selected according to the kind of the organic single crystal thin film.

The above-mentioned organic single crystal thin film or organic semiconductor single crystal thin film can be used for various kinds of electronic elements. The electronic elements may employ anything basically as long as they use the organic single crystal thin film or the organic semiconductor single crystal thin film. The organic semiconductor element is one kind of those. The electronic element may include one or two or more other thin films such, for example, as an insulation film as well as one or two or more organic semiconductor single crystal thin films. The thin films may be either organic thin films or inorganic thin films. Moreover, a bioelectronic element can be attained by combining a biological material such as protein with the organic semiconductor single crystal thin film, for example.

In the above-mentioned organic single crystal thin film group, the organic single crystal thin film is typically allowed to grow by performing: the step of supplying the unsaturated organic solution obtained by dissolving the organic compound in the solvent onto the growth control region and the nucleation control region of the base body having the growth control region and at least one nucleation control region which is provided on the one side of the growth control region and is coupled with the growth control region on the one principal plane; and the step of allowing the organic single crystal thin film composed of the organic compound to grow by evaporating the solvent of the organic solution.

The description in relation to the above-mentioned manufacturing method of an organic semiconductor element and organic semiconductor element applies to the above-mentioned organic single crystal thin film, growth method of an organic single crystal thin film, and organic single crystal thin film group except the above as long as it is consistent with their nature.

### Advantageous Effects of Invention

According to the present disclosure, the position, dimensions, crystal orientation and the like of the organic semiconductor single crystal thin film or the organic single crystal thin film can be easily controlled. Using the organic semiconductor single crystal thin film or the organic single crystal thin film can attain a high-performance organic semiconductor element or electronic element. Using the organic semiconductor element or the electronic element can attain a high-performance electronic device.

### BRIEF DESCRIPTION OF DRAWINGS

FIG. 1 is a schematic diagram illustrating a solubility-supersolubility diagram regarding an organic solution used in a growth method of an organic semiconductor single crystal thin film according to a first embodiment.

FIG. 2 is a schematic diagram for explaining the growth method of an organic semiconductor single crystal thin film according to the first embodiment.

FIG. 3A, FIG. 3B and FIG. 3C are schematic diagrams for explaining the growth method of an organic semiconductor single crystal thin film according to the first embodiment.

FIG. 4A and FIG. 4B are schematic diagrams presenting a model of simulation performed for investigating a growth mechanism in the growth method of an organic semiconductor single crystal thin film according to the first embodiment.

FIG. 5A and FIG. 5B are schematic diagrams illustrating results of the simulation performed for investigating the growth mechanism in the growth method of an organic semiconductor single crystal thin film according to the first embodiment.

FIG. 6A, FIG. 6B and FIG. 6C are drawing substitute images presenting polarization microscope images of a matrix array of C₂Ph-PXX thin films having grown on a Si wafer and the C₂Ph-PXX thin films in typical shapes in Example 1.

FIG. 7A, FIG. 7B and FIG. 7C are drawing substitute images presenting limited visual field images of an electron beam diffraction pattern of the C₂Ph-PXX thin film having grown on the Si wafer and a schematic diagram illustrating a facet of the C₂Ph-PXX thin film in Example 1.

FIG. 8 is a schematic diagram illustrating a distribution in rotational angle of the C₂Ph-PXX thin films having grown into a matrix array shape on the Si wafer in Example 1, a comb-shape pattern having a width of comb tooth part being 5 μm.

FIG. 9 is a schematic diagram illustrating a distribution in rotational angle of the C₂Ph-PXX thin films having grown into a matrix array shape on the Si wafer in Example 1, a comb-shape pattern having a width of comb tooth part being 5 μm.

FIG. 10A and FIG. 10B are schematic diagrams for explaining a growth mechanism in the growth method of an organic semiconductor single crystal thin film according to the first embodiment.

FIG. 11A and FIG. 11B are schematic diagrams for explaining a growth mechanism in the growth method of an organic semiconductor single crystal thin film according to the first embodiment.

FIG. 12 is a schematic diagram for explaining a growth mechanism in the growth method of an organic semiconductor single crystal thin film according to the first embodiment.

FIG. 13 is a schematic diagram illustrating a film forming apparatus used for the growth method of an organic semiconductor single crystal thin film according to the first embodiment.

FIG. 14 is a schematic diagram illustrating a film forming apparatus used for the growth method of an organic semiconductor single crystal thin film according to the first embodiment.

FIG. 15 is a schematic diagram for explaining a growth method of an organic semiconductor single crystal thin film according to a second embodiment.

FIG. 16 is a schematic diagram for explaining a growth method of an organic semiconductor single crystal thin film according to a second embodiment.

FIG. 17 is a schematic diagram for explaining a growth method of an organic semiconductor single crystal thin film according to a second embodiment.

FIG. 18 is a schematic diagram for explaining a growth method of an organic semiconductor single crystal thin film according to a second embodiment.

FIG. 19 is a schematic diagram for explaining a method for allowing C₂Ph-PXX thin films to grow on the Si wafer in Example 2.

FIG. 20 is a drawing substitute image presenting a polarization microscope image of the C₂Ph-PXX thin films having grown on the Si wafer at 16° C. in Example 2.

FIG. 21 is a drawing substitute image presenting a polarization microscope image of the C₂Ph-PXX thin films having grown on the Si wafer at 18° C. in Example 2.

FIG. 22 is a drawing substitute image presenting a polarization microscope image of the C₂Ph-PXX thin films having grown on the Si wafer at 16° C. in Example 2.

FIG. 23 is a drawing substitute image presenting a polarization microscope image of the C₂Ph-PXX thin films having grown on the Si wafer at 16° C. in Example 2.

FIG. 24 is a drawing substitute image presenting a polarization microscope image of the C₂Ph-PXX thin films having grown on the Si wafer at 16° C. in Example 2.

FIG. 25 is a drawing substitute image presenting a polarization microscope image of the C₂Ph-PXX thin films having grown on the Si wafer at 16° C. in Example 2.

FIG. 26 is a drawing substitute image presenting a polarization microscope image of the C₂Ph-PXX thin films having grown on the Si wafer at 16° C. in Example 2.

FIG. 27 is a drawing substitute image presenting a polarization microscope image of the C₂Ph-PXX thin films having grown on the Si wafer at 16° C. in Example 2.

FIG. 28 is a drawing substitute image presenting a polarization microscope image of the C₂Ph-PXX thin films having grown on the Si wafer at 16° C. in Example 2.

FIG. 29 is a drawing substitute image presenting a polarization microscope image of the C₂Ph-PXX thin films having grown on the Si wafer at 16° C. in Example 2.

FIG. 30 is a drawing substitute image presenting a polarization microscope image of the C₂Ph-PXX thin films having grown on the Si wafer at 16° C. in Example 2.

FIG. 31 is a drawing substitute image presenting a polarization microscope image of the C₂Ph-PXX thin films having grown on the Si wafer at 16° C. in Example 2.

FIG. 32 is a drawing substitute image presenting a polarization microscope image of the C₂Ph-PXX thin films having grown on the Si wafer at 16° C. in Example 2.

FIG. 33 is a drawing substitute image presenting a polarization microscope image of the C₂Ph-PXX thin films having grown on the Si wafer at 16° C. in Example 2.

FIG. 34 is a drawing substitute image presenting a polarization microscope image of the C₂Ph-PXX thin films having grown on a basic pattern of W₂=10 μm on the Si wafer at 16° C. in Example 2.

FIG. 35 is a drawing substitute image presenting a polarization microscope image of the C₂Ph-PXX thin films having grown on a basic pattern of W₂=10 μm on the Si wafer at 16° C. in Example 2.

FIG. 36 is a drawing substitute image presenting a polarization microscope image of the C₂Ph-PXX thin films having grown on a basic pattern of W₂=10 μm on the Si wafer at 16° C. in Example 2.

FIG. 37 is a drawing substitute image presenting a polarization microscope image of one C₂Ph-PXX thin film having grown on the Si wafer at 16° C. in Example 2.

FIG. 38 is a drawing substitute image presenting a limited visual field image of an electron beam diffraction pattern of one C₂Ph-PXX thin film having grown on the Si wafer at 16° C. in Example 2.

FIG. 39 is a schematic diagram illustrating a π-electron stacking structure of C₂Ph-PXX.

FIG. 40A and FIG. 40B are schematic diagram for explaining a growth model of the organic semiconductor single crystal thin film.

FIG. 41A and FIG. 41B are schematic diagram for explaining a growth model of the organic semiconductor single crystal thin film.

FIG. 42 is a schematic diagram for explaining a growth method of an organic semiconductor single crystal thin film according to a third embodiment.

FIG. 43 is a schematic diagram for explaining a growth method of an organic semiconductor single crystal thin film according to a fourth embodiment.

FIG. 44 is a schematic diagram illustrating an organic transistor according to a fifth embodiment.

FIG. 45 is a schematic diagram illustrating a first example of a layered structure body according to a sixth embodiment.

FIG. 46 is a schematic diagram illustrating a second example of a layered structure body according to a sixth embodiment.

FIG. 47 is a schematic diagram illustrating a third example of a layered structure body according to a sixth embodiment.

FIG. 48 is a schematic diagram illustrating a fourth example of a layered structure body according to a sixth embodiment.

FIG. 49 is a schematic diagram illustrating a fifth example of a layered structure body according to a sixth embodiment.

FIG. 50 is a schematic diagram illustrating a sixth example of a layered structure body according to a sixth embodiment.

FIG. 51 is a schematic diagram illustrating a seventh example of a layered structure body according to a sixth embodiment.

FIG. 52 is a schematic diagram illustrating an eighth example of a layered structure body according to a sixth embodiment.

FIG. 53 is a schematic diagram illustrating a ninth example of a layered structure body according to a sixth embodiment.

FIG. 54A, FIG. 54B, and FIG. 54C are a schematic diagram for explaining a growth method of an organic semiconductor single crystal thin film according to a seventh embodiment.

FIG. 55A, FIG. 55BB, and FIG. 55C are a schematic diagram for explaining a growth method of an organic semiconductor single crystal thin film according to a seventh embodiment.

FIG. 56 is a drawing substitute image presenting a polarization microscope image of a C₂Ph-PXX thin film having grown due to a growth method of an organic semiconductor single crystal thin film according to an eighth embodiment.

FIG. 57A, FIG. 57B, FIG. 57C, FIG. 57D and FIG. 57E are drawing substitute images presenting the C₂Ph-PXX thin film actually allowed to grow due to the growth method of an organic semiconductor single crystal thin film according to the first embodiment in a time series.

FIG. 58 is a drawing substitute image for explaining a preparing method of an electron microscope observation sample in transmission electron microscope observation for studying a growth mechanism of an organic semiconductor single crystal thin film.

FIG. 59 is a drawing substitute image for explaining a preparing method of an electron microscope observation sample in transmission electron microscope observation for studying a growth mechanism of an organic semiconductor single crystal thin film.

FIG. 60 is a drawing substitute image presenting a cross-sectional transmission electron microscope image of the electron microscope observation sample.

FIG. 61A and FIG. 61B are drawing substitute images presenting a cross-sectional transmission electron microscope image of the electron microscope observation sample.

FIG. 62A and FIG. 62B are drawing substitute images presenting a cross-sectional transmission electron microscope image of the electron microscope observation sample.

FIG. 63A and FIG. 63B are drawing substitute images presenting a cross-sectional transmission electron microscope image of the electron microscope observation sample.

FIG. 64A and FIG. 64B are drawing substitute images presenting a cross-sectional transmission electron microscope image of the electron microscope observation sample.

FIG. 65 is a drawing substitute image presenting a cross-sectional transmission electron microscope image of the electron microscope observation sample.

FIG. 66 is a drawing substitute image presenting a cross-sectional transmission electron microscope image of the electron microscope observation sample.

FIG. 67 is a drawing substitute image presenting a cross-sectional transmission electron microscope image of the electron microscope observation sample.

FIG. 68A, FIG. 68B and FIG. 68C are drawing substitute images of a planer shape of a coupling part of a growth crystal with a transition region illustrated FIG. 58.

FIG. 69A, FIG. 69B, FIG. 69C, FIG. 69D and FIG. 69E are schematic diagrams for explaining a growth mechanism in the growth method of an organic semiconductor single crystal thin film according to the first embodiment.

FIG. 70A and FIG. 70B are a plan view and a cross-sectional view for explaining a method of draining an organic solution after the growth of the organic semiconductor single crystal thin films, respectively.

FIG. 71 is a drawing substitute image exemplarily presenting growth of two layers of C₂Ph-PXX thin films in their different crystal orientations from each other.

### DESCRIPTION OF EMBODIMENTS

Hereafter, modes for implementing the invention (hereinafter referred to as embodiments) will be described. Incidentally, the description is made in the following order.

### 1. First Embodiment (Growth Method of Organic Semiconductor Single Crystal Thin Film)

### 2. Second Embodiment (Growth Method of Organic Semiconductor Single Crystal Thin Film)

### 3. Third Embodiment (Growth Method of Organic Semiconductor Single Crystal Thin Film)

### 4. Fourth Embodiment (Growth Method of Organic Semiconductor Single Crystal Thin Film)

### 5. Fifth Embodiment (Organic Transistor and Manufacturing Method Thereof)

### 6. Sixth Embodiment (Layered Structure Body and Manufacturing Method Thereof)

### 7. Seventh Embodiment (Growth Method of Organic Semiconductor Single Crystal Thin Film)

### 8. Eighth Embodiment (Growth Method of Organic Semiconductor Single Crystal Thin Film)

### 1. First Embodiment

### Growth Method of Organic Semiconductor Single Crystal Thin Film

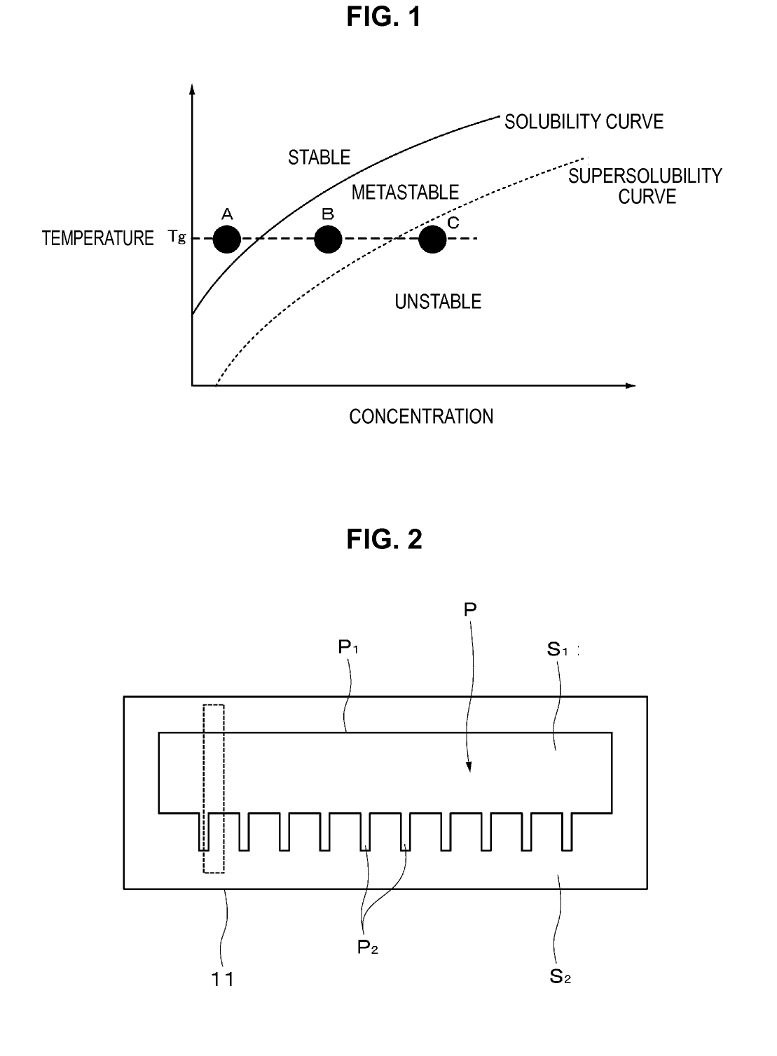

FIG. 1 illustrates a solubility-supersolubility diagram regarding an organic solution used in a growth method of an organic semiconductor single crystal thin film according to a first embodiment (solution obtained by dissolving an organic compound which is a raw material of an organic semiconductor single crystal thin film). As illustrated in FIG. 1, the state of the organic solution changes from the unsaturated region (stable region) on the upper side of the solubility curve to the supersaturated region on the lower side of the solubility curve as its temperature decreases and/or its concentration increases. In the stable region, spontaneous crystallization does not take place. The crystallization can proceed in the supersaturated region. The supersaturated region is divided into two regions. One region is the metastable region between the solubility curve and the supersolubility curve. In the metastable region, only the crystal growth takes place but the nucleation does not take place. The other region is the unstable region on the lower side of the supersolubility curve. In the unstable region, spontaneous crystallization can take place.

One example of the growth method of an organic semiconductor single crystal thin film is described based on FIG. 1. As illustrated in FIG. 2, on a substrate 11, a comb-shape pattern P having a surface S₁ which is lyophilic to an organic solution is formed. The comb-shape pattern P having the lyophilic surface S₁ is a region liable to be wet with an organic solution and has a property of fixing the organic solution thereon. The surface of the substrate 11 other than the comb-shape pattern P is configured to be a surface S₂ which is lyophobic to the organic solution. The region having the lyophobic surface S₂ is a region which is hardly wet with the organic solution and has a property of repelling the organic solution. The comb-shape pattern P is configured of a rectangular back part P₁ and a plurality of rectangular comb tooth parts P₂ which are provided at an interval along one long side of the back part P₁ to protrude in the direction perpendicular to the long side. The area of the back part P₁ is sufficiently large to the area of each comb tooth part P₂.

Here, when a droplet of the organic solution is placed on the comb-shape pattern P, the droplet stays on the lyophilic surface S₁ of the comb-shape pattern P but does not move onto the lyophobic surface S₂ outside the comb-shape pattern P. State transition of the droplet of the organic solution to the supersaturated region can be realized by increasing the concentration of the organic solution, taking advantage of evaporation of the solvent. The broken line ABC in FIG. 1 represents a method of performing the above-mentioned operation at a constant temperature T_{g} as one example. Rapid evaporation of the solvent is suppressed in the back part P₁ which has a large area and can retain a larger amount of the organic solution. The region of the back part P₁ is used as a growth control region (GCR). Meanwhile, the region of the comb tooth part P₂ is used as a nucleation control region (NCR). Since the area of the comb tooth part P₂ is sufficiently small relative to the area of the back part P₁, the amount of the organic solution on each comb tooth part P₂ is sufficiently small relative to the amount of the organic solution on the back part P₁. Hence, the evaporation rate of the solvent from each comb tooth part P₂, that is, nucleation control region is much larger relative to the evaporation rate of the solvent from the back part P₁, that is, growth control region. As above, the local degree of supersaturation in the droplet of the organic solution can be controlled in high accuracy, taking advantage of a large difference in evaporation rate of the solvent between a part of the organic solution on the back part P₁, that is, growth control region and a part of the organic solution on each comb tooth part P₂, that is, nucleation control region.

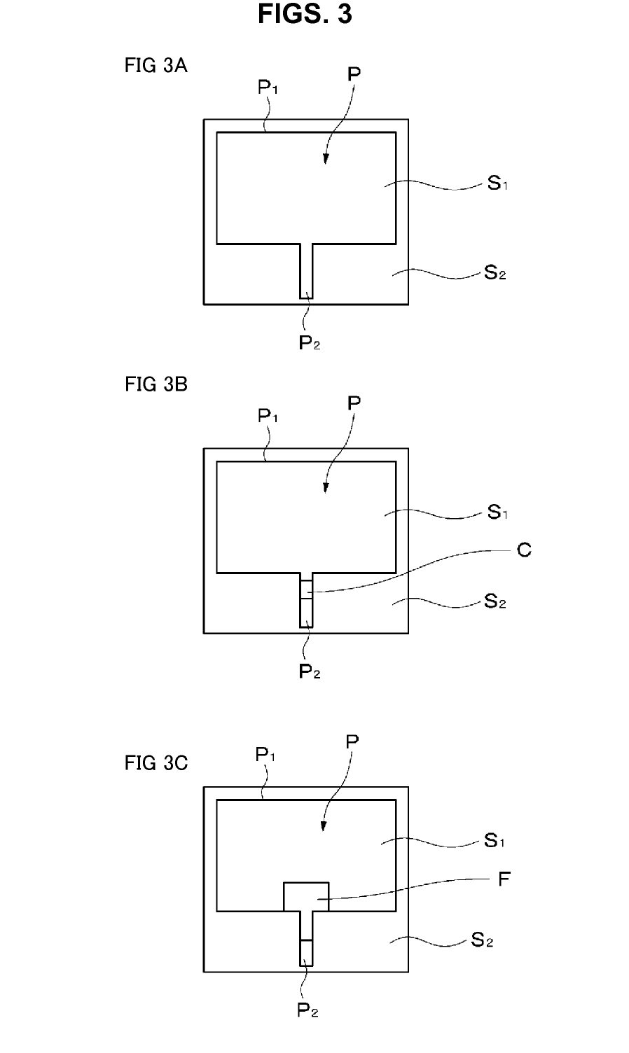

Referring to FIG. 3A, FIG. 3B and FIG. 3C, a growth model of an organic semiconductor single crystal thin film from an organic solution due to solution growth is described. FIG. 3A illustrates one comb tooth part P₂ and a part of the back part P₁ in the comb-shape pattern P. A droplet of an unsaturated organic solution is retained on the back part P₁ and the comb tooth part P₂. The organic solution in this state is in the stable state A of FIG. 1. Upon start of evaporation of the organic solution, since, relative to the part of the organic solution on the back part P₁, the part of the organic solution on the comb tooth part P₂ is faster in evaporation of the solvent, this leading to faster increase of the concentration of the organic solution, the part of the organic solution on the back part P₁ is to be in the metastable state B of FIG. 1. Meanwhile, the part of the organic solution on the comb tooth part P₂ is realized to be in a state of the unstable state C in FIG. 1. Namely, although the back part P₁ and the comb tooth part P₂ are adjacent to each other, the states of the organic solutions on them can be simultaneously configured to be different states from each other, being in the metastable state B for the back part P₁ and being in the unstable state C for the comb tooth part P₂. Spontaneous crystallization can take place on the comb tooth part P₂, that is, nucleation control region on which the organic solution is in the unstable state C and crystal nuclei can be formed in plural portions within the region on the comb tooth part P₂. Eventually, only one crystal C grows large enough to close the comb tooth part P₂ completely as illustrated in FIG. 3B. Then, as illustrated in FIG. 3C, an organic semiconductor single crystal thin film F grows on the back part P₁, that is, growth control region on which the organic solution is in the metastable state B, originating from this stable crystal C closing the comb tooth part P₂. As apprehended from the above, according to this method, it is understood that the organic semiconductor single crystal thin film F can be allowed to grow on the back part P₁, starting from the comb tooth part P₂. Namely, the position where the organic semiconductor single crystal thin film F is allowed to grow can be controlled in high accuracy.

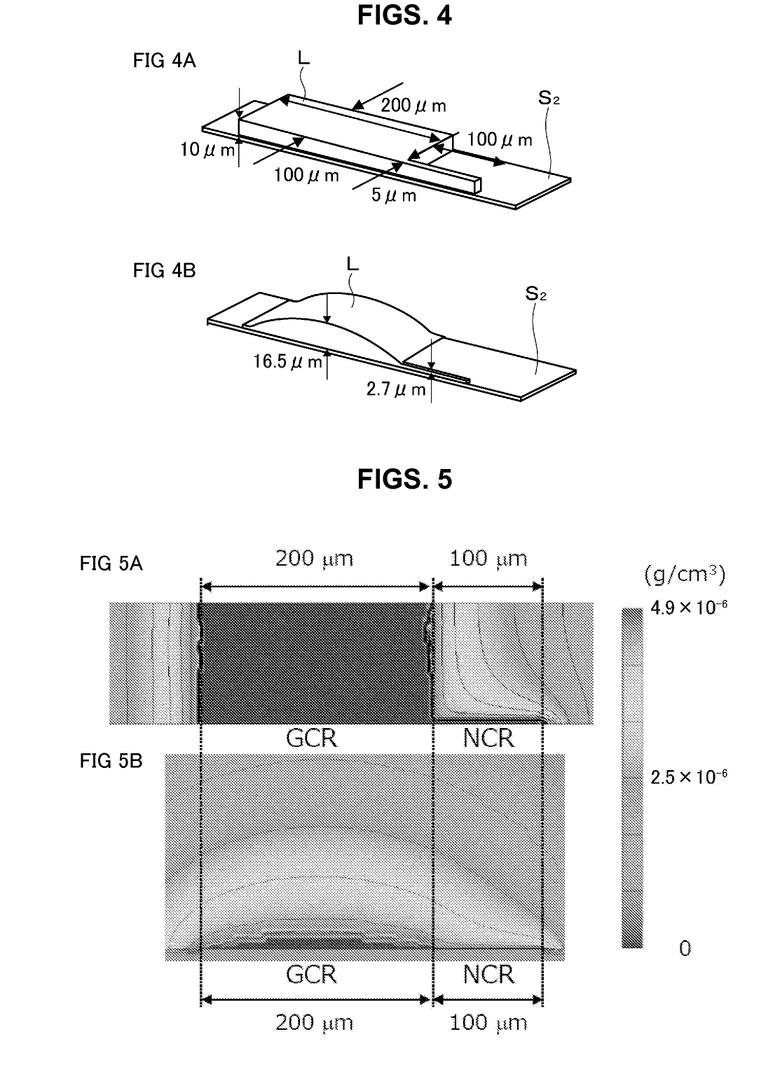

As to the rectangular region enclosed by broken lines illustrated in FIG. 2, simulation of the shape and the evaporation rate of a droplet of the organic solution based on computational fluid dynamics was performed in order to study behavior in evaporation of the solvent of the organic solution. To simplify the computation, the shape of a droplet of the solvent was computed using computational fluid dynamics (CFD) software FLOW-3D® in consideration of the surface tension and the contact angle of the solvent. The surface tension of the solvent was set to 35.9 mN/m. The contact angle θ of the solvent was obtained based on experiments to be 6 degrees on a lyophilic surface or to be 63 degrees on a lyophobic surface. Moreover, the viscosity of the solvent was set as t=0.01 Pa·s and the density thereof as ρ=1030 kg/m³. FIG. 4A and FIG. 4B schematically illustrate initial and final shapes of a droplet of the solvent on the comb-shape pattern P, respectively. The dimensions of those are illustrated in FIG. 4A and FIG. 4B. As illustrated in FIG. 4A, a droplet L of the solvent initially had a uniform thickness over the comb-shape pattern P (10 μm in this example). As illustrated in FIG. 4B, the droplet L of the solvent finally had a shape with a bulge in its center part on the back part P₁ due to the surface tension (hogback shape). The thickness of the droplet L of the solvent was 16.5 μm on the back part P₁, that is, growth control region or 2.7 μm on the comb tooth part P₂, that is, nucleation control region. Accordingly, it is understood that the amount of the solvent on the comb tooth part P₂, that is, nucleation control region was much smaller than the amount of the solvent on the back part P₁, that is, growth control region. The results lead to the evaporation rate of the solvent on the comb tooth part P₂, that is, nucleation control region being much larger than the evaporation rate of the solvent on the back part P₁, that is, growth control region.

The evaporation rate of the solvent is expressed by the following differential equation.

dw/dt=−C(P_{sat.}−P)

where w, C, P_{sat.}, P and t denote a mass of the solvent molecules, a constant factor, the saturated vapor pressure of the solvent, a vapor pressure of the solvent and time, respectively. FIG. 5A and FIG. 5B illustrate densities of the vapor of the solvent at a time point before the evaporation of the solvent on the comb tooth part P₂ finishes as calculation results. Here, the temperature is 20° C. FIG. 5A and FIG. 5B illustrate a distribution of the vapor densities of the solvent as seen above the comb-shape pattern P and a distribution of the vapor densities of the solvent in a cross section of the comb-shape pattern P, respectively. FIG. 5A and FIG. 5B also illustrate contours of the vapor densities. The spacing between the contours of the vapor densities is narrower as the slope is larger. Since the vapor pressure is nearly equal to the saturated vapor pressure on the surface of the solvent, the evaporation rate of the solvent on the comb tooth part P₂, that is, nucleation control region is faster than the evaporation rate of the solvent on the back part P₁, that is, growth control region. This is because the comb tooth part P₂ is not enclosed by the solvent and the diffusion rate of the evaporating solvent molecules is larger on the comb tooth part P₂ than on the back part P₁.

The above-mentioned simulation results provide a support for the transition from the stable state A to the unstable state C in FIG. 1 which transition takes place on the comb tooth part P₂ at first, allowing spontaneous crystallization. Moreover, not only the amount of the solvent but also the evaporation rate thereof lead to the large difference in evaporation of the solvent between the back part P₁, that is, growth control region and the comb tooth part P₂, that is, nucleation control region.

As an organic compound for a raw material of the organic semiconductor single crystal thin film, the ones that have been already mentioned can be employed, and among those, specific examples of the perixanthenoxanthene(PXX)-based compound are the followings.

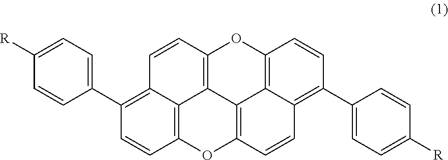

(where R is an alkyl group regardless of linear one or branched one)

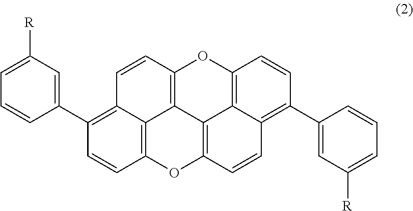

(where R is an alkyl group regardless of linear one or branched one)

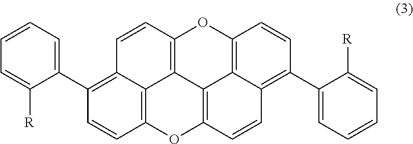

(where R is an alkyl group regardless of linear one or branched one)

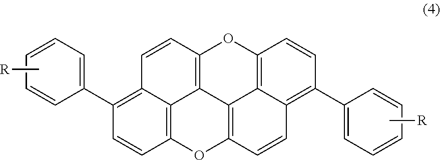

(where R is an alkyl group and the number of Rs is 2 to 5)

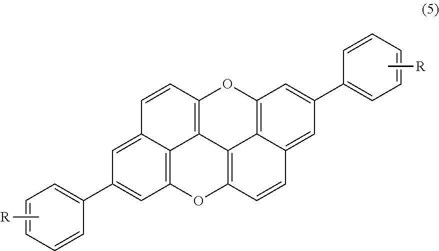

(where R is an alkyl group and the number of Rs is 1 to 5)

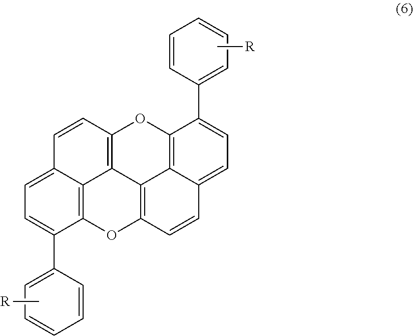

(where R is an alkyl group and the number of Rs is 1 to 5)

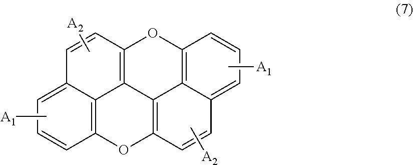

(where A₁ and A₂ are indicated by equation (8))

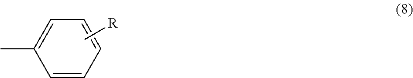

(where R is an alkyl group or another substituent and the number of Rs is 1 to 5)

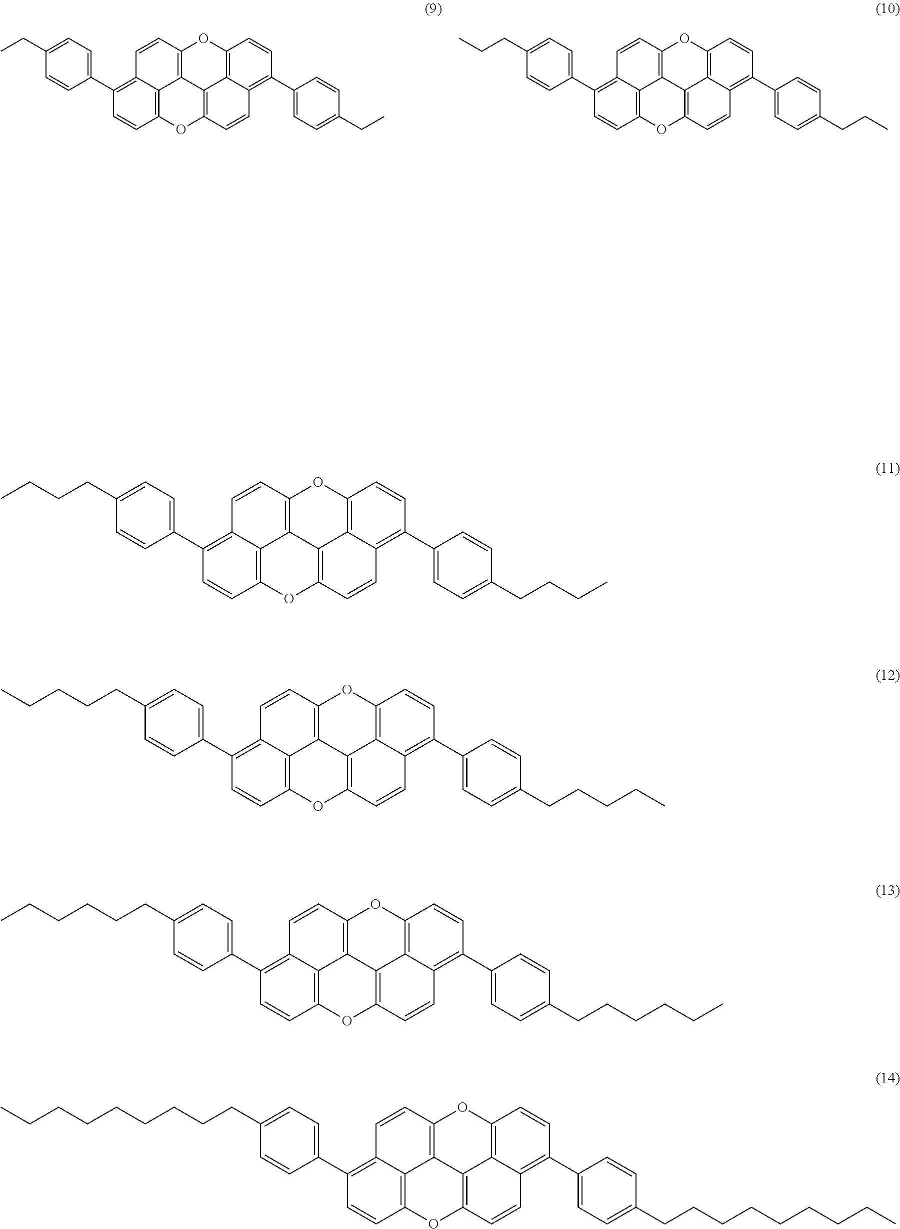

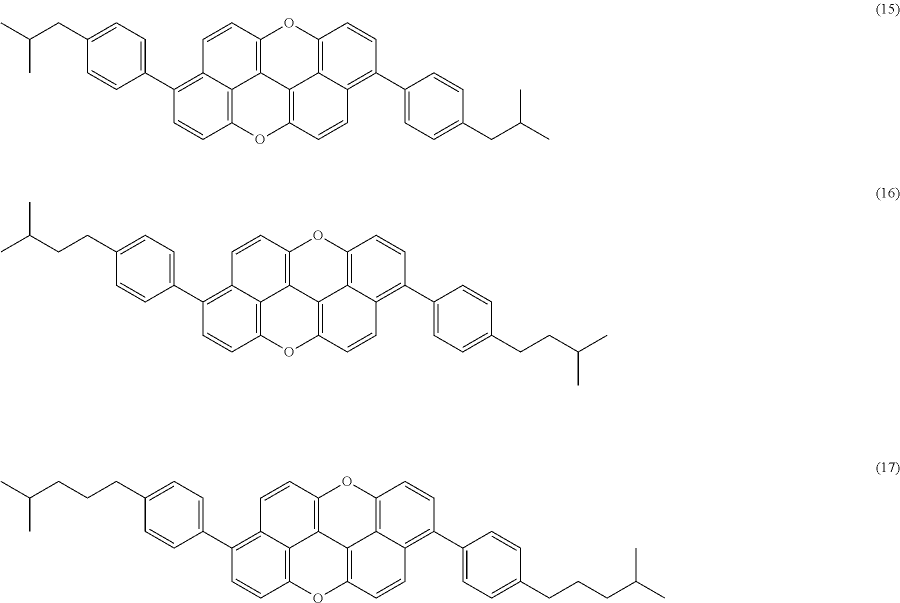

### Example 1

Investigation results of the growth mechanism as mentioned above by actually performing the growth of an organic semiconductor single crystal thin film are described.

A Si wafer with a size of 4 inch was used as a substrate on which an organic semiconductor single crystal thin film was allowed to grow, which wafer was doped with high concentration of impurity and on the surface of which wafer a SiO₂ film was formed. After cleansing the surface of the Si wafer, a comb-shape pattern P was formed thereon as follows. Namely, an amorphous fluorocarbon resin film (Cytop; Asahi Glass Co., Ltd.) was formed on the part except a part in which the comb-shape pattern P was formed out of the surface of the Si wafer due to the lift-off method to form a lyophobic surface S₂. The surface of the part inside the lyophobic surface S₂ was a lyophilic surface S₁ and was configured to be the comb-shape pattern P. The dimensions of a back part P₁ of the comb-shape pattern P were 200 μm×6.5 mm and 12 comb-shape patterns P were formed to separate from one another by 300 μm and to be parallel to one another. Comb tooth parts P₂ of the comb-shape pattern P had a width of 5 μm or 10 μm and a length of 40 μm and spacings between the comb tooth parts P₂ were 200 μm. The number of the comb tooth parts P₂ per comb-shape pattern P was 32. Namely, the comb tooth parts P₂ were formed into a 12×32 matrix array. As a raw material of the organic semiconductor single crystal thin film, C₂Ph-PXX indicated by equation (9) was selected. This is because C₂Ph-PXX is sufficiently dissolved in a solvent at room temperature and exhibits excellent stability in the air. The C₂Ph-PXX powder was dissolved in tetralin at room temperature to prepare an organic solution of C₂Ph-PXX with a concentration of 0.4 wt. %. After the organic solution was dropped on the above-mentioned Si wafer in the air, the Si wafer was placed on a holder provided inside a film forming apparatus mentioned later to allow C₂Ph-PXX thin films to grow on the Si wafer. The temperature of the holder was held at 17° C. Namely, the growth temperature was 17° C. When the Si wafer was introduced inside the film forming apparatus, nitrogen (N₂) gas was allowed to flow from a gas introduction tube which was held at approximately 60° C. at a flow rate of 0.3 L/min. After completion of the growth, the Si wafer was dried in a vacuum oven for 8 hours at 80° C. completely to remove the solvent remaining on the Si wafer surface.

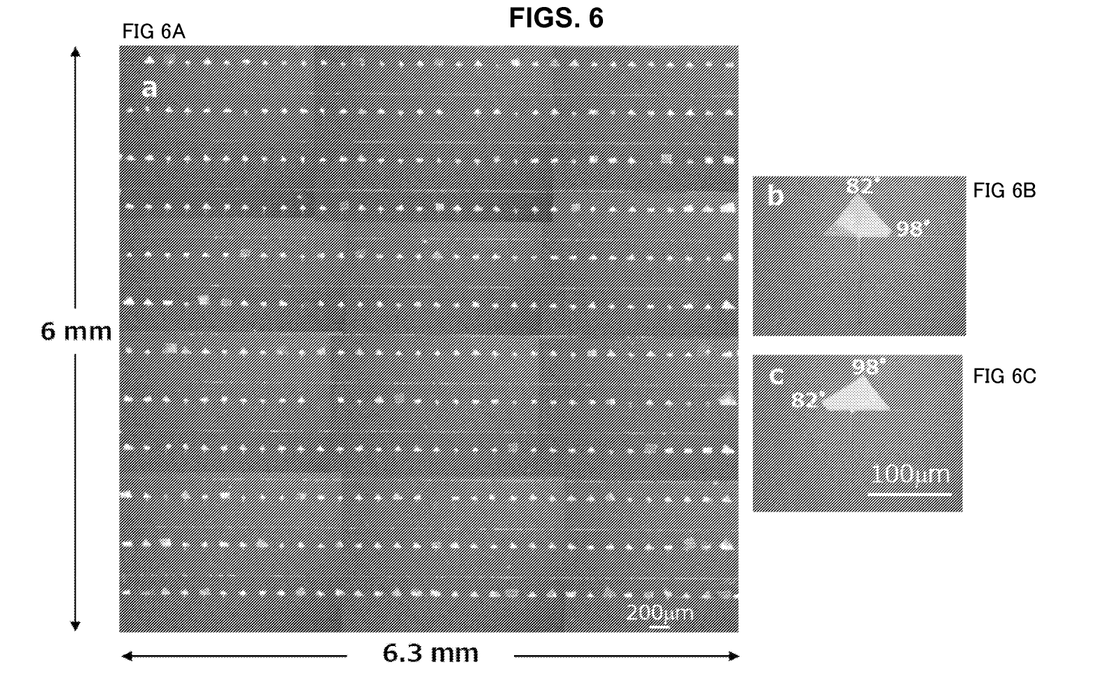

FIG. 6A illustrates a polarization microscope image of the C₂Ph-PXX thin films which were allowed to grow as mentioned above. Note that the width of each comb tooth part P₂ was 5 μm. FIG. 6B and FIG. 6C illustrate polarization microscope images for presenting typical shapes of these C₂Ph-PXX thin films. According to FIG. 6A, FIG. 6B and FIG. 6C, it is understood that the growth took place as described with reference to FIG. 1 to FIG. 3. Namely, all the C₂Ph-PXX thin films were allowed to grow starting from the intersections of the comb tooth parts P₂ and the back parts P₁ down to the back parts P₁. This indicates that the growth positions of the C₂Ph-PXX thin films can be controlled in high accuracy. The dimensions of the C₂Ph-PXX thin films were approximately 100×100 μm². Moreover, The thicknesses of the C₂Ph-PXX thin films were approximately 0.2 μm. The contrast of each C₂Ph-PXX thin film is caused by the difference in thickness thereof depending on a position therein. All the C₂Ph-PXX thin films similarly had facet angles of 82 degrees or 98 degrees, this indicating that faceted growth took place. These results indicate that all the C₂Ph-PXX thin films are crystals with a single domain, in other words, single crystal thin films. Additionally, the yield defined as a value obtained by dividing the number of the C₂Ph-PXX thin films by the number of the comb tooth parts P₂ was 98.2% of the 12×32 matrix array, this indicating the method promising a large-area scale process of those.

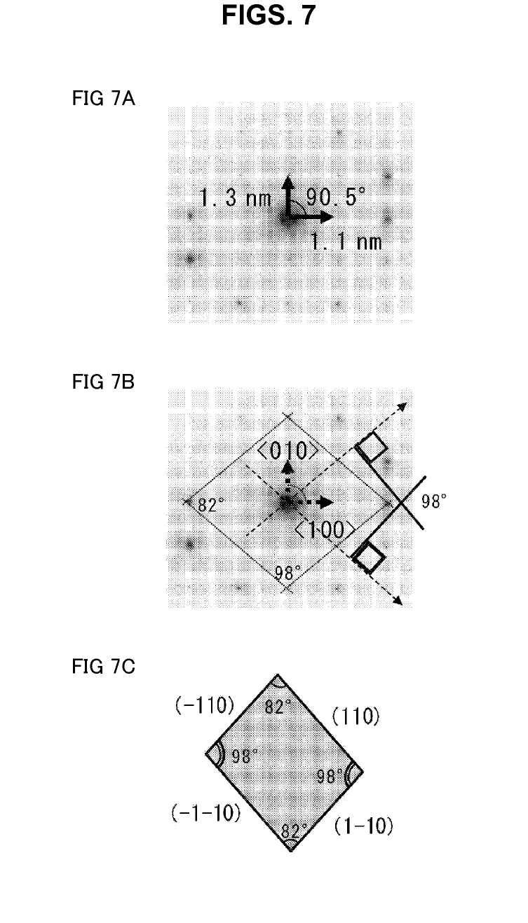

In order to study the structure of the above-mentioned C₂Ph-PXX thin film in detail, electron microscope observation was performed using a transmission electron microscope (TEM) (JEOL JEM-4000FXS) at an acceleration voltage of 400 kV and under low dose conditions. FIG. 7A illustrates a limited visual field image of an electron beam diffraction pattern of the C₂Ph-PXX thin film based on planar TEM observation. As apparent from FIG. 7A, the diffraction spots were definitely observed, indicating the C₂Ph-PXX thin film being a single crystal. The lattice constants in the plane (for a-axis and for b-axis) are obtained as 1.1 nm and 1.3 nm, respectively, based on the periodicity of the diffraction pattern. The angle formed by two directions of the a-axis and the b-axis is 90.5 degrees. The lattice constant in the c-axis direction is 2.2 nm based on a cross-sectional TEM image, being completely consistent with the length of the C₂Ph-PXX molecule. Here, it is assumed that the crystal structure of the C₂Ph-PXX thin film is orthorhombic since the angle formed by the two directions of the a-axis and the b-axis is approximately 90 degrees. FIG. 7B presents the characteristic facet angles of 82 degrees and 98 degrees. As illustrated in FIG. 7C, the rectangle enclosed by the {110} facet in the real space has characteristic vertices with the angles of 82 degrees and 98 degrees at both ends of its diagonals. Accordingly, it can be concluded that all the C₂Ph-PXX thin films are single crystals for which FIG. 7C definitely presents faceted growth.

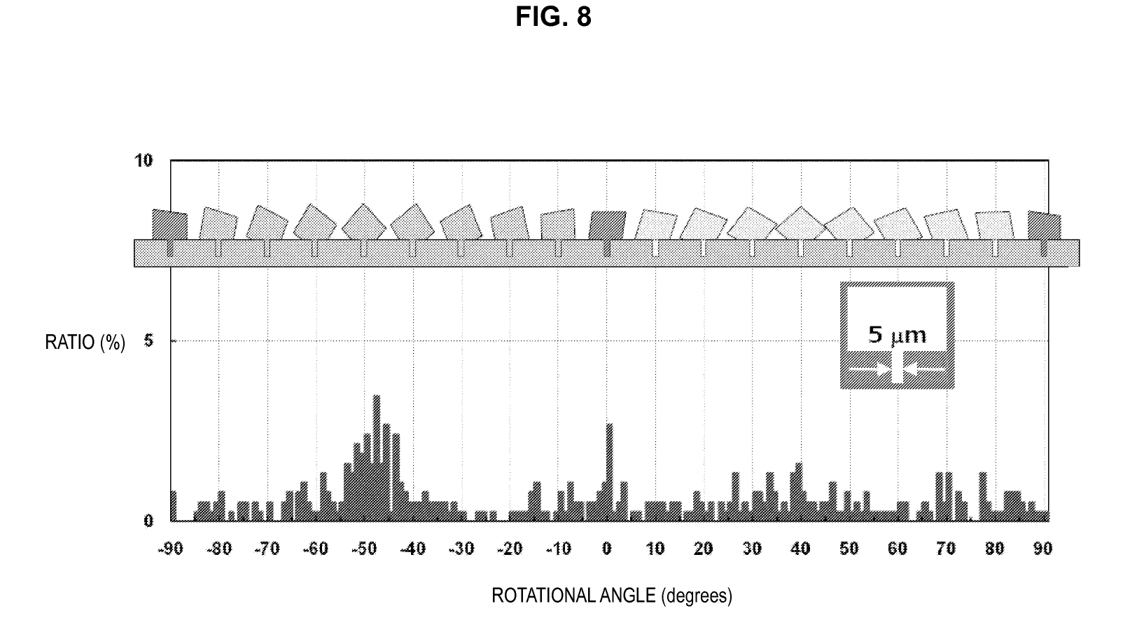

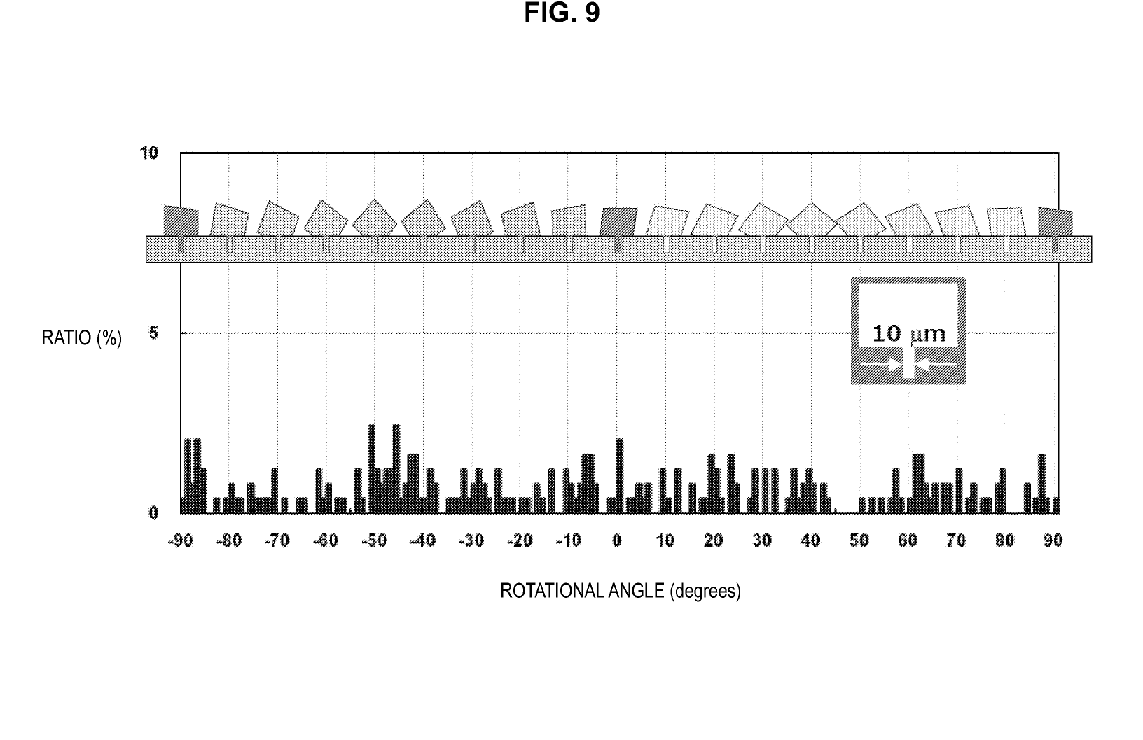

In order to study the crystal orientation of the C₂Ph-PXX thin film in detail, the rotational angles of all the C₂Ph-PXX thin films illustrated in FIG. 6A were investigated. It is defined that the shape of the C₂Ph-PXX thin film in which the <-110> orientation is parallel to the longitudinal direction of the comb tooth part P₂, that is, nucleation control region corresponds to a rotational angle of 0 degrees. Clockwise and counterclockwise rotations are denoted by positive and negative rotational angles, respectively. FIG. 8 illustrates a histogram of the rotational angles of the C₂Ph-PXX thin films when the comb tooth part P₂ has 5 μm of width. The insertion in the upper part of FIG. 8 presents the crystal shapes of the C₂Ph-PXX thin films corresponding to the rotational angles. FIG. 8 presents definite observation that the C₂Ph-PXX thin films have the rotational angles of approximately −48 degrees and 0 degrees. It is estimated that the ratio of the C₂Ph-PXX thin films with a rotational angle within approximately −48 degrees±10 degrees and the ratio thereof with a rotational angle within approximately 0 degrees±10 degrees are 29.1% and 13.1%, respectively. Accordingly, the shape for which the rotational angle is approximately −48 degrees is predominant. This shape corresponds to the shape of the C₂Ph-PXX thin film illustrated in FIG. 6B. FIG. 9 illustrates a histogram for the C₂Ph-PXX thin films when the comb tooth part P₂ has 10 μm of width. FIG. 9 presents no particular rotational angle in this case. These results imply that the crystal orientation of the C₂Ph-PXX thin film depends on the width of the comb tooth part P₂. As the width of the comb tooth part P₂ decreases, the C₂Ph-PXX thin films in the shape illustrated in FIG. 6B increase.

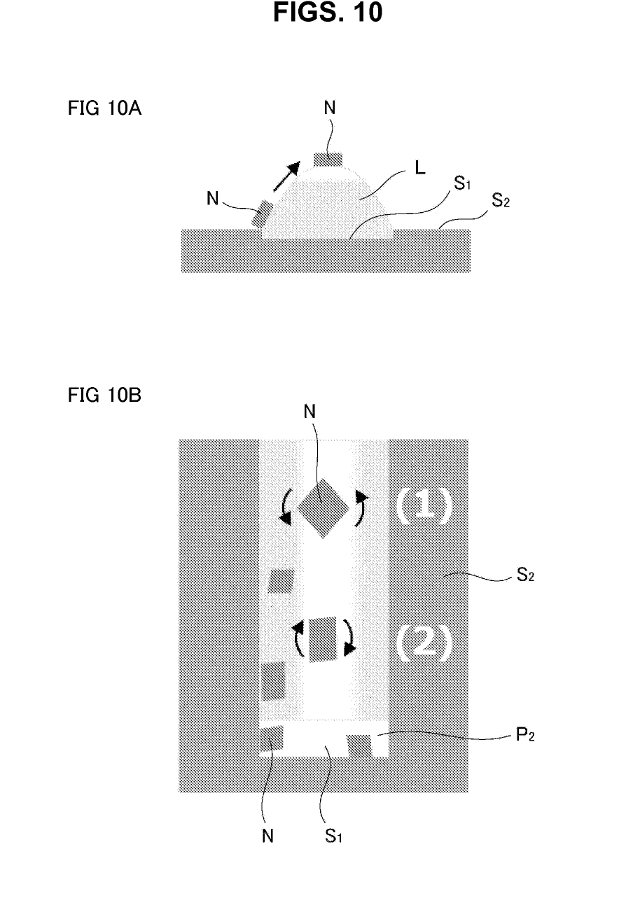

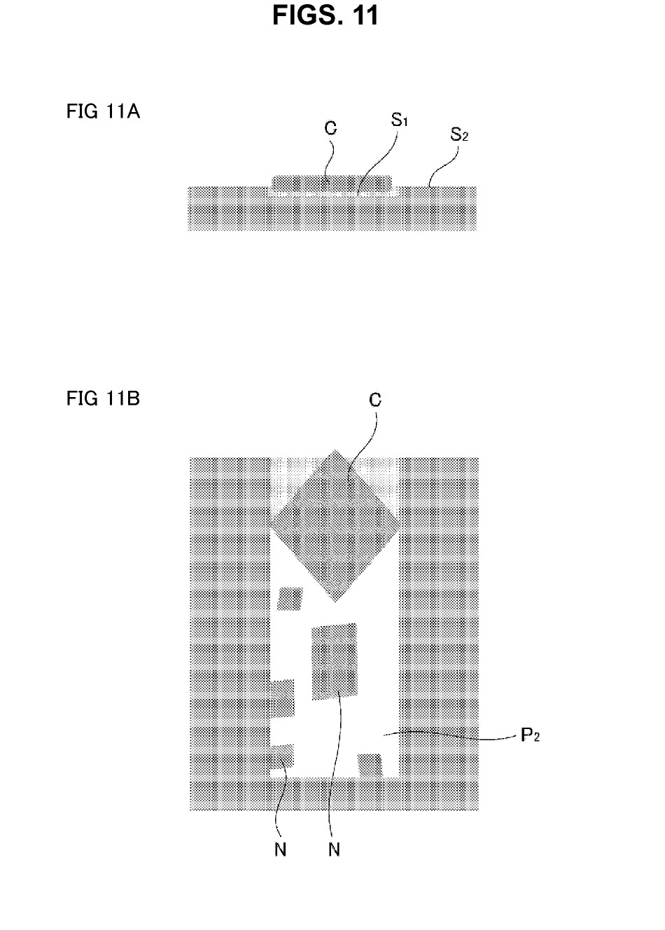

According to the above, the following important results have been obtained. First, a C₂Ph-PXX thin film with a single domain, that is, in single crystal can be allowed to grow. Second, the crystal orientation of the C₂Ph-PXX thin film depends on the width of the comb tooth part P₂. These results are considered closely to relate to the phenomena in the region of the comb tooth part P₂. FIG. 10A and FIG. 10B illustrate a crystallization mechanism in the region of the comb tooth part P₂ in the initial stage of evaporation of the solvent. Moreover, FIG. 11A and FIG. 11B illustrate a crystallization mechanism in the region of the comb tooth part P₂ in the final stage of evaporation of the solvent. Herein, FIG. 10A and FIG. 11A are cross-sectional views and FIG. 10B and FIG. 11B are top views. As illustrated in FIG. 10A and FIG. 10B, in the initial stage of evaporation of the solvent, a plurality of crystal nuclei N are formed on the surface of the droplet L of the organic solution in the region of the comb tooth part P₂, and meanwhile, in the final stage of evaporation of the solvent, as illustrated in FIG. 11A and FIG. 11B, only one crystal nucleus N is eventually allowed to grow sufficiently large to be a stable crystal C, closing the comb tooth part P₂. The reason is considered that the growth rate has anisotropy as illustrated in FIG. 12 (the lengths of the broken line arrows represent growth rates in the figure). Namely, in the initial stage of evaporation, since the energy for uneven nucleation is lower than the energy for uniform nucleation, a number of crystal nuclei N are formed unevenly on the interface between the droplet L and the lyophobic surface S₂.

Since the facet of the crystal is a stable surface, the crystal nucleus N contacts with the interface between the droplet L and the lyophobic surface S₂ to form the {110} plane. When the crystal nucleus N does not touch the interface between the droplet L and the lyophobic surface S₂ to move to the uppermost part of the droplet L, the crystal nucleus N is arranged such that the surface tension becomes largest. The smaller the width of the comb tooth part P₂ becomes, the smaller the curvature radius of the droplet L becomes. Accordingly, the smaller the width of the comb tooth part P₂ becomes, the much more favorable the thinner crystal nucleus N in shape becomes. There are two cases of a case where the crystal nucleus N does not undergo the touch immediately and a case where it does not undergo the touch to be slow. In the case of no immediate touch, as illustrated in portion (1) of FIG. 10B, the crystal nucleus N grows isotropically, and as a result, the shape at the rotational angle of 48 degrees is formed. Conversely, in the case of no touch to be slow, as illustrated in portion (2) of FIG. 10B, since the growing <110> or <1-10> facet plane does not contact with the interface between the droplet L and the lyophobic surface S₂, the crystal nucleus N grows anisotropically. Accordingly, the shape at the rotational angle close to 0 degrees is exceedingly favorable. Herein, a case is considered where the <110> or <1-10> facet plane contacts with the interface between the droplet L and the lyophobic surface S₂. In this case, the shape at the rotational angle close approximately ±90 degrees would be obtained. This would be because the bonding strength between the interface of the droplet L and the lyophobic surface S₂ and the {110} plane was larger than the bonding strength between the interface of the droplet L and the lyophobic surface S₂ and the {1-10} plane.

[Film Forming Apparatus]

One example of a film forming apparatus used for growth of the above-mentioned organic semiconductor single crystal thin film is described.

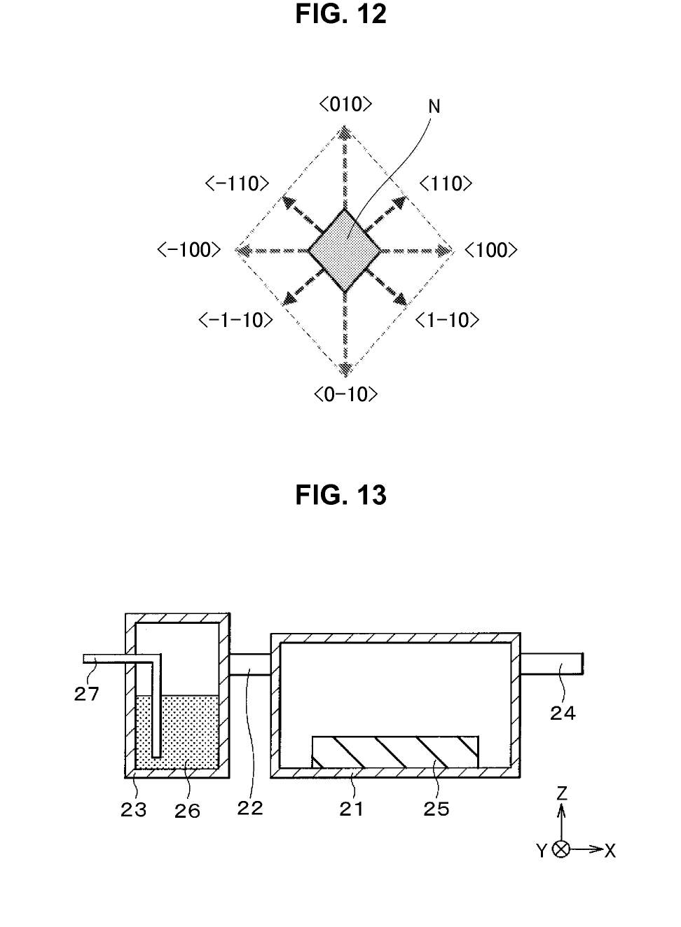

FIG. 13 illustrates a film forming apparatus used for growth of organic semiconductor single crystal thin films. As illustrated in FIG. 13, The film forming apparatus has a chamber 21 and a solvent tank 23 coupled with the chamber 21 via a coupling tube 22. The chamber 21 can be sealed up in the state of its coupling with the solvent tank 23. The chamber 21 is provided with an exhaust tube 24. In the chamber 21, a holder 25 whose temperature is controllable. On the holder 25, a base body (not shown) for forming the films is placed.

In the solvent tank 23, a co-solvent 26 of the same kind as the solvent in the organic solution used for growth of organic semiconductor single crystal thin films is retained. The temperature of the co-solvent 26 can be adjusted by heating means such as an oil bath omitted in the figure. Gas can be introduced into the co-solvent 26 through a gas introduction tube 27 settled in the inside of the solvent tank 23 from the outside thereof. The solvent tank 23 can supply vapor containing the vapor of the co-solvent 26 to the chamber 21 through the coupling tube 22. Thereby, the peripheral environment of the organic solution, that is, a pressure (vapor pressure) P of the vapor inside the chamber 21 according to the temperature of the co-solvent 26 is controlled. In addition, the vapor supplied to the chamber 21 can be vented to the outside through the exhaust tube 24 as needed.

The growth of organic semiconductor single crystal thin films using the film forming apparatus includes introducing a substrate 11 in the chamber 21 of the film forming apparatus to place it on the holder 25 as illustrated in FIG. 14. Next, after the exhaust tube 24 is closed to seal up the chamber 21 and the solvent tank 23, gas 28 such as nitrogen (N₂) is introduced in the solvent tank 23, for example, through the gas introduction tube 27. Thereby, vapor 29 containing the co-solvent 26 is supplied to the chamber 21 from the solvent tank 23 through the coupling tube 22, this allowing the inside of the chamber 21 to be an environment which is filled with the vapor 29. The temperature of the substrate 11 is configured at temperature T_{g} illustrated in FIG. 1 using the holder 25. It is also preferable for the temperature of the co-solvent 26 to be configured at T_{g} using an oil bath or the like as needed. Since the vapor pressure P inside the chamber 21 is the saturated vapor pressure at temperature T_{g} by doing as above, the liquid phase (organic solution 30) and the gas phase (vapor) are allowed to be in an equilibrium state. This also applies to the liquid phase (co-solvent 26) and the gas phase (vapor) inside the solvent tank 23.

Meanwhile, an organic solution 30 obtained by dissolving an organic compound used for the growth of organic semiconductor single crystal thin films in a solvent is prepared. Conventionally known ones can be used as the solvent which is selected as needed and specifically employs at least one, for example, of xylene, p-xylene, mesitylene, toluene, tetralin, anisole, benzene, 1,2-dichlorobenzene, o-dichlorobenzene, cyclohexane and ethylcyclohexane.

Then, the organic solution 30 thus prepared is supplied onto the substrate 11, as illustrated in FIG. 14, via a not-shown nozzle.

Next, similarly to the above-mentioned growth method, the solvent in the organic solution 30 is evaporated holding the temperature of the organic solution 30 at T_{g}. Thereby, crystal nuclei are formed from the organic solution 30 retained on the comb tooth part P₂, only one crystal C having grown from the crystal nuclei closes a coupling part of the comb tooth part P₂ with the back part P₁, the crystal C starts to grow in the organic solution 30 retained on the back part P₁, and the organic semiconductor single crystal thin film is allowed to grow on the back part P₁.

As mentioned above, according to the first embodiment, the crystal orientation, position and dimensions of an organic semiconductor single crystal thin film can be controlled. Hence, for example, in an organic transistor, the crystal orientation of the organic semiconductor single crystal thin film can be configured such that the direction of electrons traveling coincides with the direction high in mobility of carriers in the organic semiconductor single crystal thin film, this attaining a high-performance organic transistor high in mobility. Moreover, in an organic photoelectric transducer, the crystal orientation of the organic semiconductor single crystal thin film can be configured to be in the direction of the polarizing axis, this attaining a polarization organic photoelectric transducer high in sensitivity to polarized light.

### 2. Second Embodiment

### Growth Method of Organic Semiconductor Single Crystal Thin Film

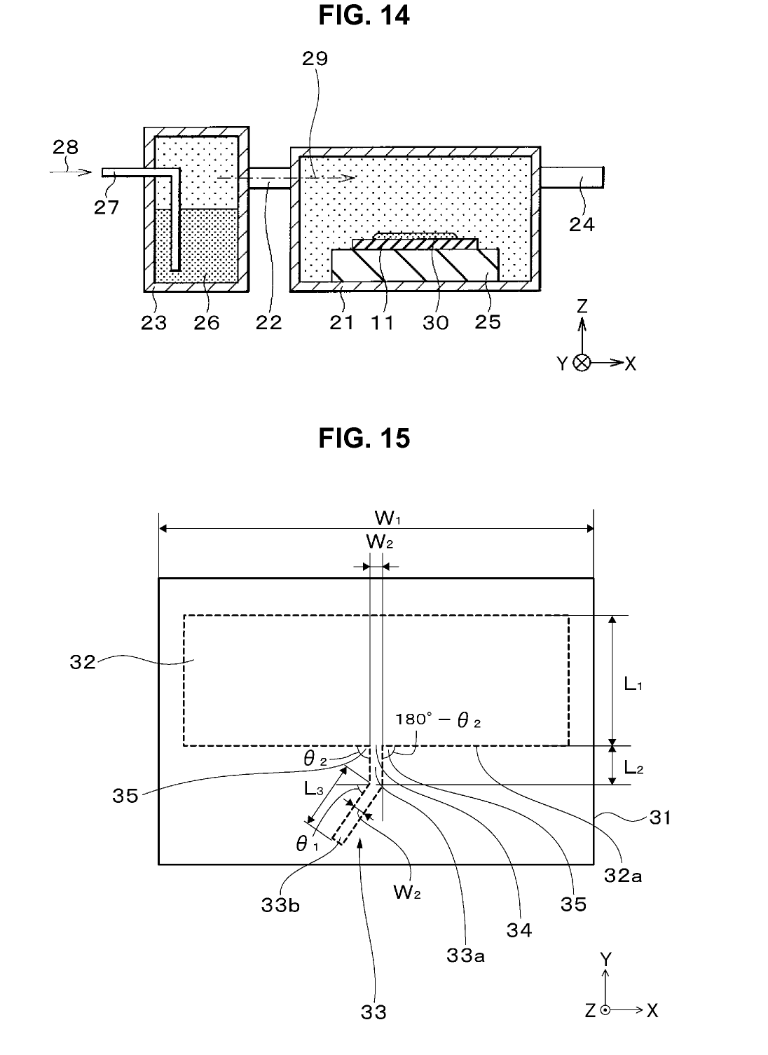

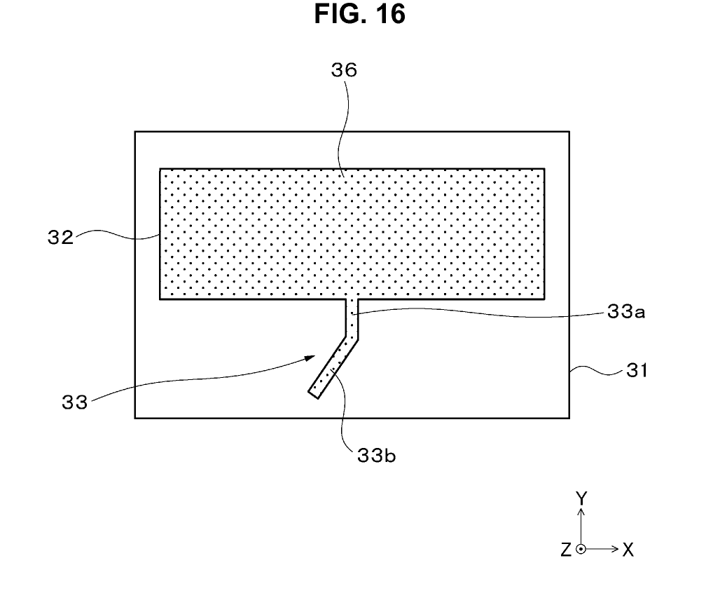

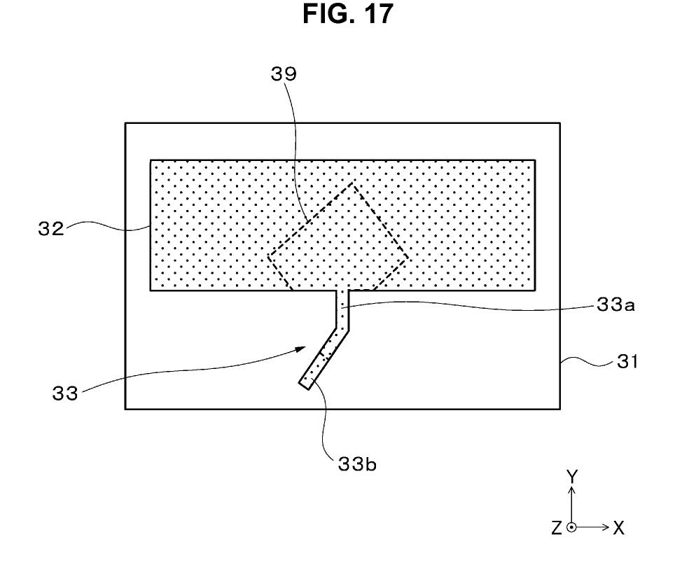

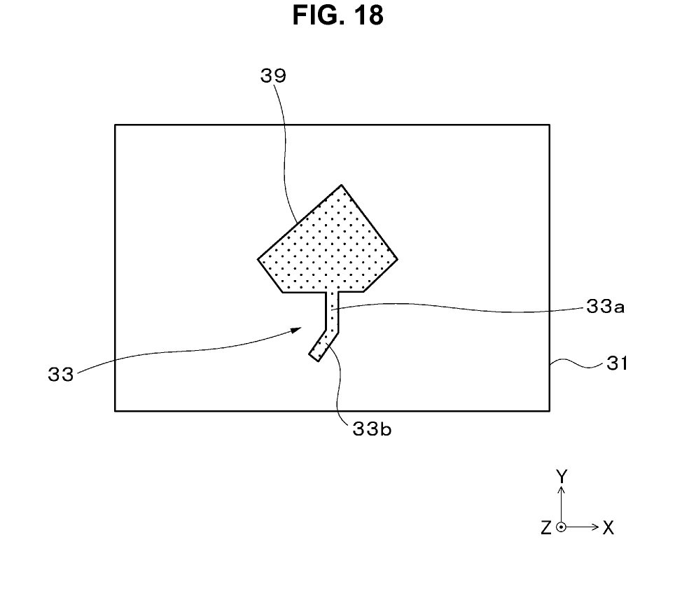

As illustrated in FIG. 15, on one principal plane of a substrate 31, a growth control region 32 and a nucleation control region 33 connected to the growth control region 32 which regions have lyophilic surfaces are formed. The part of the surface other than the growth control region 32 and the nucleation control region 33 in the one principal plane of the substrate 31 is lyophobic. The growth control region 32 and the nucleation control region 33 having the lyophilic surfaces are regions liable to be wet with the organic solution and have a property of fixing the organic solution thereon. Meanwhile, the region having the lyophobic surface other than the growth control region 32 and the nucleation control region 33 is a region hardly wet with the organic solution and have a property of repelling the organic solution. The growth control region 32 and the nucleation control region 33 having the lyophilic surfaces are obtained, for example, by performing lyophobic surface processing or film forming processing on the lyophilic surface of the substrate 31. Allowing the lyophilic surface of the substrate 31 to be lyophobic is achieved, for example, by forming an amorphous fluorocarbon resin film (Cytop; Asahi Glass Co., Ltd.) on a region desired to be lyophobic.

The growth control region 32 has a rectangular shape in this example. The area of the growth control region 32 is defined by a width W₁ and a length L₁. The width W₁ and the length L₁ are properly selected according to the shape and dimensions of the organic semiconductor single crystal thin film, and preferably, the width W₁ and the length L₁ are selected sufficiently large in order to secure the amount of the organic solution. For example, such selection is made as the width W₁=1000 to 10000 μm and the length L₁=100 to 800 μm.

The nucleation control region 33 is constituted of a first part 33a perpendicular to a one side 32a which is a long side of the growth control region 32 and a second part 33b which is coupled with the first part 33a and inclines by an angle θ₁ of 0° or more and smaller than 90°, for example, 25° or more and 65° or less relative to the above-mentioned one side 32a of the growth control region 32. A width W₂ of the first part 33a and the second part 33b is smaller than the width W₁ of the growth control region 32 and a coupling position 34 of the growth control region 32 with the nucleation control region 33 is provided with corner parts 35 which are convex toward the inside. Preferably, the width W₂ is selected sufficiently small and, for example, such selection is made as the width W₂=0.1 to 30 μm. The length L₂ of the first part 33a is selected, for example, as L₂=5 to 50 μm and the length L₃ of the second part 33b is selected, for example, as L₃=10 to 150 μm, whereas these are not limited to the above.

The tip shape of the corner parts 35 is not particularly limited but is a pointing shape preferably. Moreover, the angle θ₂ of the corner parts 35 is not particularly limited but is substantially 90°.

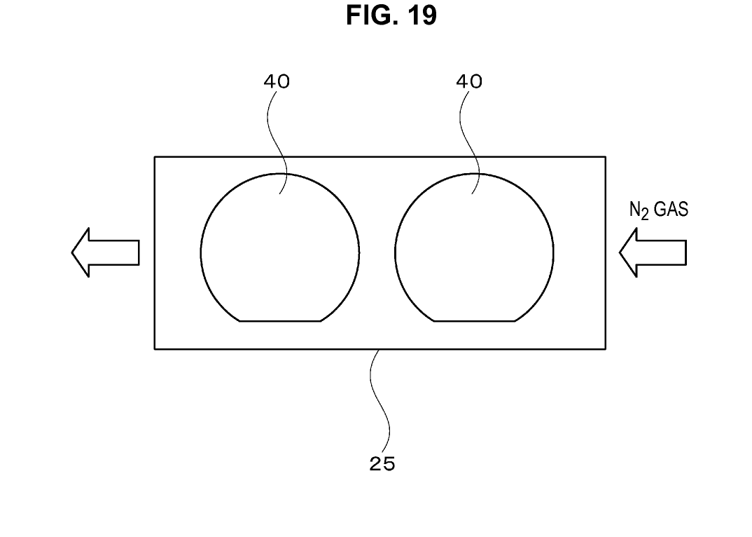

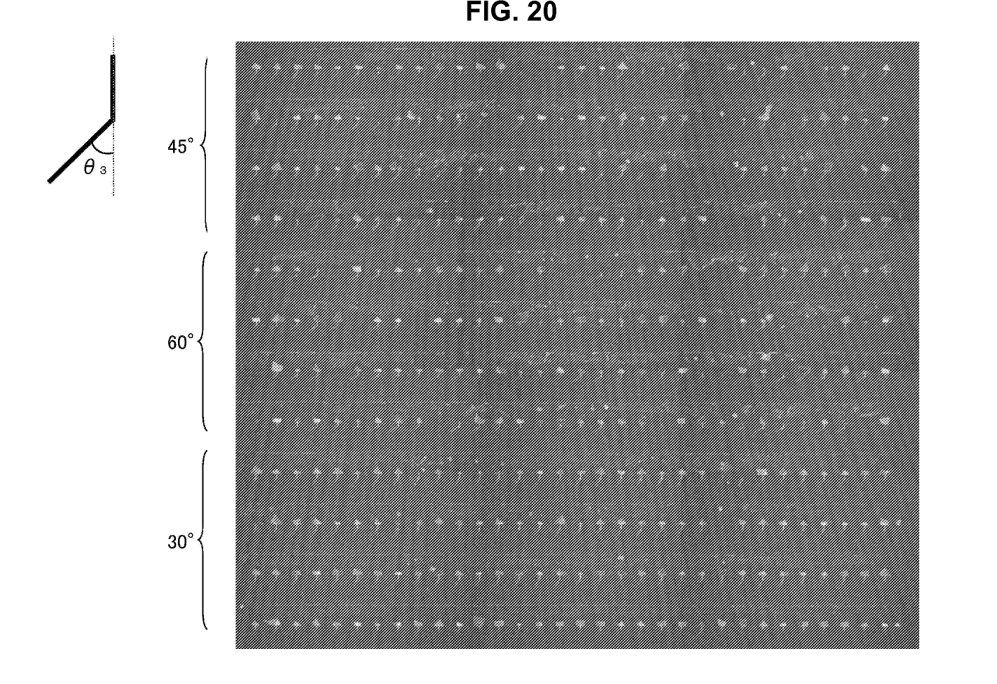

As illustrated in FIG. 16, the organic solution 36 is supplied onto the growth control region 32 and the nucleation control region 33. After that, similarly to the first embodiment, the solvent of the organic solution 36 is evaporated, and thereby, a crystal obtained by growth of a crystal nucleus formed in the first part 33a, for example, closes the first part 33a. The crystal undergoes crystal growth, and thereby, an organic semiconductor single crystal thin film 39 is allowed to grow on the growth control region 32 as illustrated in FIG. 17.

Finally, the organic solution 36 is removed from the one principal plane of the substrate 31 as needed, and thereby, the organic semiconductor single crystal thin film 39 is obtained as illustrated in FIG. 18.

As illustrated in FIG. 18, for example, the organic semiconductor single crystal thin film 39 is allowed to grow on the growth control region 32, having a pentagonal shape with a first vertex with a vertical angle of 82° and a second vertex with a vertical angle of 98°. There is a case where the organic semiconductor single crystal thin film 39 has a tetragonal shape with the first vertex with a vertical angle of 82° and the second vertex with a vertical angle of 98°.

After the growth of the organic semiconductor single crystal thin film 39, the organic semiconductor single crystal thin film 39 may undergo patterning using the etching method or the like as needed to be a desired planer shape.

### Example 2

A Si wafer similar to that in Example 1 was used as the substrate 31.

Lyophobic processing was performed on a predetermined part of its surface to arrange basic patterns with a size of 7 mm×7 mm constituted of the growth control regions 32 and the nucleation control regions 33 having the lyophilic surfaces into 10 rows by 9 columns. Note that the first to fourth rows and the eighth to tenth rows had columns less than 9 since the Si wafer is circular. The basic patterns employed ones in cases where an angle θ₃ (=90°−θ₁) between the first part 33a and the second part 33b of the nucleation control region 33 were 45°, 60° and 30°. The dimensions of the growth control region 32 was 200 μm×6.5 mm and 10 growth control regions 32 were formed to separate from one another by 300 μm and to be parallel to one another. Spacings between the nucleation control regions 33 in the direction of the one long side of the growth control region 32 were 200 μm. The nucleation control region 33 had the width W₂ of 5 μm or 10 μm, the first part 33a had the length L₂ of 40 μm and the second part 33b had a length L₃ of 100 μm. As illustrated in FIG. 19, two Si wafers 40 above were placed on the holder 25 of the film forming apparatus illustrated in FIG. 14 and the organic semiconductor single crystal thin films 39 were allowed to grow on the Si wafers 40. The growth temperature (substrate temperature) was 16° C. (similar results were obtained also at 16° C.±1° C.) or 18° C. (similar results were obtained also at 18° C.±1° C.). Nitrogen (N₂) gas was supplied from the gas introduction tube 27 of the film forming apparatus illustrated in FIG. 14 at a flow rate of 0.3 L/min. The temperature of the gas introduction tube 27 was configured to be 58° C.

As the raw material of the organic semiconductor single crystal thin films 39, C₂Ph-PXX indicated by equation (9) was used.

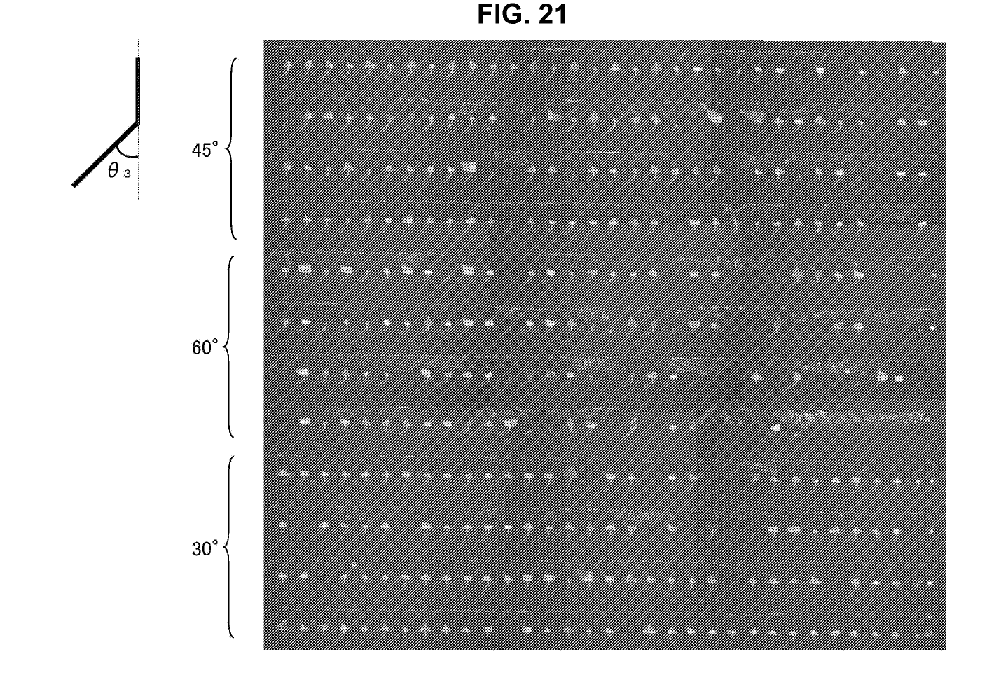

FIG. 20 and FIG. 21 illustrate polarization microscope images of all the organic semiconductor single crystal thin films 39 having grown over the whole surfaces of the Si wafers 40. FIG. 20 is for the case of the growth temperature of 16° C. and FIG. 21 is for the case of the growth temperature of 18° C. The desiccation of the solvent of the organic solution 36 started by approximately 8 minutes after the organic solution 36 was supplied onto the principal planes of the Si wafers 40 and N₂ gas was started to be supplied from the gas introduction tube 27. The desiccation of the solvent of the organic solution 36 over the entirety of the Si wafers 40 had completed in 1 hour and minutes. In FIG. 20 and FIG. 21, the first to fourth rows present the case of θ₃=45°, the fifth to eighth rows present the case of θ₃=60° and the ninth to twelfth rows present the case of θ₃=30°.

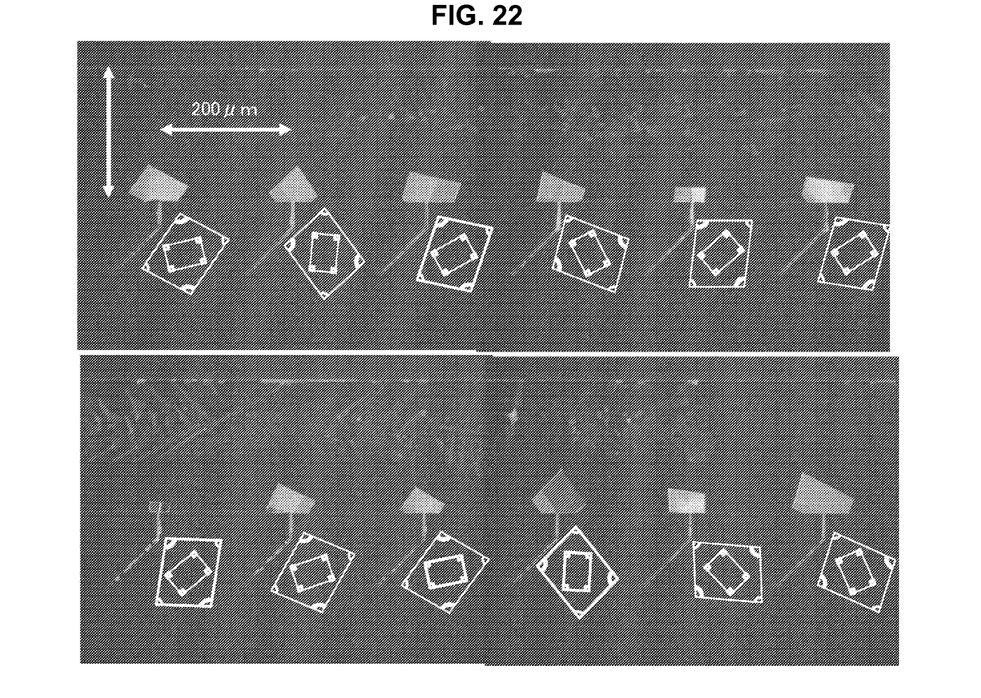

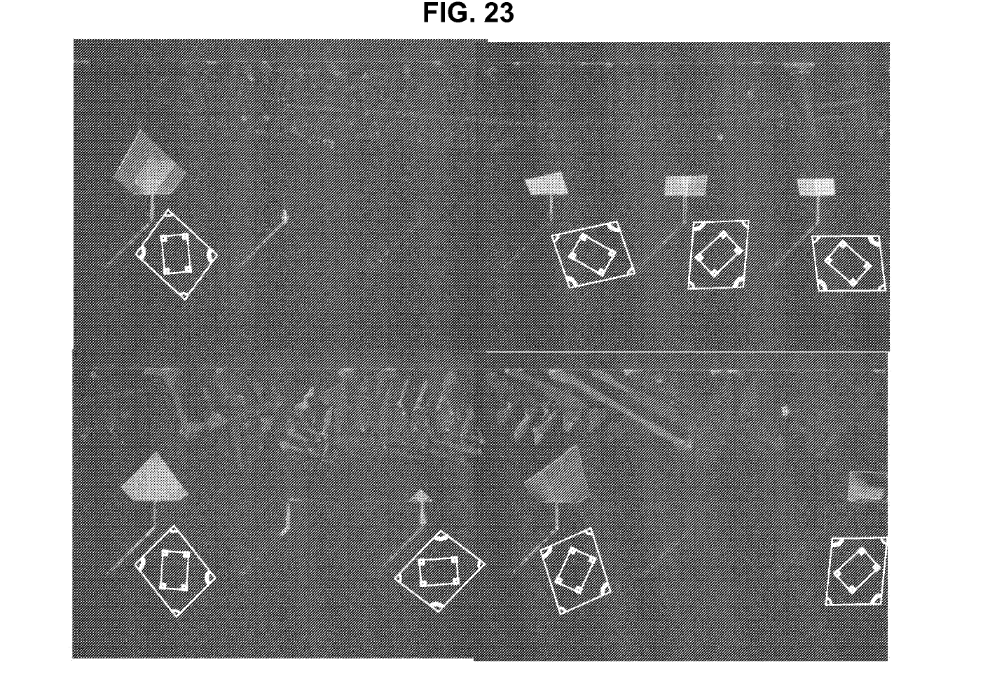

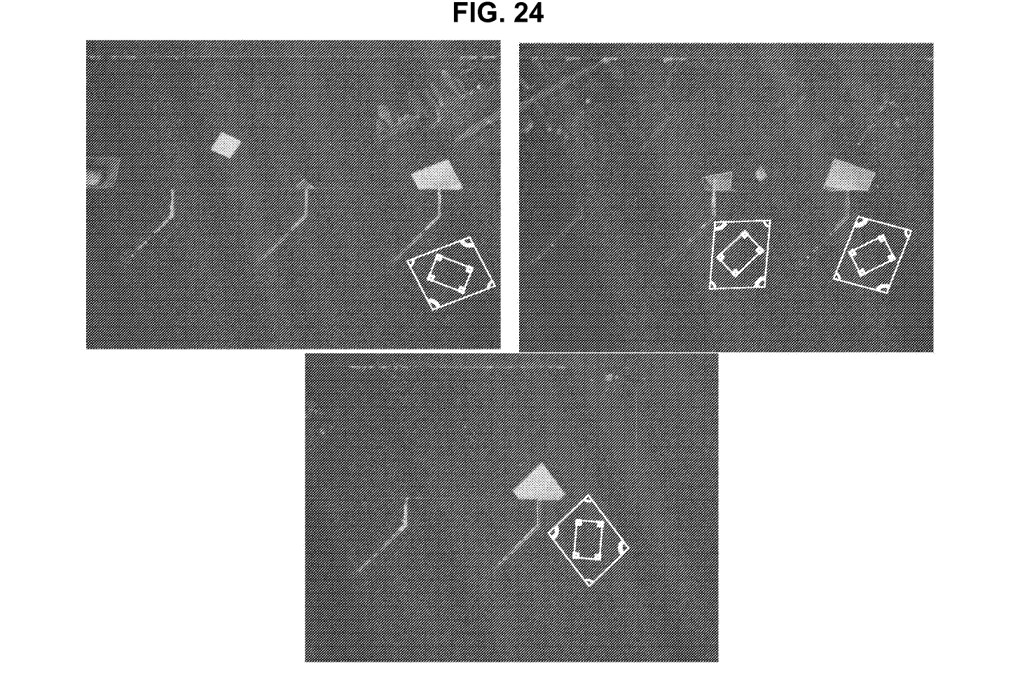

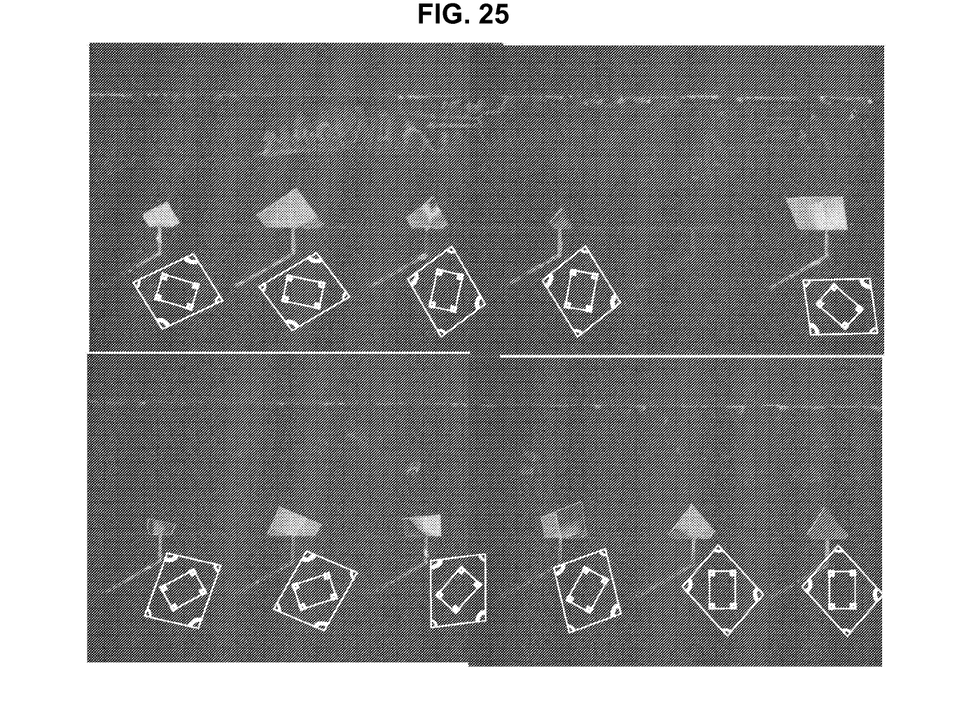

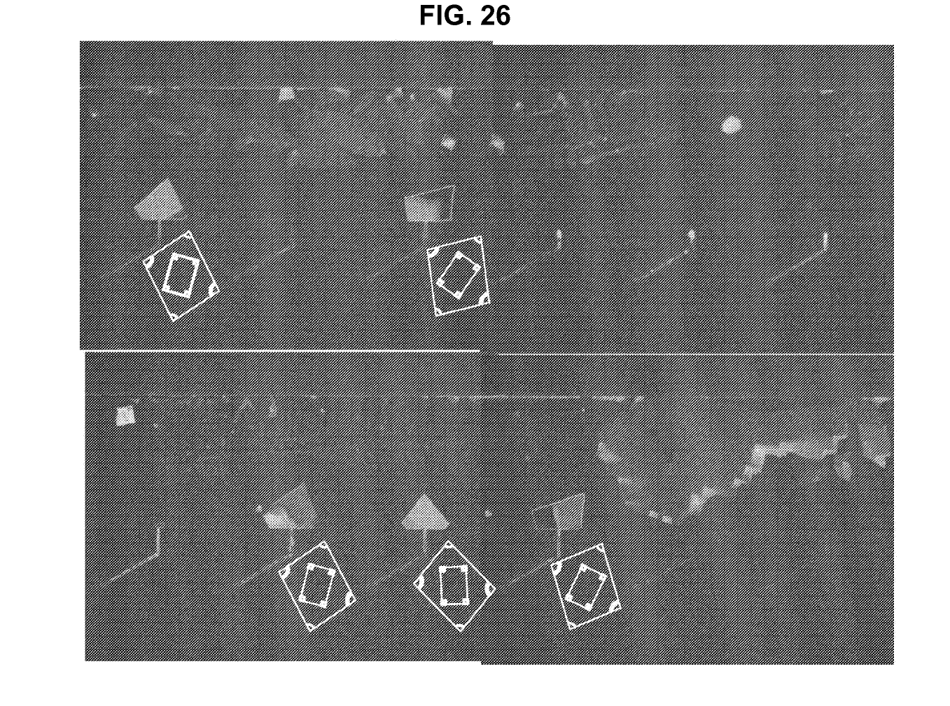

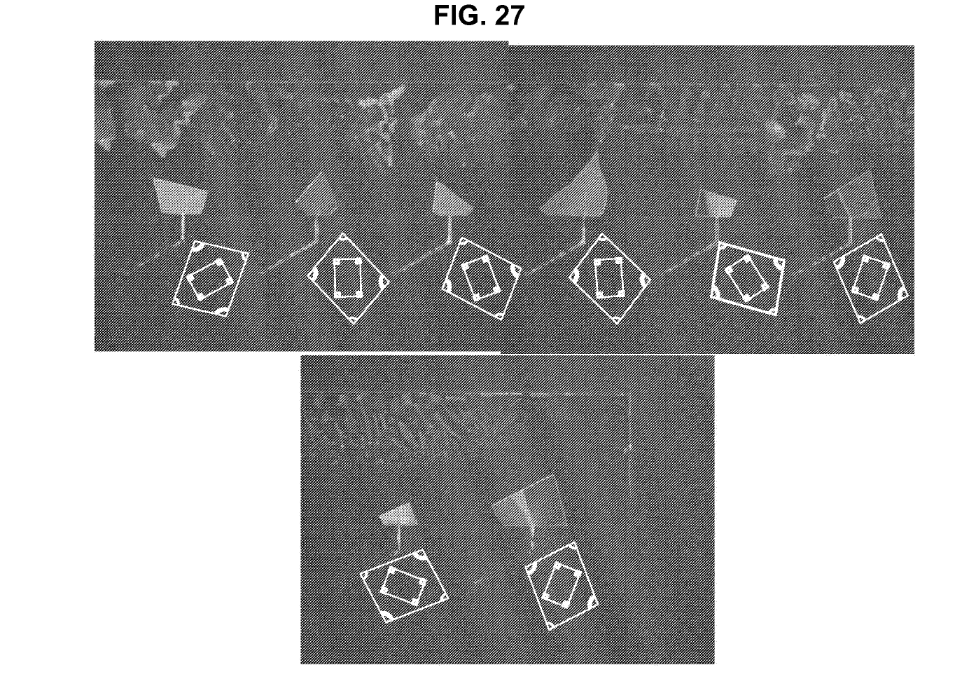

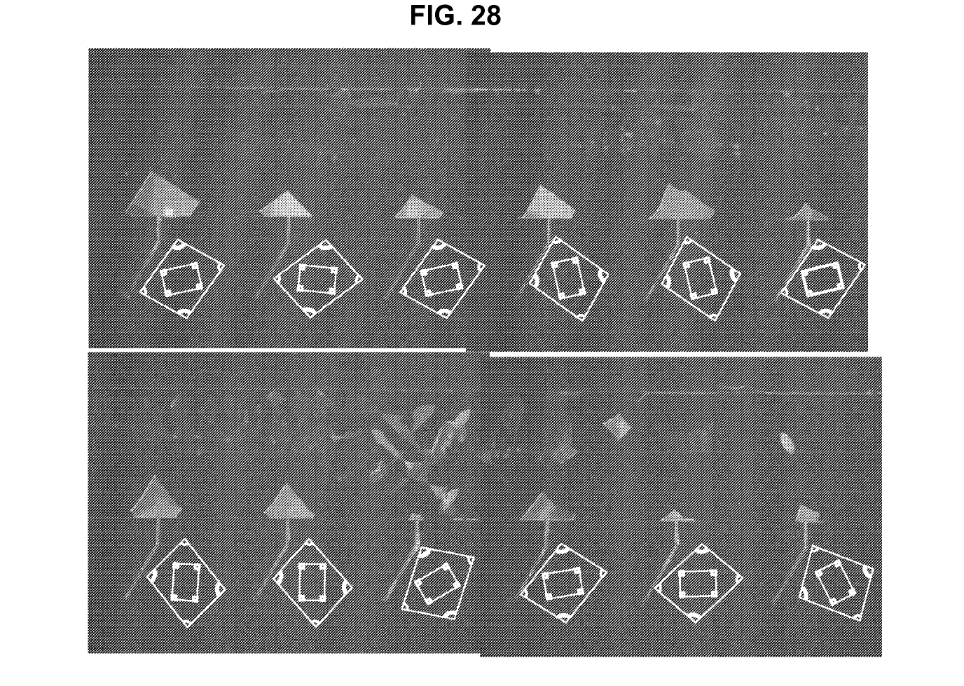

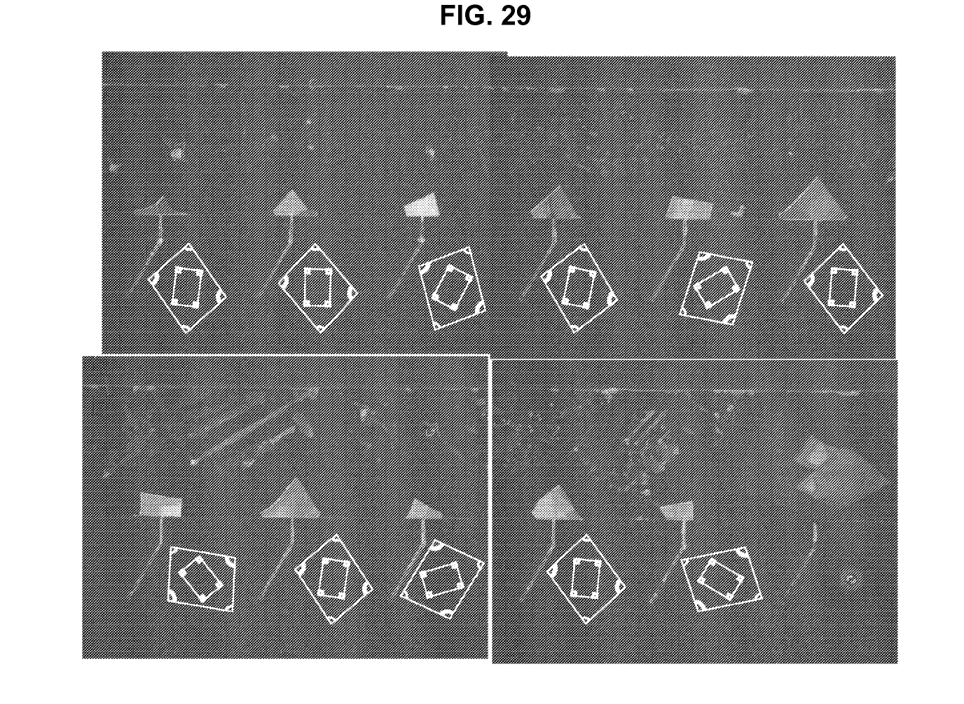

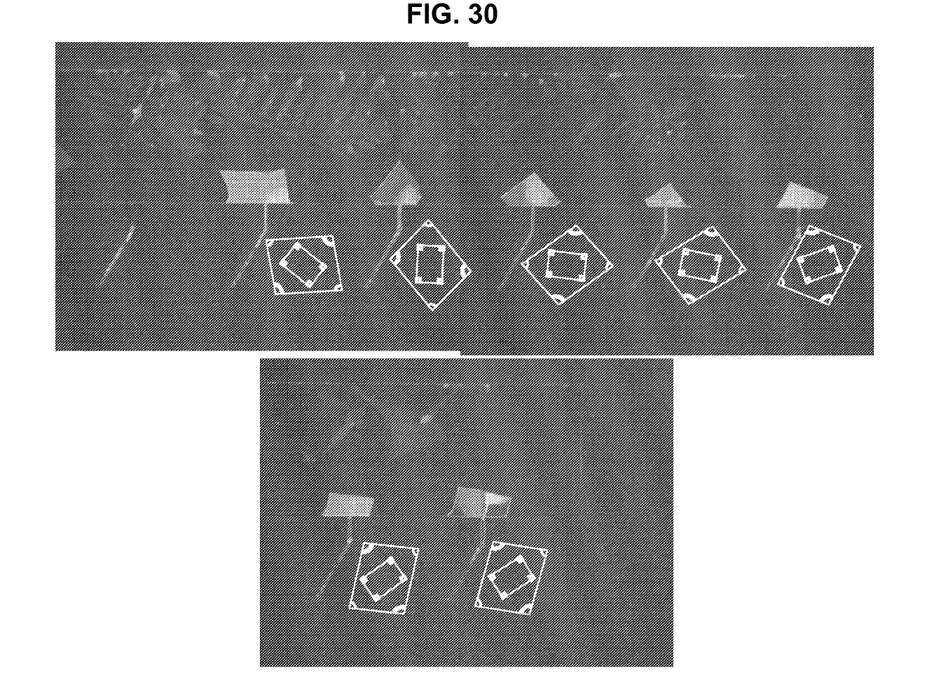

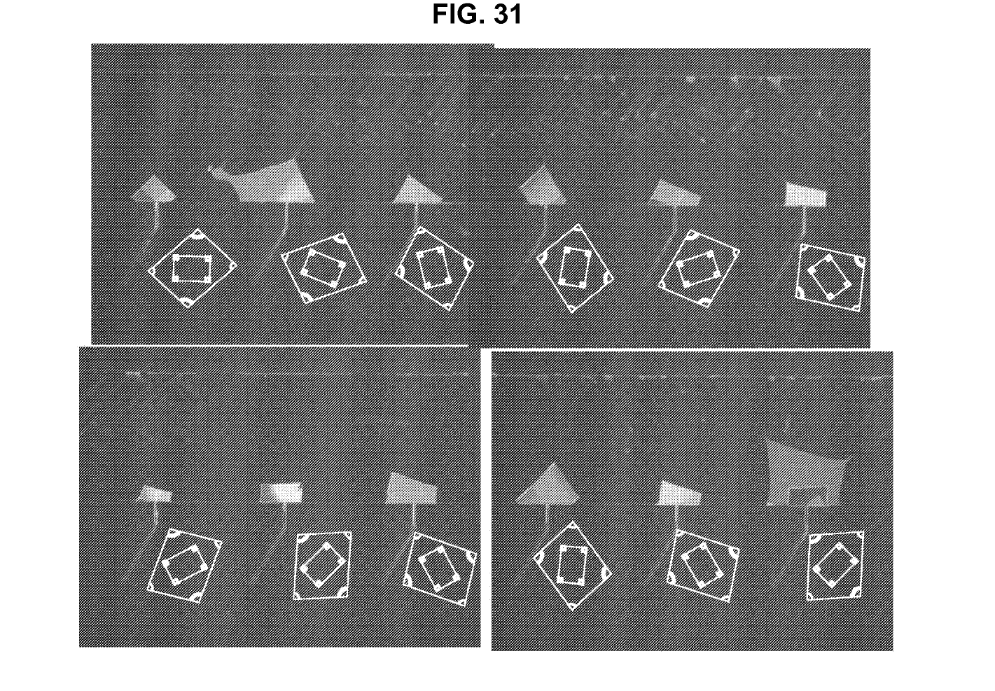

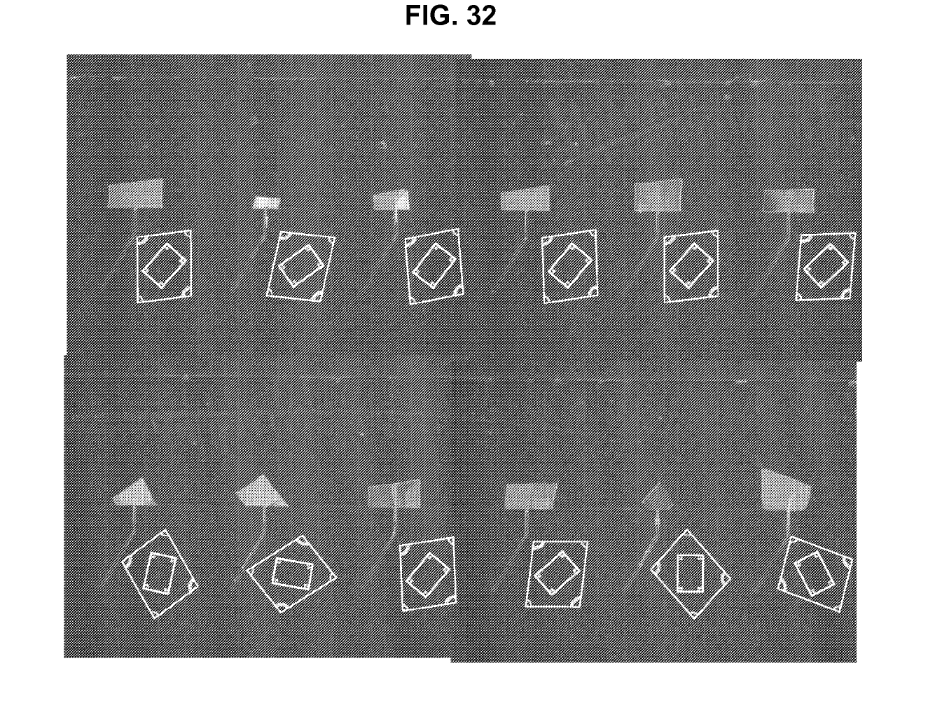

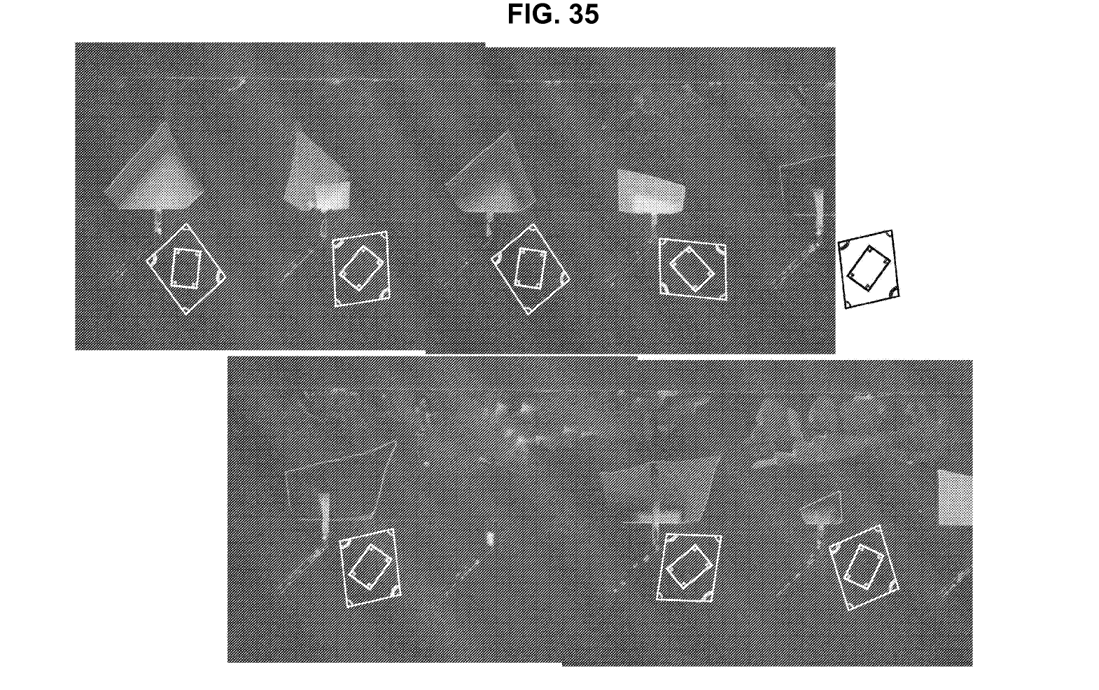

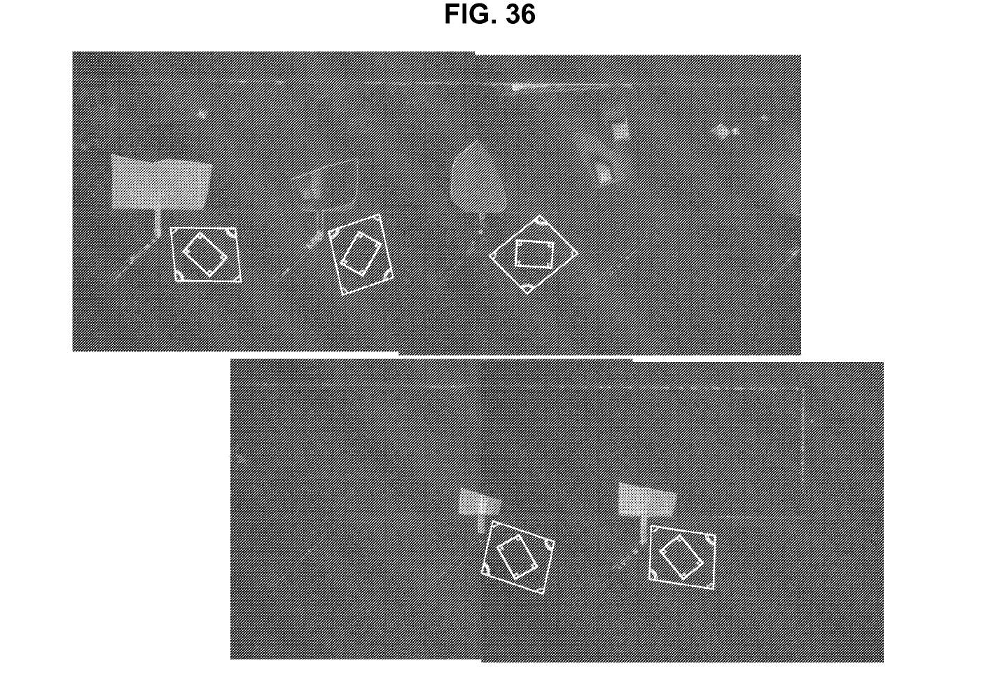

FIG. 22 to FIG. 24 are enlarged views of the organic semiconductor single crystal thin films 39 in the first stages of the Si wafers 40 (θ₃=45′). FIG. 22 to FIG. 24 have, as insertions close to the individual organic semiconductor single crystal thin films 39, tetragons constituted of the {110} plane facets expected from their crystal structures (similarly to FIG. 25 to FIG. 36 below). FIG. 25 to FIG. 27 are enlarged views of the organic semiconductor single crystal thin films 39 in the fifth stages of the Si wafers 40 (θ₃=60°). FIG. 28 to FIG. 30 are enlarged views of the organic semiconductor single crystal thin films 39 in the ninth stages of the Si wafers 40 (θ₃=30°). FIG. 31 to FIG. 33 are enlarged views of the organic semiconductor single crystal thin films 39 in the twelfth stages of the Si wafers 40 (θ₃=30°).

As illustrated in FIG. 20 to FIG. 33, tetragons and pentagons having the first vertex with a vertical angle of 82° and the second vertex with a vertical angle of 98° are observed as the shapes of the organic semiconductor single crystal thin films 39 on the growth control regions 32. The numbers of the organic semiconductor single crystal thin films 39 having these two kinds of shapes and the ratios relative to their entirety are counted to be the followings.

Growth Temperature: 16° C.

| θ₃ | The Number of Pentagons | The Number of Tetragons |
|---|---|---|
| 45° | 42 (33%) | 31 (24%) |
| 60° | 37 (29%) | 27 (21%) |
| 30° | 31 (24%) | 41 (32%) |

Growth Temperature: 18° C.

| θ₃ | The Number of Pentagons | The Number of Tetragons |
|---|---|---|
| 45° | 60 (47%) | 16 (13%) |
| 60° | 27 (21%) | 31 (24%) |
| 30° | 20 (17%) | 29 (23%) |

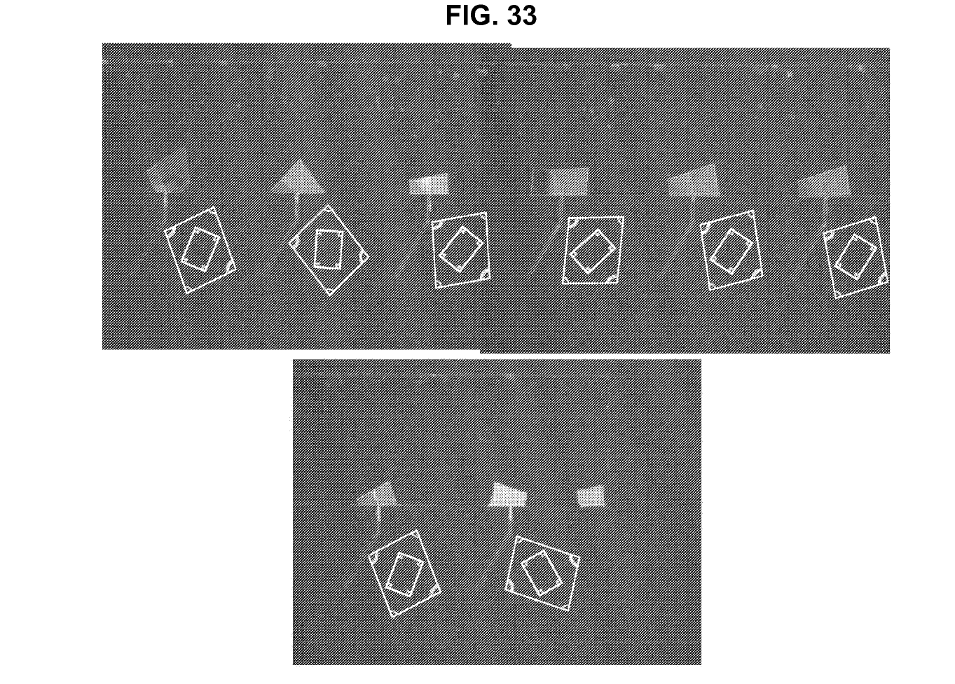

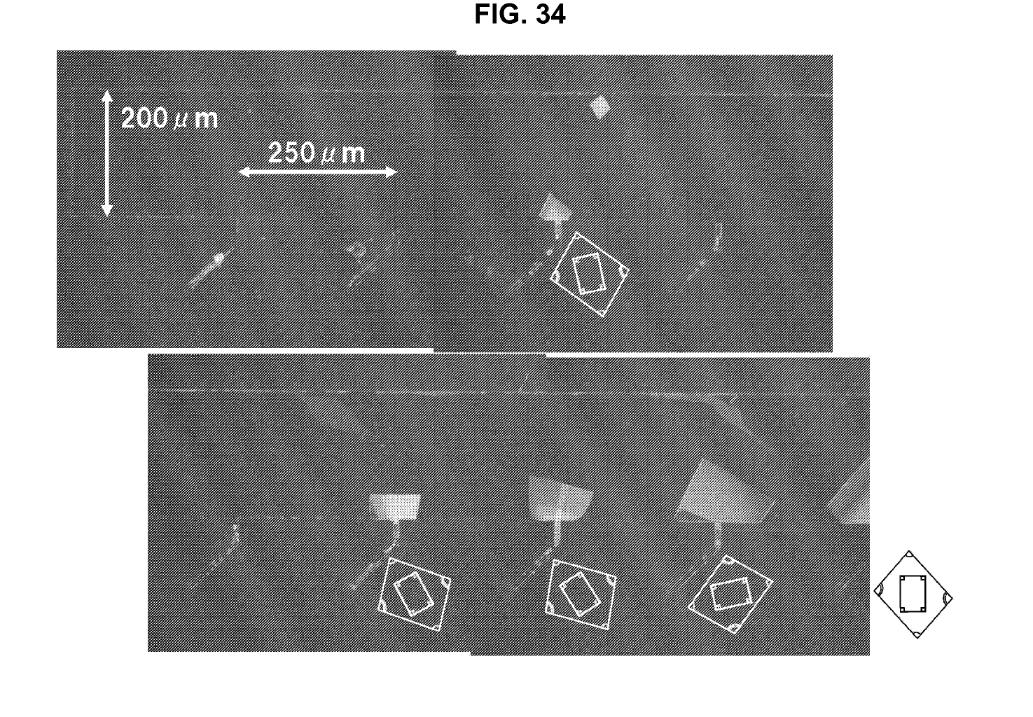

FIG. 34 to FIG. 36 are enlarged views of the organic semiconductor single crystal thin films 39 in the fourth stages of the Si wafers 44 (θ₃=45′). The width W₂ of the nucleation control regions 33 was 10 μm.

According to FIG. 34 to FIG. 36, the nucleation control regions 33 with the width W₂ of 5 μm are high in yield of the organic semiconductor single crystal thin films 39 compared with the case of the width W₂ of 10 μm.

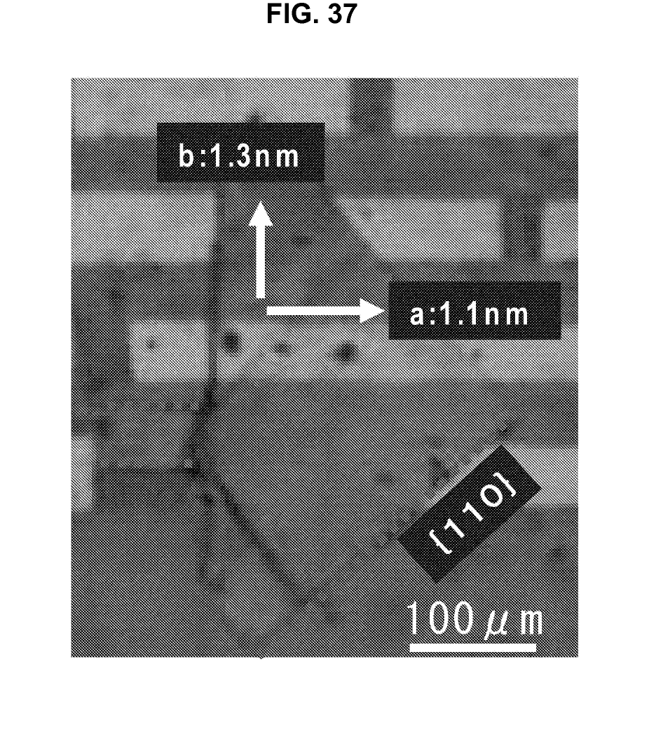

FIG. 37 illustrates a planer transmission electron microscope image (planer TEM image) of one organic semiconductor single crystal thin film 39 having grown as mentioned above. FIG. 38 illustrates a planer limited visual field image of an electron beam diffraction pattern when an electron beam was allowed to be incident on the organic semiconductor single crystal thin film 39 in a substantial vertical direction thereto. According to FIG. 38, a=1.1 nm, b=1.3 nm, and as to an angle γ between the a-axis and the b-axis, γ=90.5°. X-ray diffraction measurements of molecular crystal thin films composed of C₂Ph-PXX present a=11.44 angstrom (1.144 nm), b=12.67 angstrom (1.267 nm), c=22.17 angstrom (2.217 nm), α=94.8°, β=88.4° and γ=94.8° or a=11.43 angstrom (1.143 nm), b=12.63 angstrom (1.263 nm), c=22.80 angstrom (2.280 nm), α=94.5°, β=88.3° and γ=94.8°, indicating a triclinic or monoclinic crystal structure to be apparent. FIG. 38 affords a and b, which are nearly equal to the values obtained by the X-ray diffraction measurements. Nevertheless, FIG. 38 affords γ, which is exceedingly smaller than the value obtained by the X-ray diffraction measurements. The c-axis of the organic semiconductor single crystal thin film 39 is nearly equal to the incident direction of the electron beam. Based on these results, it can be concluded that the facet of the organic semiconductor single crystal thin film 39 due to the planer TEM observation illustrated in FIG. 37 is the {110} plane.

FIG. 39 schematically illustrates a π-electron stacking structure of the organic semiconductor single crystal thin film 39 composed of C₂Ph-PXX in the a-axis direction. FIG. 39 schematically illustrates arrangement of main skeletons of C₂Ph-PXX such that the direction of the π-electron stacking is clear.

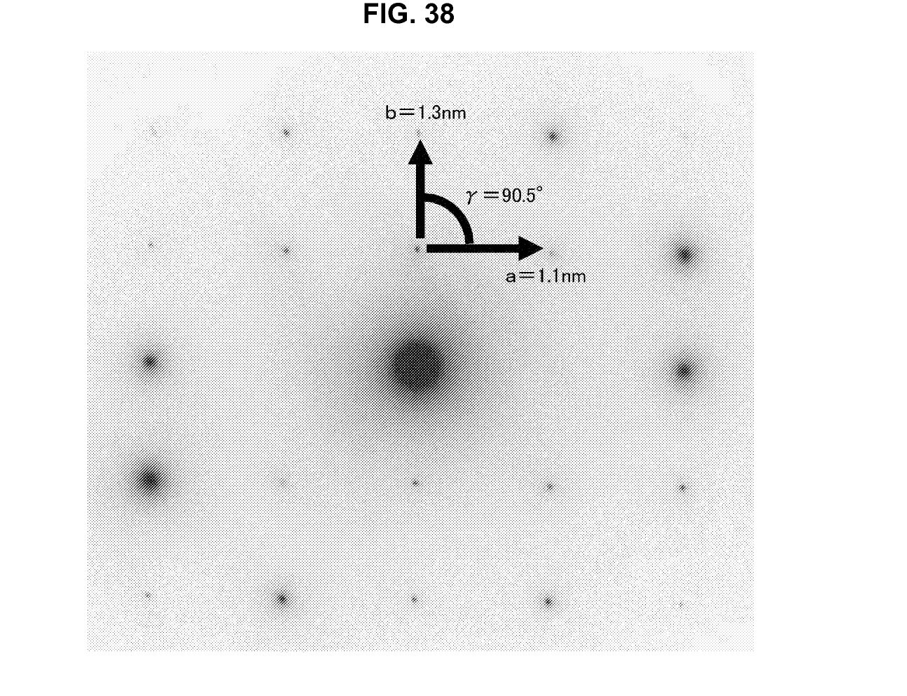

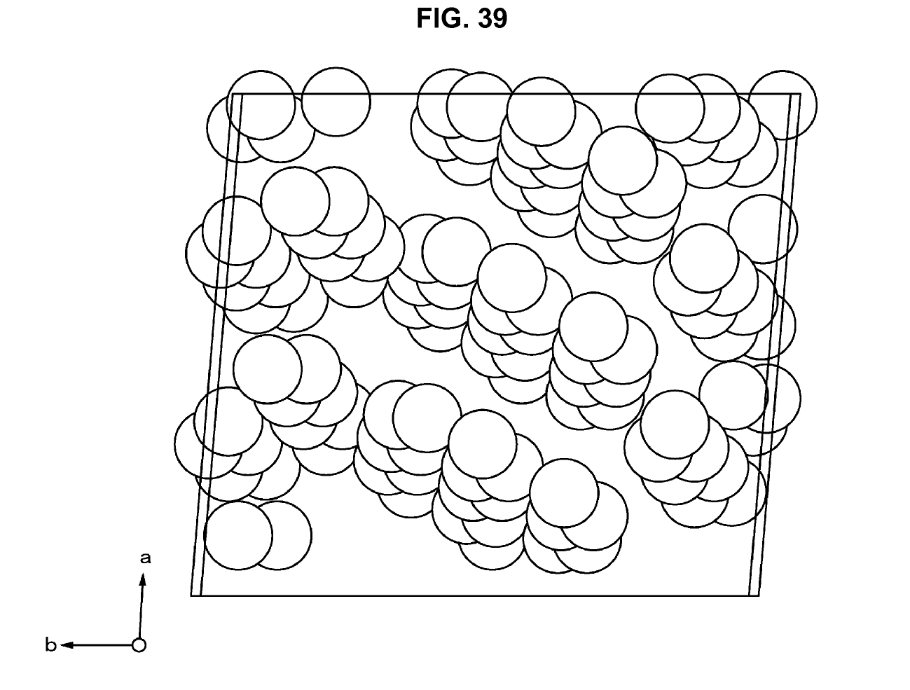

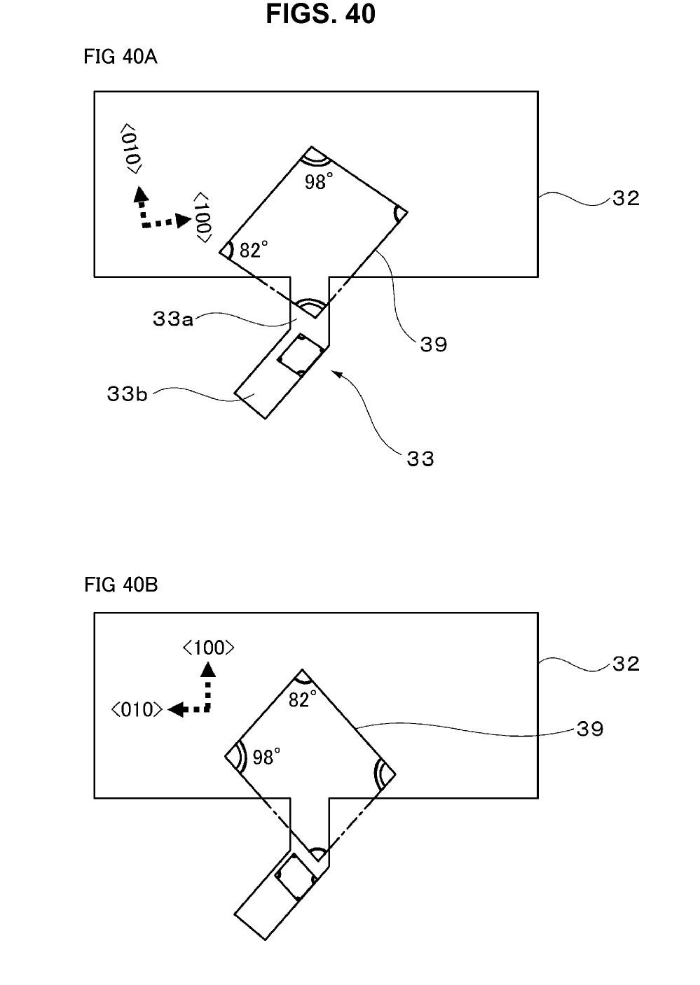

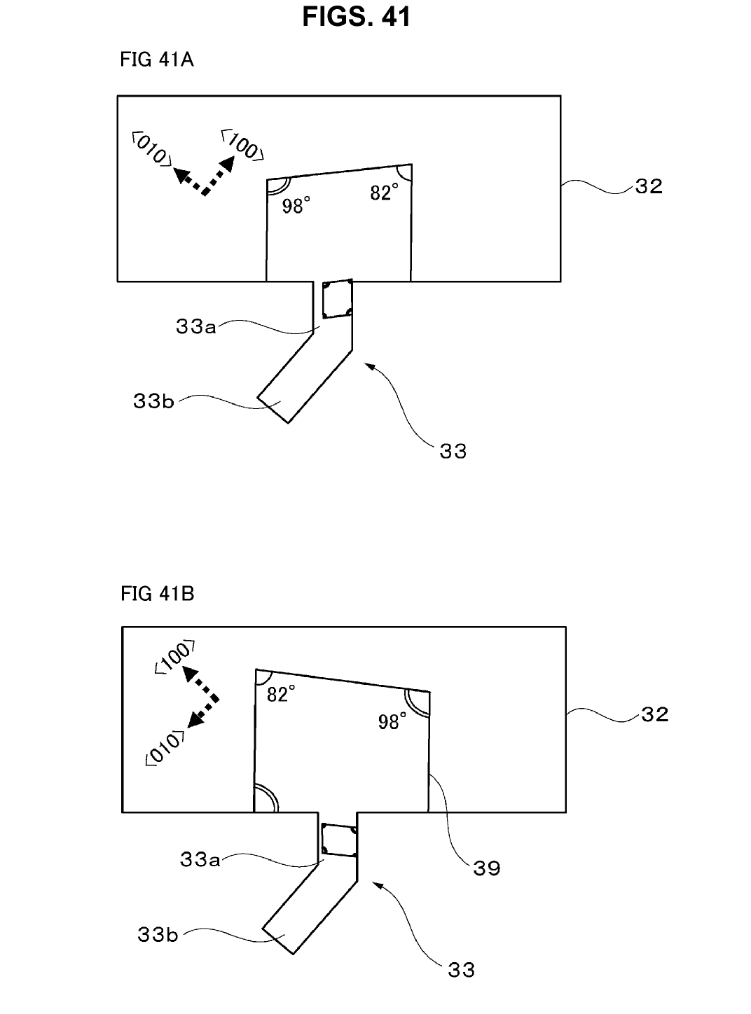

Based on the above results, a growth model of the organic semiconductor single crystal thin film 39 is considered. As described for the first embodiment, in the initial stage of growth, crystal nuclei are formed in the first part 33a or the second part 33b of the nucleation control region 33. FIG. 40A and FIG. 40B illustrate cases in each of which a crystal nucleus is formed in the second part 33b of the nucleation control region 33 and only one crystal has grown to close the second part 33b. In each of these cases, the crystal nucleus is formed to have a tetragonal shape enclosed by the {110} plane such that the a-axis or the b-axis of the crystal nucleus is parallel to the side wall of the second part 33b. Then, only one crystal having grown from the crystal nucleus closes the second part 33b, holding the crystal orientation of the crystal nucleus. The crystal thus having closed the second part 33b grows on the growth control region 32, and as a result, the organic semiconductor single crystal thin film 39 is allowed to grow on the growth control region 32. The organic semiconductor single crystal thin film 39 has a pentagonal shape which has the first vertex having a vertical angle of 82° and the second vertex having a vertical angle of 98° and whose four sides are parallel to the {110} plane. FIG. 41A and FIG. 41B illustrate cases in each of which a crystal nucleus is formed in the first part 33a of the nucleation control region 33 and only one crystal has grown to close the first part 33a. Similarly to the cases of FIG. 40A and FIG. 40B, the crystal nucleus is formed to have a tetragonal shape enclosed by the {110} plane such that the a-axis or the b-axis of the crystal is parallel to the side wall of the first part 33a. Then, the crystal growth proceeds on the growth control region 32, holding the crystal orientation of the crystal. As a result, the organic semiconductor single crystal thin film 39 having grown on the growth control region 32 has a tetragonal shape which has the first vertex having a vertical angle of 82° and the second vertex having a vertical angle of 98° and whose three sides are parallel to the {110} plane.

Comparing the shapes of the organic semiconductor single crystal thin films 39 on the growth control regions 32 illustrated in FIG. 20 to FIG. 33 with the shapes led from the above-mentioned growth model, they substantially coincide with the others with some variations. This can conclude that the growth of the organic semiconductor single crystal thin film 39 is explained by the above-mentioned growth model.

According to the second embodiment, the similar merit to that in the first embodiment can be attained.

### 3. Third Embodiment

### Growth Method of Organic Semiconductor Single Crystal Thin Film

In a third embodiment, patterns for the growth control region 32 and the nucleation control region 33 provided on the one principal plane of the substrate 31 as illustrated in FIG. 42 are used.

As illustrated in FIG. 42, in the third embodiment, the nucleation control region 33 is constituted of a third part 33c in a triangular shape whose first side is led from the one side 32a of the growth control region 32 and a fourth part 33d in a straight line shape which is coupled with the third part 33c at a vertex part opposite to the first side and inclines by the angle θ₁ of 0° or more and 90° or less, for example, 25° or more and 65° or less relative to the above-mentioned one side 32a of the growth control region 32. A second side 33e of the triangular third part 33c is on the same line as that on one side wall of the fourth part 33d and inclines by the angle θ₁ of 0° or more and 90° or less, for example, 25° or more and 65° or less relative to the above-mentioned one side 32a of the growth control region 32. The angle between the second side 33e and a third side 33f of the triangular third part 33c is defined depending on a crystal structure of the organic semiconductor single crystal thin film 39 and is exemplarily 98° or 82°. The cases of the angle between the second side 33e and the third side 33f of the third part 33c being 98° and 82° are illustrated in the left part of FIG. 42 and the right part of FIG. 42, respectively.

The width W₂ of the fourth part 33d is smaller than the width W₁ of the growth control region 32. In other words, the nucleation control region 33 in this case has a constant width W₂ in the fourth part 33d and a gradually increasing width W₂ in the third part 33c. Preferably, the width W₂ is selected sufficiently small and, for example, such selection is made as width W₂=0.1 to 30 μm. The length L₃ of the second side 33e of the third part 33a is selected, for example, as L₃=5 to 50 μm and the length L₄ of the fourth part 33d is selected, for example, as L₄=10 to 150 μm.

The shapes of the nucleation control regions 33 are selected as mentioned above, and thereby, in the initial stage of growth, crystal nuclei are formed on the fourth part 33d of the nucleation control region 33 and only one crystal grows to close the fourth part 33d. The crystal grows on the growth control region 32 through the third part 33a and the crystal growth proceeds such that the facet defined by the angle between the second side 33e and the third side 33f of the third part 33c arises during this. As a result, the organic semiconductor single crystal thin film 39 has grown in a tetragonal or pentagonal shape, for example, having the first vertex having a vertical angle of 82° and the second vertex having a vertical angle of 98°.

According to the third embodiment, the similar merit to that in the first embodiment can be attained.

### 4. Fourth Embodiment

### Growth Method of Organic Semiconductor Single Crystal Thin Film

In a fourth embodiment, patterns for the growth control region 32 and the nucleation control region 33 provided on the one principal plane of the substrate 31 as illustrated in FIG. 43 are used. As illustrated in FIG. 43, a plurality of growth control regions 32 are provided on the one principal plane of the substrate 31 (not shown) to be parallel to one another and to separate from one another. A plurality of nucleation control regions 33 are provided on each of the sides 32a of two neighboring growth control regions 32, out of these growth control regions 32, which sides oppose each other typically to be at a constant interval and not to overlap with one another. In this case, the nucleation control regions 33 for one growth control region 32 of the two growth control region 32 opposite to each other are provided to locate between the nucleation control regions 33 for the other growth control region 32. Moreover, the nucleation control regions 33 for the one growth control region 32 are provided to oppose and to be close to the nucleation control regions 33 for the other growth control region 32.

The fourth embodiment is similar to the first embodiment except the above.

According to the fourth embodiment, the following merit can be attained in addition to the similar merit to that in the first embodiment. Namely, The nucleation control regions 33 are provided on each of the sides of two neighboring growth control regions 32 which sides oppose each other not to overlap with one another. The nucleation control regions 33 for one growth control region 32 are provided close to the nucleation control regions 33 for the other growth control region 32. Due to this, while evaporation of the solvent of the organic solution 36 supplied to the growth control regions 32 is suppressed, evaporation of the solvent of the organic solution 36 supplied to the nucleation control regions 33 can be promoted, this improving the growth rate of the organic semiconductor single crystal thin films 39.

### 5. Fifth Embodiment

### Organic Transistor

In a fifth embodiment, an organic transistor and a manufacturing method of the same using the organic semiconductor single crystal thin film is described.

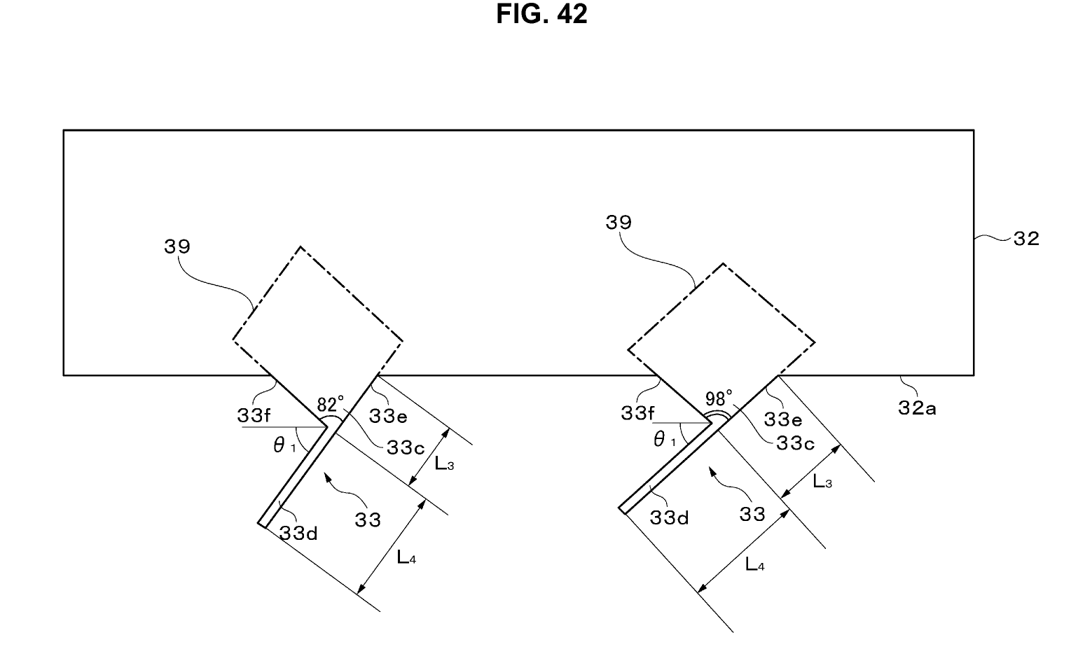

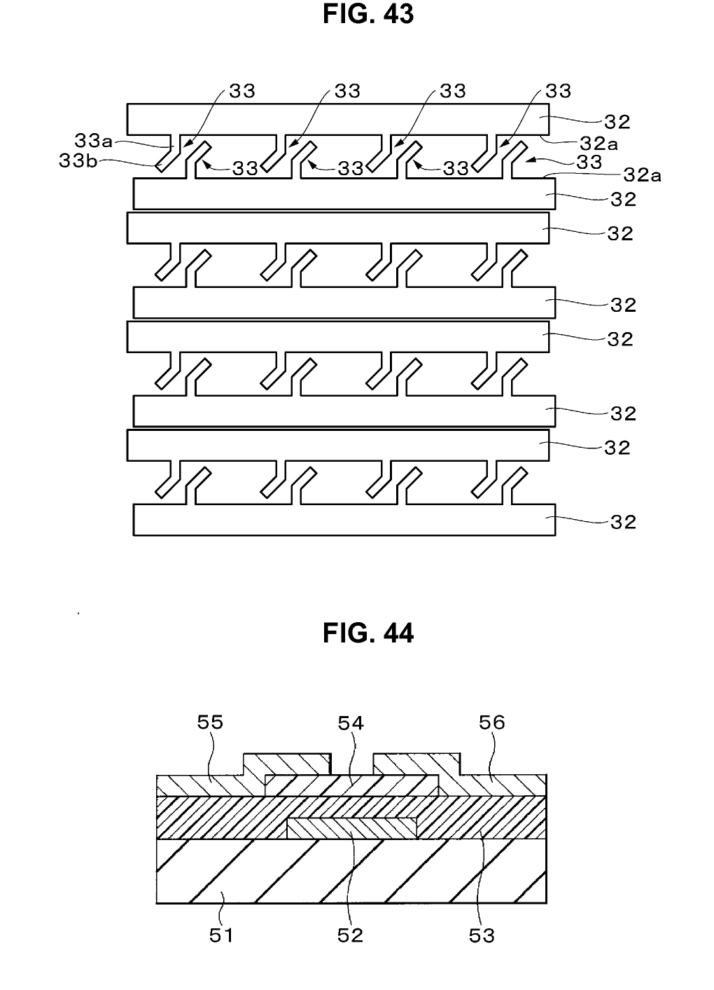

FIG. 44 illustrates the organic transistor. As illustrated in FIG. 44, a gate electrode 52 is provided on a substrate 51 in the organic transistor. A gate insulation film 53 is provided to cover the gate electrode 52. An organic semiconductor single crystal thin film 54 which is a channel region is provided on the gate insulation film 53. Furthermore, a source electrode 55 and a drain electrode 56 are provided on the organic semiconductor single crystal thin film 54. The gate electrode 52, organic semiconductor single crystal thin film 54, source electrode 55 and drain electrode 56 constitute a top contact and bottom gate-type organic transistor which has a configuration of an insulation gate-type field effect transistor.

Preferably, a channel length direction (direction from the source electrode 55 to the drain electrode 56) is configured to be a direction high in carrier mobility of the organic semiconductor single crystal thin film 54 in the organic transistor.

The organic semiconductor single crystal thin film 54 is composed of the already-mentioned organic compound. The gate insulation film 53 is composed, for example, of an inorganic insulator, organic insulator, organic insulative polymer, or the like. Examples of the inorganic insulator include, for example, silicon dioxide (SiO₂), silicon nitride (Si₃N₄ or SiNₓ) and the like. Examples of the organic insulator and the organic insulative polymer includes, for example, poly(vinylphenol), poly(methyl methacrylate), polyimide, fluorine resin, PVP-RSiCl₃, DAP, isoDAP, poly(α-methylstyrene), cycloolefin copolymer and the like. Thicknesses of the organic semiconductor single crystal thin film 54 and the gate insulation film 63 are properly selected according to characteristics and the like required for the organic transistor.

The material of the substrate 51 is selected from among conventionally known materials and may be a transparent material or an opaque material to visible light. Moreover, the substrate 51 may be conductive or non-conductive. Moreover, the substrate 51 may be flexible (resilient) or inflexible. Specifically, examples of the material of the substrate 51 include various kinds of plastics (organic polymers) such as poly(methyl methacrylate) (polymethyl methacrylate, PMMA), poly(vinylalcohol) (PVA), poly(vinylphenol) (PVP), polyethersulfone (PES), polyimide, polycarbonate, poly(ethylene telephthalate) (PET) and poly(ethylene naphthalate) (PEN), mica, various kinds of glass substrates, quartz substrates and silicon substrates, various kinds of alloy such as stainless steel, various kinds of metals, and the like. Using plastics as the material of the substrate 51 allows the substrate 51 to be flexible, eventually attaining a flexible organic transistor. The plastic substrate is composed, for example, of polyimide, polycarbonate, poly(ethylene telephthalate), poly(ethylene naphthalate), polyethersulfon, and the like.

Example of the materials composing the gate electrode 52, source electrode 55 and drain electrode 56 include, for example, metals such as platinum (Pt), gold (Au), palladium (Pd), chromium (Cr), molybdenum (Mo), nickel (Ni), aluminum (Al), silver (Ag), tantalum (Ta), tungsten (W), copper (Cu), titanium (Ti), indium (In) and tin (Sn), alloy containing these metal elements, conductive particles composed of these metals, conductive particles of alloy containing these metals, various kinds of conductive substances such as polysilicon containing impurity. The examples of the materials composing the gate electrode 52, source electrode 55 and drain electrode 56 also include organic conductive materials (conductive polymers) such as poly(3,4-ethylenedioxythiophene)/polystyrenesulfonic acid [PEDOT/PSS] and tetrathiafulvalene-7,7,8,8-tetracyanoquinodimethane (TTF-TCNQ). Each of the gate electrode 52, source electrode 55 and drain electrode 56 may have a layered structure constituted of two or more layers composed of these substances. The width of the gate electrode 52 in the channel length direction (gate length) and the distance between the source electrode 55 and drain electrode 56 (channel length) are selected according to characteristics and the like required for the organic transistor.

Manufacturing Method of Organic Transistor

As illustrated in FIG. 44, first, the gate electrode 52 is formed on the substrate 51, and after that, the gate insulation film 53 is formed on these by the conventionally known method.

Meanwhile, similarly to the first embodiment, the organic solution obtained by dissolving the organic compound in the solvent is prepared. Then, the organic semiconductor single crystal thin film 39 is allowed to grow on the gate insulation film 53 using the organic solution, for example, by any of the methods in the first to fourth embodiments.

Next, the organic semiconductor single crystal thin film 39 thus formed undergoes patterning into a predetermined shape using etching or the like, and after that, the source electrode 55 and drain electrode 56 are formed on the organic semiconductor single crystal thin film 39 by the conventionally known method.

As above, the desired top contact and bottom gate-type organic transistor is manufactured.

According to the fifth embodiment, since the crystal orientation of the organic semiconductor single crystal thin film 39 can be controlled, the direction high in carrier mobility of the organic semiconductor single crystal thin film 39 can be configured to the channel length direction, this attaining a high-performance organic transistor high in mobility.

### 6. Sixth Embodiment

### Layered Structure Body

In a sixth embodiment, various kinds of layered structure bodies including the organic semiconductor single crystal thin film are described. These layered structure bodies are used for various kinds of electronic elements.

In a layered structure body according to a first example illustrated in FIG. 45, an organic semiconductor single crystal thin film 62 and an organic semiconductor polycrystalline thin film 63 are layered on a substrate 61 sequentially. The conductive types of the organic semiconductor single crystal thin film 62 and the organic semiconductor polycrystalline thin film 63 may be any of p-type, n-type and i-type and are selected as needed. Electrodes or wires are provided on the organic semiconductor single crystal thin film 62 and the organic semiconductor polycrystalline thin film 63 as needed. The substrate 61 can employ, for example, similar ones to the substrate 51 in the fifth embodiment and is selected as needed (this applies to the following examples). The organic semiconductor single crystal thin film 62 can be allowed to grow, for example, similarly to the first to fourth embodiments. The organic semiconductor polycrystalline thin film 63 can be allowed to grow by various kinds of methods, for example, solution growth (liquid phase growth), gas-phase growth, vacuum deposition and the like.

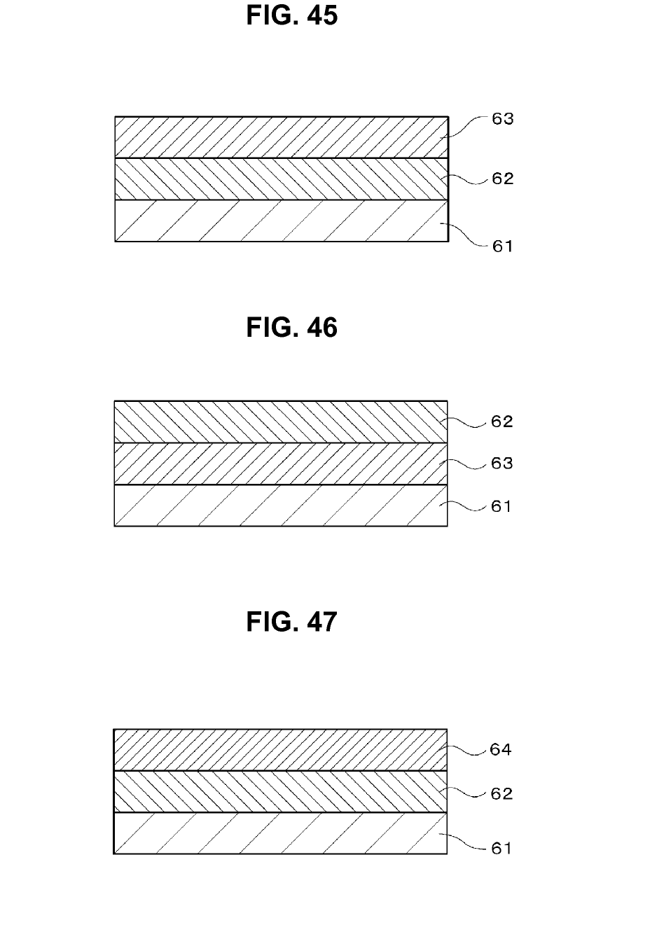

In a layered structure body according to a second example illustrated in FIG. 46, the organic semiconductor polycrystalline thin film 63 and the organic semiconductor single crystal thin film 62 are layered on the substrate 61 sequentially. Namely, the layering order of the organic semiconductor single crystal thin film 62 and the organic semiconductor polycrystalline thin film 63 is reverse to that of the layered structure body illustrated in FIG. 45.

In a layered structure body according to a third example illustrated in FIG. 47, the organic semiconductor single crystal thin film 62 and an inorganic thin film 64 composed of inorganic material are layered on the substrate 61 sequentially. The conductivity type of the organic semiconductor single crystal thin film 62 may be any of p-type, n-type and i-type and is selected as needed. The inorganic thin film 64 may be conductive or insulative and is selected as needed. The organic semiconductor single crystal thin film 62 can be allowed to grow, for example, similarly to the first to fourth embodiments. The inorganic thin film 64 can be allowed to grow by various kinds of methods, for example, solution growth (liquid phase growth), chemical vapor deposition, vacuum deposition, sputtering and the like.

In a layered structure body according to a fourth example illustrated in FIG. 48, the inorganic thin film 64 composed of inorganic material and the organic semiconductor single crystal thin film 62 are layered on the substrate 61 sequentially. Namely, the layering order of the organic semiconductor single crystal thin film 62 and the inorganic thin film 64 is reverse to that of the layered structure body illustrated in FIG. 47.

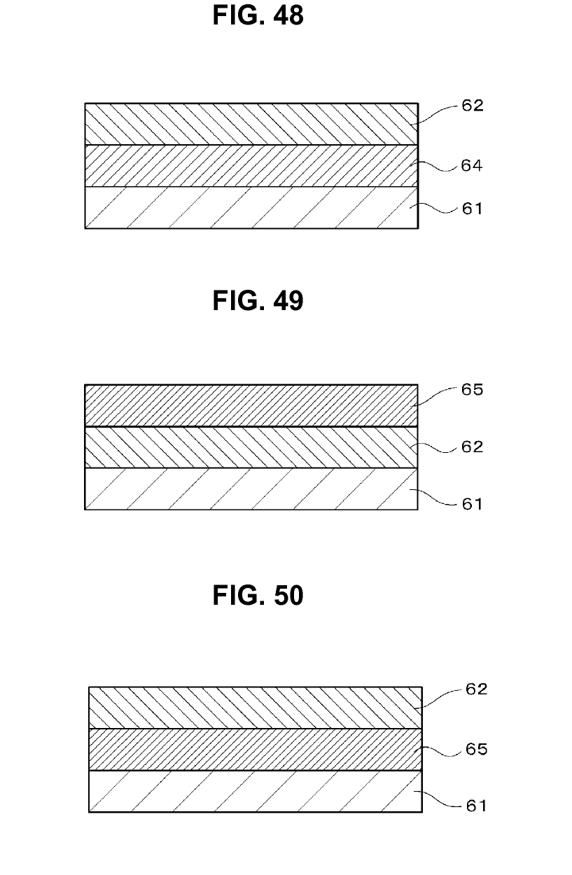

In a layered structure body according to a fifth example illustrated in FIG. 49, the organic semiconductor single crystal thin film 62 and an organic semiconductor single crystal thin film 65 different from the organic semiconductor single crystal thin film 62 are layered on the substrate 61 sequentially. The organic semiconductor single crystal thin films 62 and 65 can be allowed to grow, for example, similarly to the first to fourth embodiments. The layered structure body can be applied, for example, to various kinds of semiconductor elements using hetero-junction such as a light-emitting diode (LED), a semiconductor laser and a hetero-interface FET (HIFET). Moreover, further layering one organic semiconductor single crystal thin film can attain a hetero junction bipolar transistor (HBT) and the like, for example.

In a layered structure body according to a sixth example illustrated in FIG. 50, the organic semiconductor single crystal thin film 65 and the organic semiconductor single crystal thin film 62 are layered on the substrate 61 sequentially. Namely, the layering order of the organic semiconductor single crystal thin films 62 and 65 is reverse to that of the layered structure body illustrated in FIG. 49.

In a layered structure body according to a seventh example illustrated in FIG. 51, the organic semiconductor single crystal thin film 65 and the organic semiconductor single crystal thin film 62 are layered on the substrate 61 in this order similarly to the layered structure body illustrated in FIG. 50 and the upper-layer organic semiconductor single crystal thin film 62 is smaller than the lower-layer organic semiconductor single crystal thin film 65. A lead-out part 65a is provided at one end of the lower-layer organic semiconductor single crystal thin film 65. A lead-out part 62a is provided at one end of the upper-layer organic semiconductor single crystal thin film 62 opposite to that of the lead-out part 65a of the organic semiconductor single crystal thin film 65. The lead-out parts 62a and 65a can be used, for example, for regions in which electrodes or wires are formed.

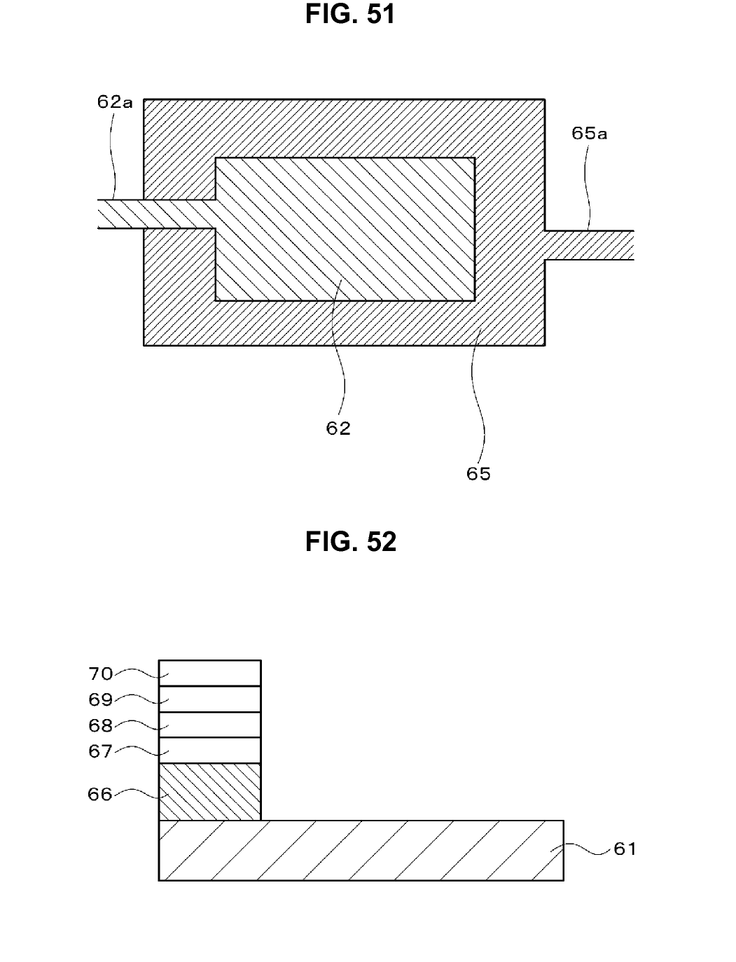

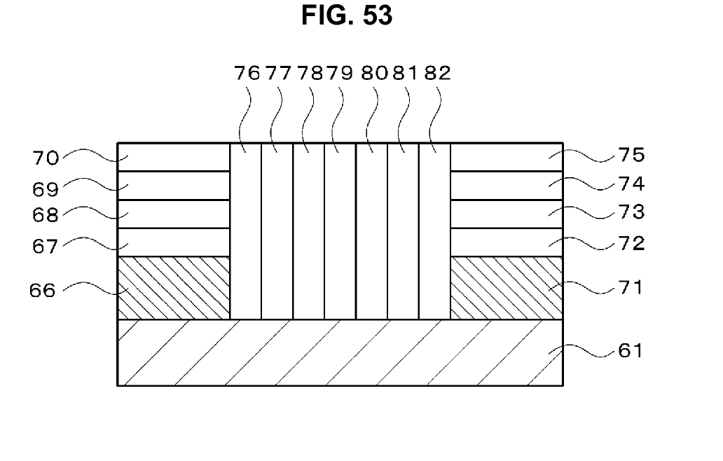

In a layered structure body according to an eighth example illustrated in FIG. 52, an electrode 66 is formed on the substrate 61, and thereon, thin films 67 to 70 are layered sequentially. At least one layer of the thin films 67 to 70 is an organic semiconductor single crystal thin film. The organic semiconductor single crystal thin film can be allowed to grow, for example, similarly to the first to fourth embodiments. Thin films of the thin films 67 to 70 other than the organic semiconductor single crystal thin film can be allowed to grow by various kinds of methods, for example, solution growth (liquid phase growth), chemical vapor deposition, vacuum deposition, sputtering and the like.

In a layered structure body according to a ninth example illustrated in FIG. 53, electrodes 66 and 71 are provided separate from each other on the substrate 61. The thin films 67 to 70 are layered on the electrode 66 sequentially. Thin films 72 to 75 are layered on the electrode 71 sequentially. At least one layer of the thin films 67 to 70 is an organic semiconductor single crystal thin film. Moreover, at least one layer of the thin films 72 to 75 is an organic semiconductor single crystal thin film. Furthermore, thin films 76 to 82 whose film surfaces are substantially in the perpendicular direction to one principal plane of the substrate 61 are provided sequentially in the parallel direction to the one principal plane of the substrate 61 on the part of the substrate 61 between the electrodes 66 and 71.

According to the sixth embodiment, a layered structure body which is a base of various kinds of electronic elements such as an organic transistor, a light-emitting diode (LED) and a semiconductor laser can be obtained.

### 7. Seventh Embodiment

### Growth Method of Organic Semiconductor Single Crystal Thin Film

In a seventh embodiment, a growth method of a large-area organic semiconductor single crystal thin film is described.

As described in reference to FIG. 8 and FIG. 9, the smaller the width of the comb tooth parts P₂ (nucleation control regions) in the comb-shape pattern P, for example, illustrated in FIG. 3A, FIG. 3B and FIG. 3C is, with the more tendency the orientations of the organic semiconductor single crystal thin films F having grown from the crystals C formed in the comb tooth parts P₂ coincide with one another.

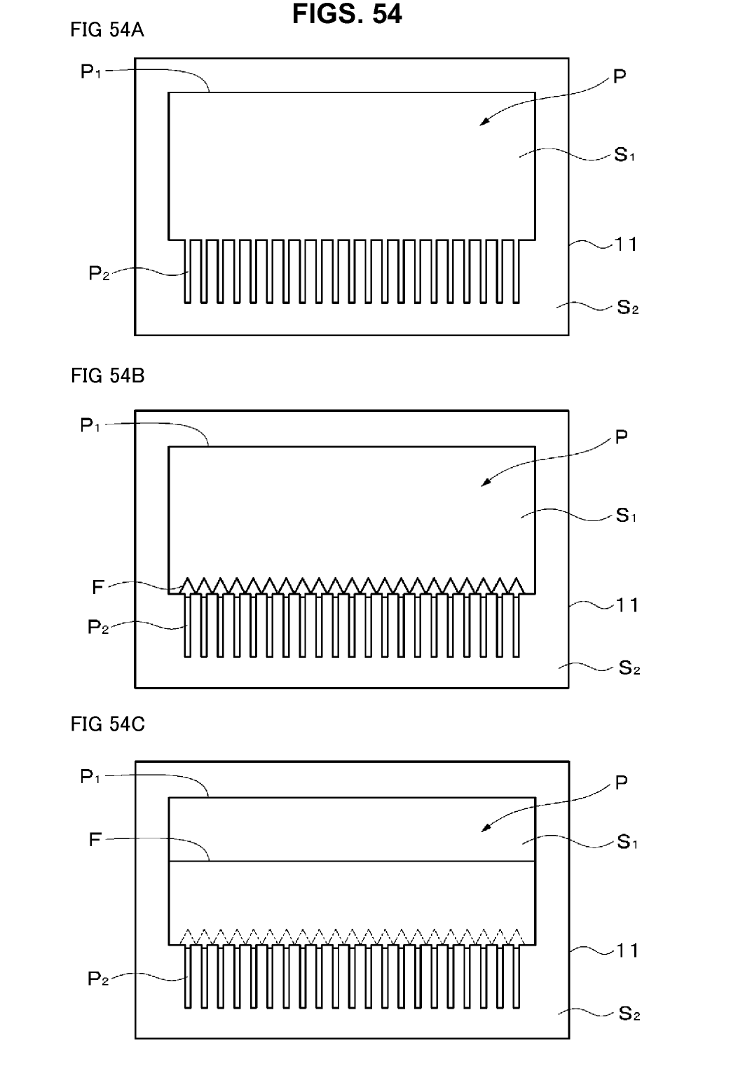

Therefore, in the seventh embodiment, first, the comb-shape pattern P in which the width of the comb tooth parts P₂ is small (for example, a width of 5 μm) and the spacing between the comb tooth parts P₂ is small as illustrated in FIG. 54A is formed.

Next, similarly to the first embodiment, crystals are allowed to grow at the bases of the comb tooth parts P₂ as illustrated in FIG. 54B to allow the organic semiconductor single crystal thin films F to grow from the crystals on the back part P₁.

The growth proceeding, due to the small spacing between the comb tooth parts P₂, the organic semiconductor single crystal thin films F having grown from the bases of the comb tooth parts P₂ are combined with one another in the parallel direction to the side of the comb-shape pattern P which side is in its longitudinal direction, and additionally, the orientations of the organic semiconductor single crystal thin films F coincide with one another due to the small width of the comb tooth parts P₂, this affording a single organic semiconductor single crystal thin film F in a long and thin shape. Conversely, the spacing between the comb tooth parts P₂ is selected such that the organic semiconductor single crystal thin films F having grown from the bases of the comb tooth parts P₂ are combined with one another in a short time after the growth. The growth further proceeding, a large-area rectangular organic semiconductor single crystal thin film F which has the same width as the width of the back part P₁ in its longitudinal direction on the back part P₁ of the comb-shape pattern P as illustrated in FIG. 54C has grown. The organic semiconductor single crystal thin film F thus having grown has not only a large area but also a small thickness.

As mentioned above, according to the seventh embodiment, a merit that a large-area organic semiconductor single crystal thin film F is allowed to grow can be attained as well as the similar merit to that in the first embodiment.

### 8. Eighth Embodiment

### Growth Method of Organic Semiconductor Single Crystal Thin Film

In an eighth embodiment, a growth method of a large-area organic semiconductor single crystal thin film is described similarly to the seventh embodiment.

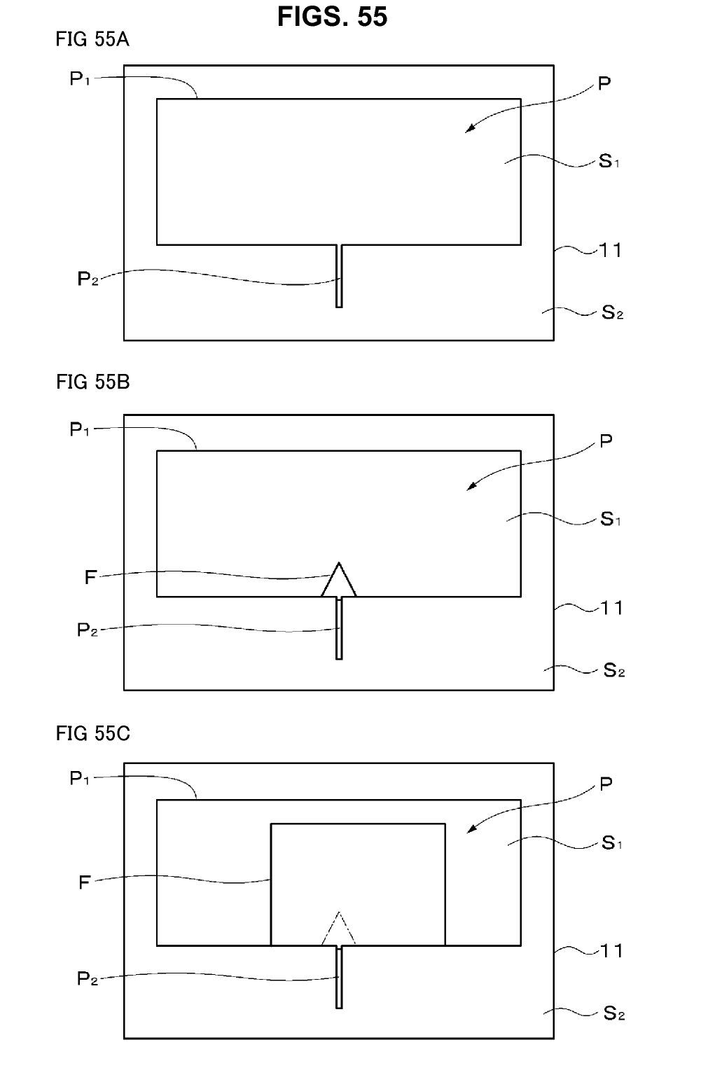

In the eighth embodiment, first, the comb-shape pattern P in which the width of the comb tooth part P₂ is small (for example, a width of 5 μm) as illustrated in FIG. 55A is formed on the substrate 11.

Next, as illustrated in FIG. 55B, the substrate 11, which is normally placed parallel to the horizontal plane, is placed such that the longitudinal direction of the comb-shape pattern P inclines by a predetermined angle relative to the horizontal plane. The inclination angle is properly selected according to the organic solution in use and the like and is, for example, 1° or more and 20° or less, preferably 5° or more and 20° or less. Then, the substrate 11 held to incline, a crystal is allowed to grow at the base of the comb tooth part P₂ similarly to the first embodiment to allow the organic semiconductor single crystal thin film F to grow from the crystal on the back part P₁. At this stage, the organic solution flows downstream of the inclination direction due to the inclination of the substrate 11.

The growth further proceeding, as illustrated in FIG. 55C, a large-area organic semiconductor single crystal thin film F grows on the back part P₁ of the comb-shape pattern P to extend in the longitudinal direction of the back part P₁. The reason for the large-area organic semiconductor single crystal thin film F growing as above can be considered as follows. As a consequence of a flow of the organic solution downstream of the inclination direction of the substrate 11, the organic solution spreads and its thickness decreases, causing the surface area of the organic solution to increase and the amount of the organic solvent evaporating from the surface of the organic solution to increase. Since the degree of supersaturation of the organic solution increase due to this, the state of the organic solution tends to be “metastable” (FIG. 1). Accordingly, it can be considered that molecules of the organic compound which is the raw material are supplied to the step end of the organic semiconductor single crystal thin film F and that a large and thin organic semiconductor single crystal thin film F is obtained. Moreover, as a consequence of the flow of the organic solution in the inclination direction of the substrate 11 under such conditions, the organic semiconductor single crystal thin film F grows in asymmetry in the horizontal direction relative to the comb tooth part P₂, and specifically, the width of the downstream side of the organic solution flow is larger than that of the upstream side thereof.

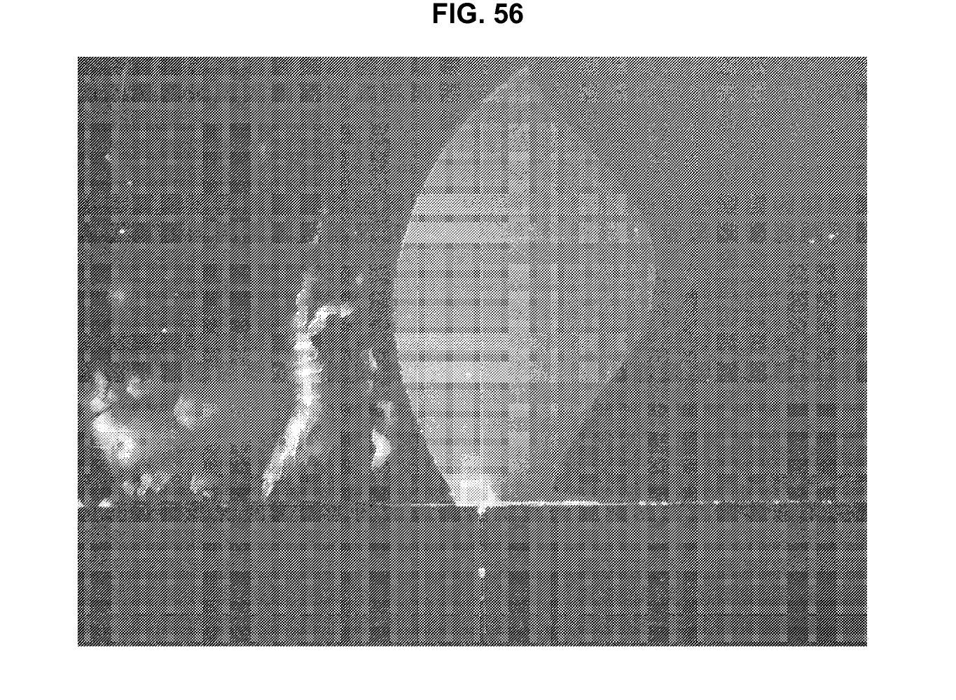

FIG. 56 illustrates an example of growth of the organic semiconductor single crystal thin film F on the substrate 11 which inclines actually. The organic semiconductor single crystal thin film F employed a C₂Ph-PXX thin film. As illustrated in FIG. 56, a large-area organic semiconductor single crystal thin film has grown. It is apparent that the organic semiconductor single crystal thin film has grown such that the width of the downstream side of the organic solution flow is larger than that of the upstream side thereof as to the comb tooth part.

According to the eighth embodiment, the similar merit to the seventh embodiment can be attained.

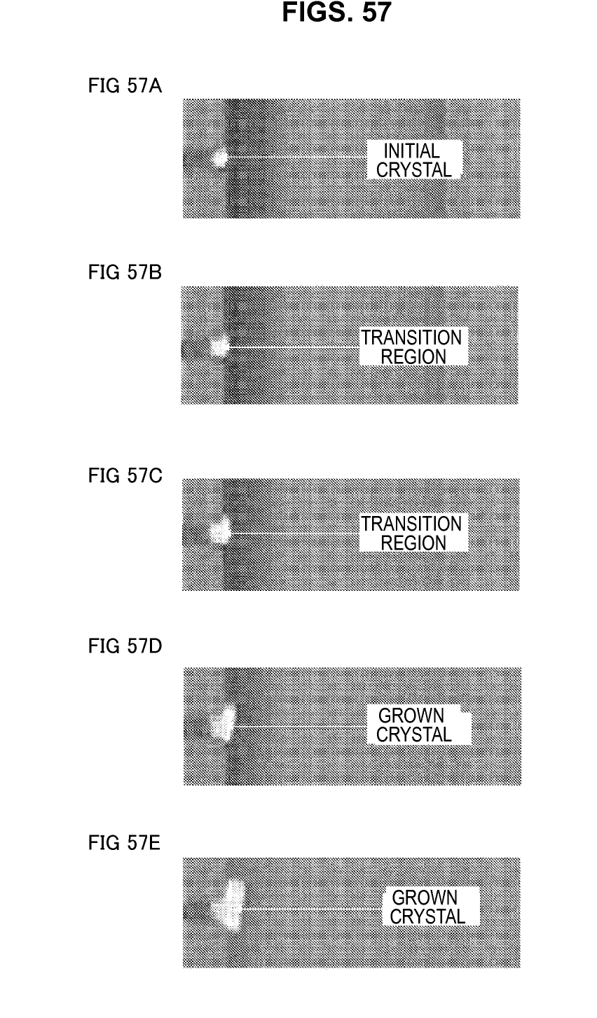

It is imaged that the crystal C (initial crystal) grows at the base of the comb tooth part P₂ of the comb-shape pattern P and the organic semiconductor single crystal thin film F has grown from the crystal C in the first embodiment, and herein, the results are described. The organic semiconductor single crystal thin film F employs a C₂Ph-PXX thin film. FIG. 57A, FIG. 57B, FIG. 57C, FIG. 57D and FIG. 57E illustrate the results, which are obtained by imaging the initial stage employed is employed of the crystal growth by a video camera and editing it into 5 frames. Time proceeds from FIG. 57A toward FIG. 57E. As illustrated in FIG. 57A, FIG. 57B, FIG. 57C, FIG. 57D and FIG. 57E, it is apparent that the initial crystal grows at the base of the comb tooth part to close the comb tooth part and that the organic semiconductor single crystal thin film is gradually growing from the initial crystal toward the back part. The observation results provide a support for validity of the already-described growth mechanism of the organic semiconductor single crystal thin film.

Next, the process of the growth of the organic semiconductor single crystal thin film (grown crystal) from the initial crystal having grown at the base of the comb tooth part of the comb-shape pattern was studied in detail and the results are described. The organic semiconductor single crystal thin film employed a C₂Ph-PXX thin film.

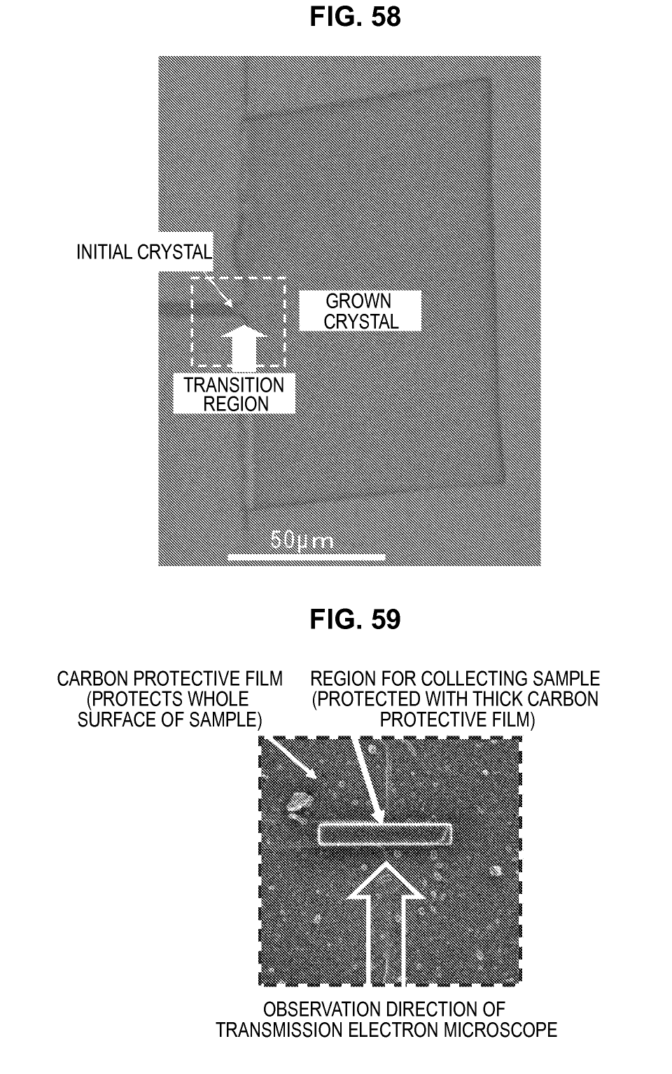

FIG. 58 presents an optical microscope image of growth of the grown crystal from the initial crystal having grown at the base of one comb tooth part. Detailed inspection of the optical microscope image presents the existence of a transition region between the initial crystal and the grown crystal.

FIG. 59 presents an enlarged optical microscope image of the region enclosed by the broken-lined square in FIG. 58. The sample was protected by forming a carbon protective film on its whole area, and particularly, the center part of the region which part is a long and thick rectangle was protected by forming a thick carbon protective film on its surface. The region on which the thick carbon protective film was formed was cut out to collect an electron microscope observation sample. Then, the electron microscope observation sample was observed in the direction indicated by the arrow in FIG. 59 by a transmission electron microscope.

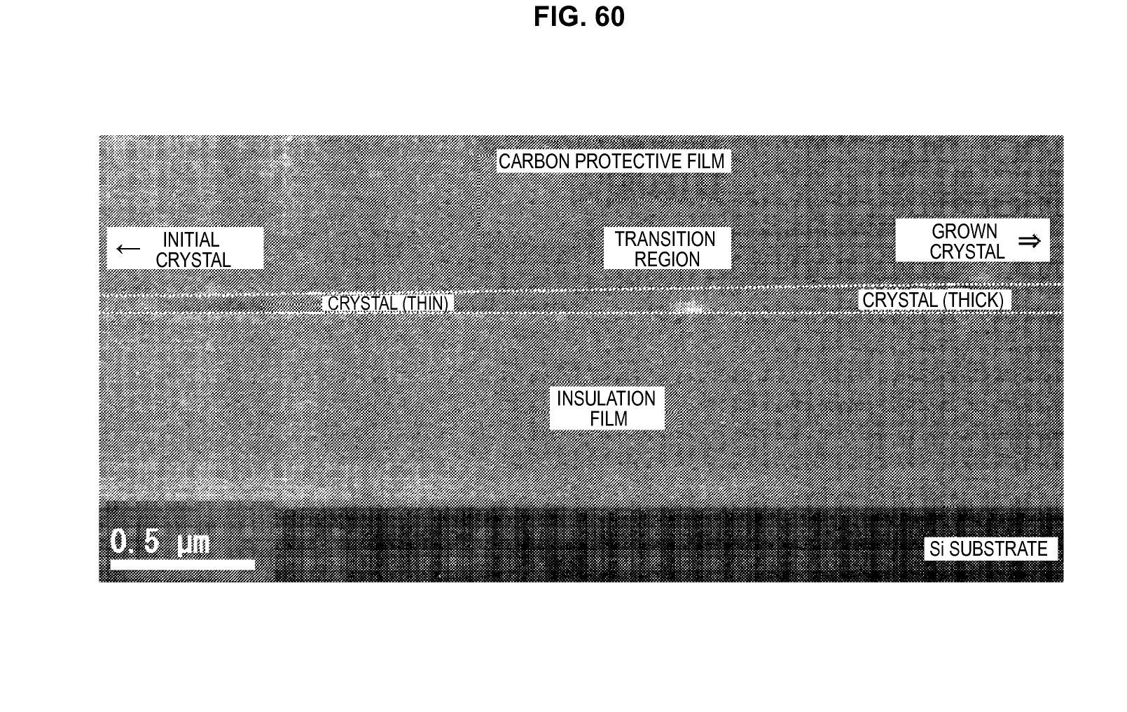

FIG. 60 presents a cross-sectional transmission electron microscope image (low magnification image) presenting a cross-sectional mode in the vicinity of the transition region in the electron microscope observation sample. As illustrated in FIG. 60, the thickness of the crystal gradually increases from the initial crystal toward the grown crystal in the transition region between the initial crystal and the grown crystal. In addition, the insulation film in FIG. 60 is a SiO₂ film formed on the surface of the Si substrate (Si wafer) (this also applies to the followings).

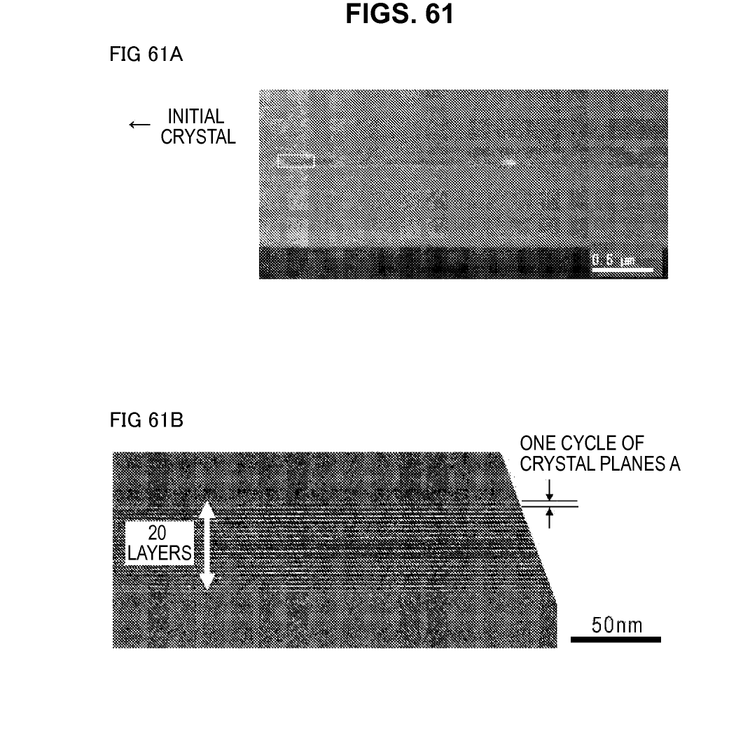

FIG. 61B presents a cross-sectional transmission electron microscope image of the part of the initial crystal in the electron microscope observation sample illustrated in FIG. 61A which part is enclosed by the rectangle. In FIG. 61B, approximately 20 layers of crystal planes (presented as crystal planes A) are observed and one cycle of them corresponds to one molecular layer. As illustrated in FIG. 61B, the crystal planes A are substantially parallel to the surface of the crystal.

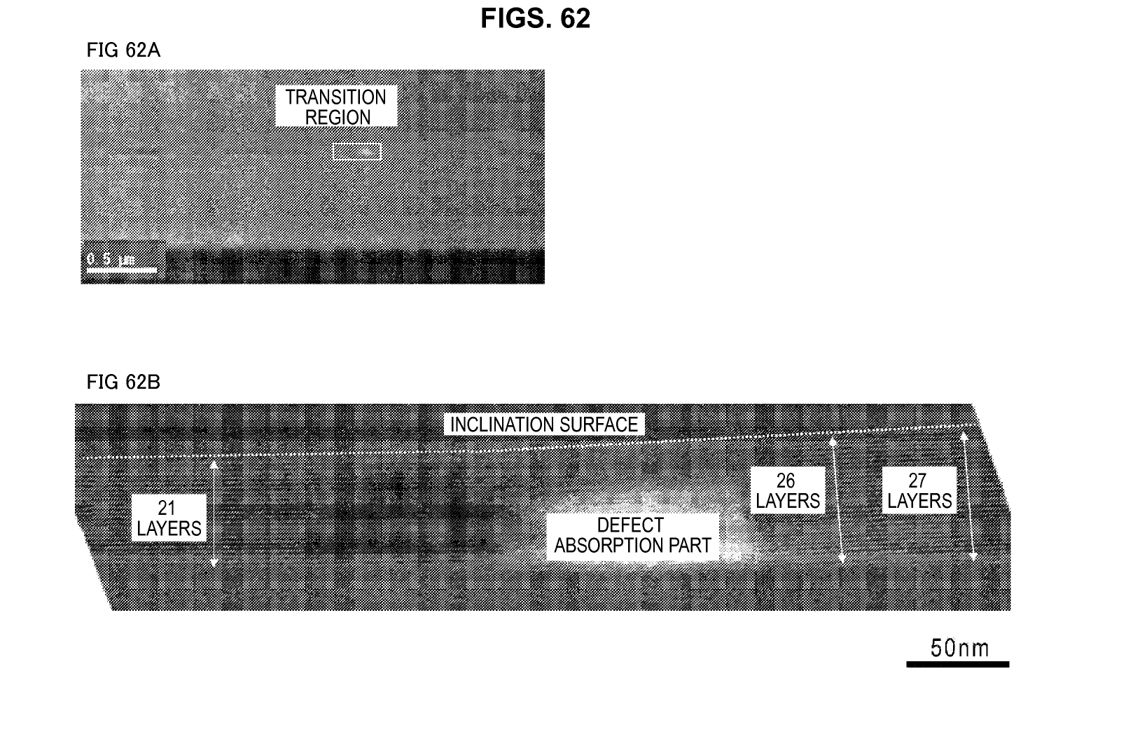

FIG. 62B presents a cross-sectional transmission electron microscope image of the part of the transition region in the electron microscope observation sample illustrated in FIG. 62A which part is enclosed by the rectangle. As illustrated in FIG. 62B, in the transition region, molecular layers constituting the crystal increase from 21 layers to 26 layers, this causing the surface of the crystal to incline. The part presenting the contrast to be white is observed on the substrate side in the part of the transition region having the inclination surface, presenting a porous region (a porous region presents contrast to be white in a transmission electron microscope image). The porous region is considered to be a defect absorption part absorbing crystal defect. In other words, it is considered that, when the grown crystal grows from the initial crystal, the crystal defect arises in the transition region to absorb distortion, this allowing the excellent growth of the grown crystal.

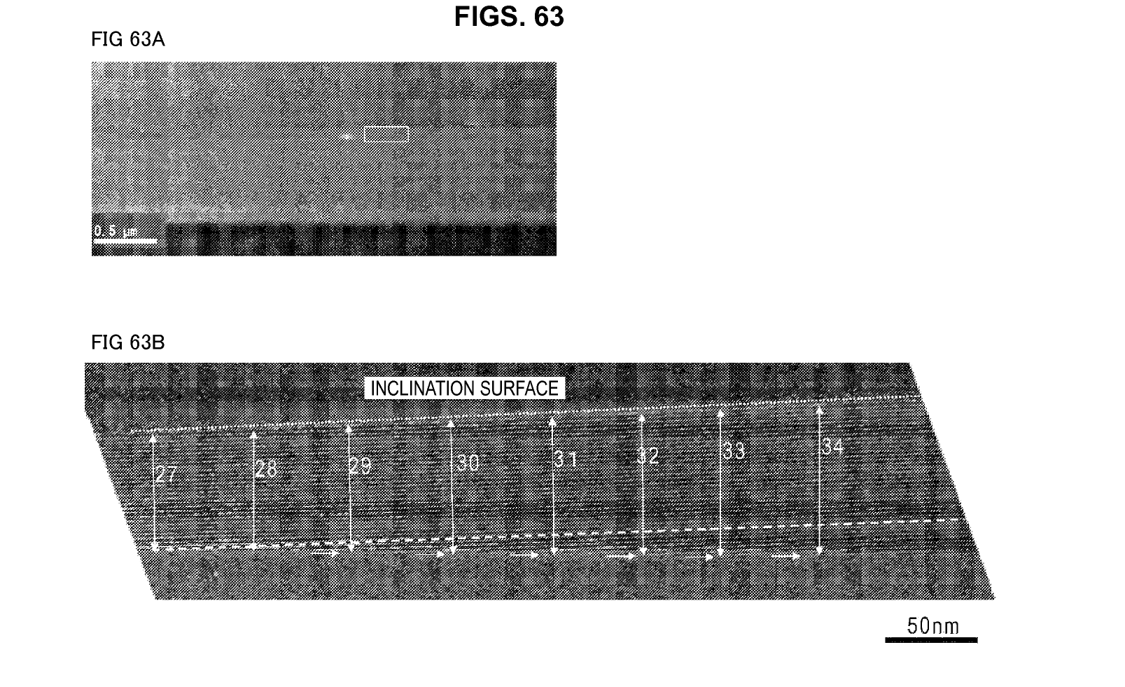

FIG. 63B presents a cross-sectional transmission electron microscope image of the part of the transition region in the electron microscope observation sample illustrated in FIG. 63A which part is enclosed by a rectangle. As illustrated in FIG. 63B, in the part of the transition region which part has the inclination surface, the crystal planes A are substantially parallel to the inclination surface and the molecular layers increase one by one in the direction from the initial crystal to the grown crystal, starting from 27 layers. Accordingly, the steps are observed on the substrate side as indicated by the arrows in FIG. 63B.

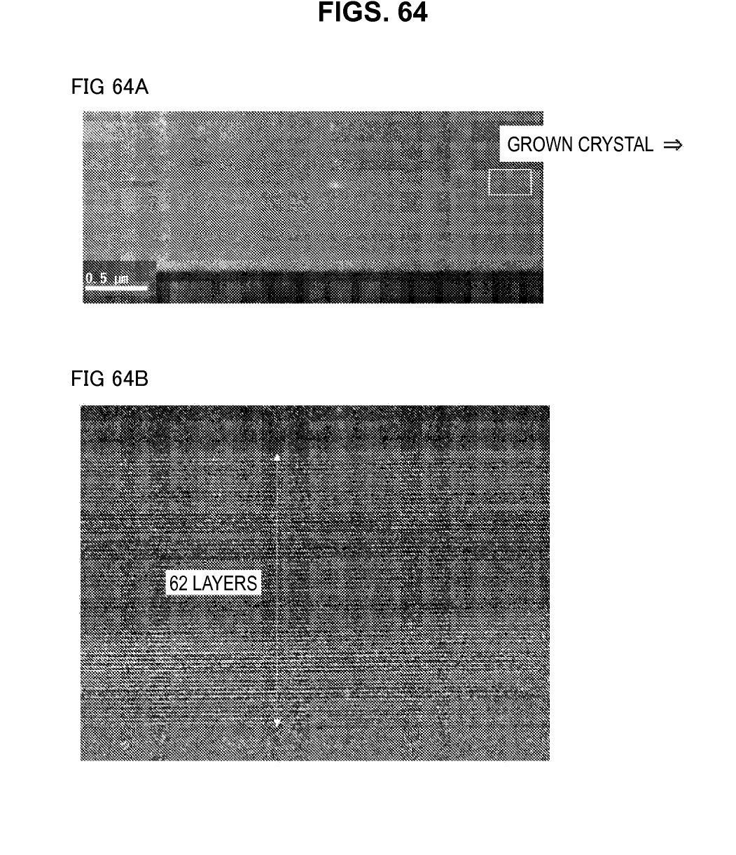

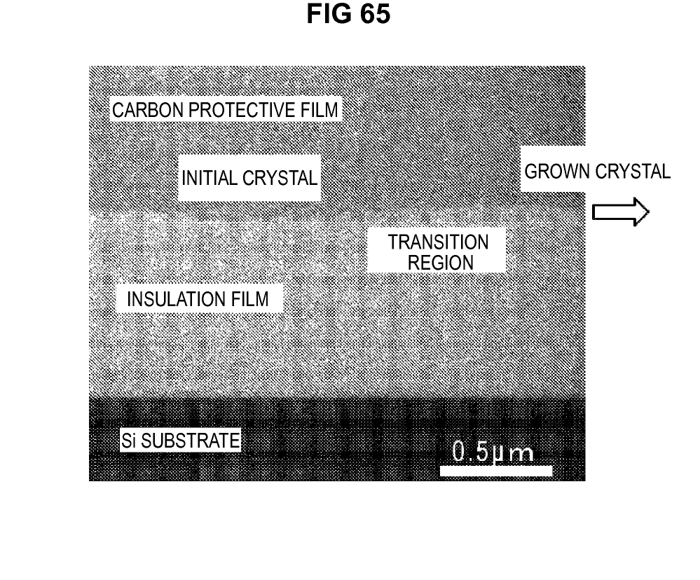

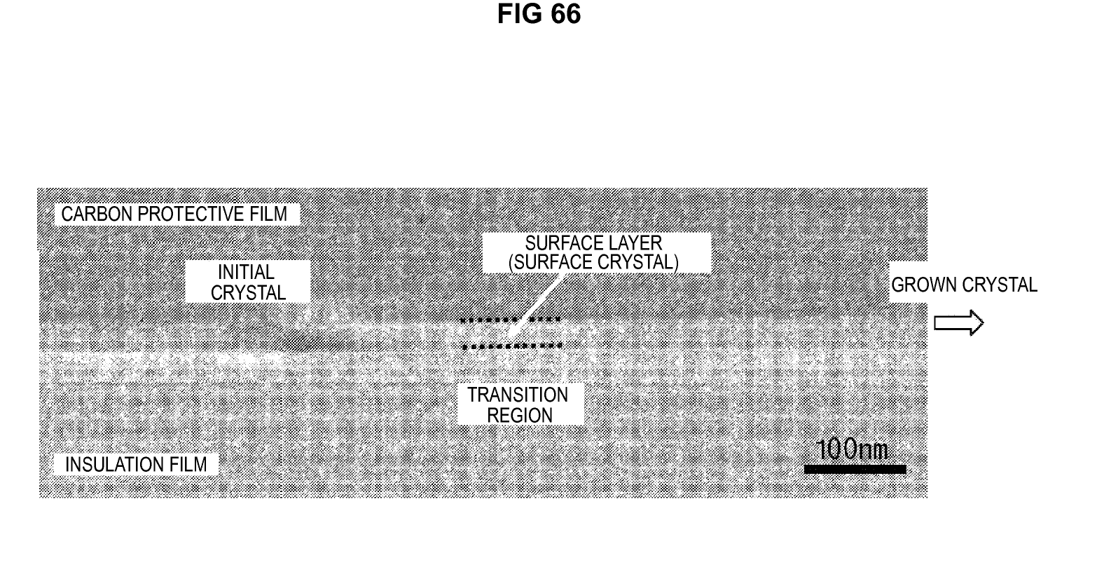

FIG. 64B presents a cross-sectional transmission electron microscope image of the part of the grown crystal in the electron microscope observation sample illustrated in FIG. 64A which part is enclosed by the rectangle. As illustrated in FIG. 64B, in the part of the grown crystal, the crystal has the surface substantially parallel to the substrate surface and the crystal planes A are substantially parallel to the crystal surface. The molecular layers constituting the grown crystal are 62 layers.

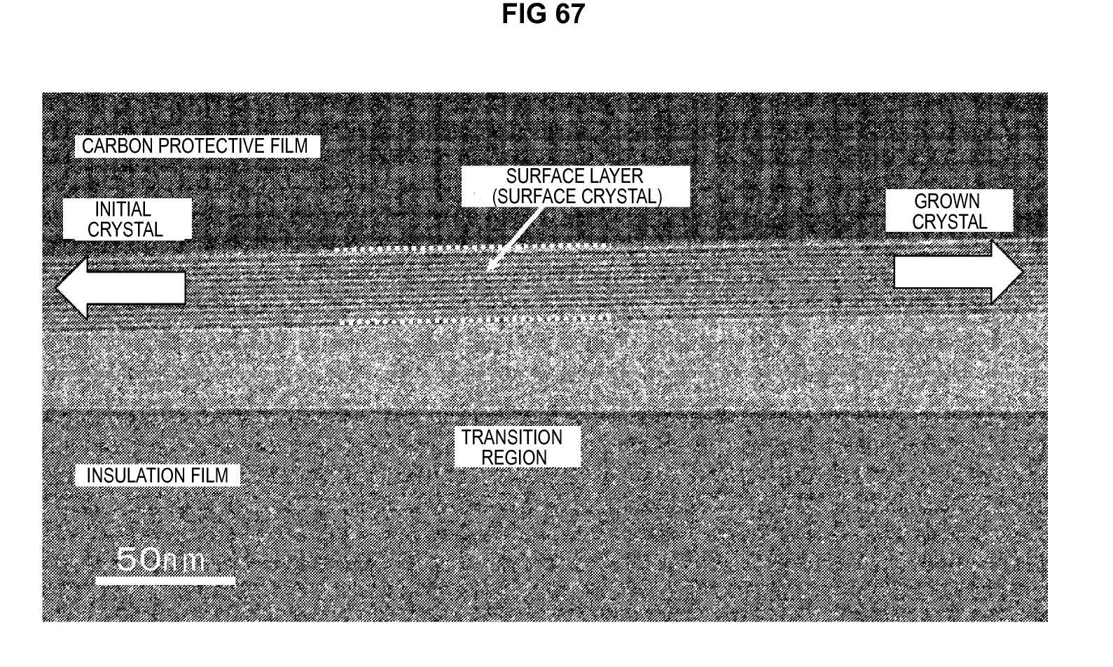

An electron microscope observation sample was prepared similarly to the above except the growth temperature forcibly lowered in the middle of the growth from the organic solution and the cross-sectional transmission electron microscope observation was performed, and the results are described. FIG. 65 presents a cross-sectional transmission electron microscope image of the electron microscope observation sample. FIG. 66 is an enlarged cross-sectional transmission electron microscope image of a cross section of a part in the vicinity of the transition region in the electron microscope observation sample. As illustrated in FIG. 66, both of the initial crystal and the crystal in the transition region are separate into two layers of upper and lower ones. FIG. 67 presents an enlarged cross-sectional transmission electron microscope image of the transition region. As illustrated in FIG. 67, although crystal planes parallel to the surface are definitely observed in the upper layer part of the crystal (surface crystal), crystal planes are not observed in the lower layer part thereof, this indicating no single crystal therein. These observation results provide a support for the crystal growth from the organic solution starting from the surface of the organic solution. Namely, evaporation of the organic solvent from the surface of the organic solution allows the surface of the organic solution first to be in supersaturation. This will be discussed later again.

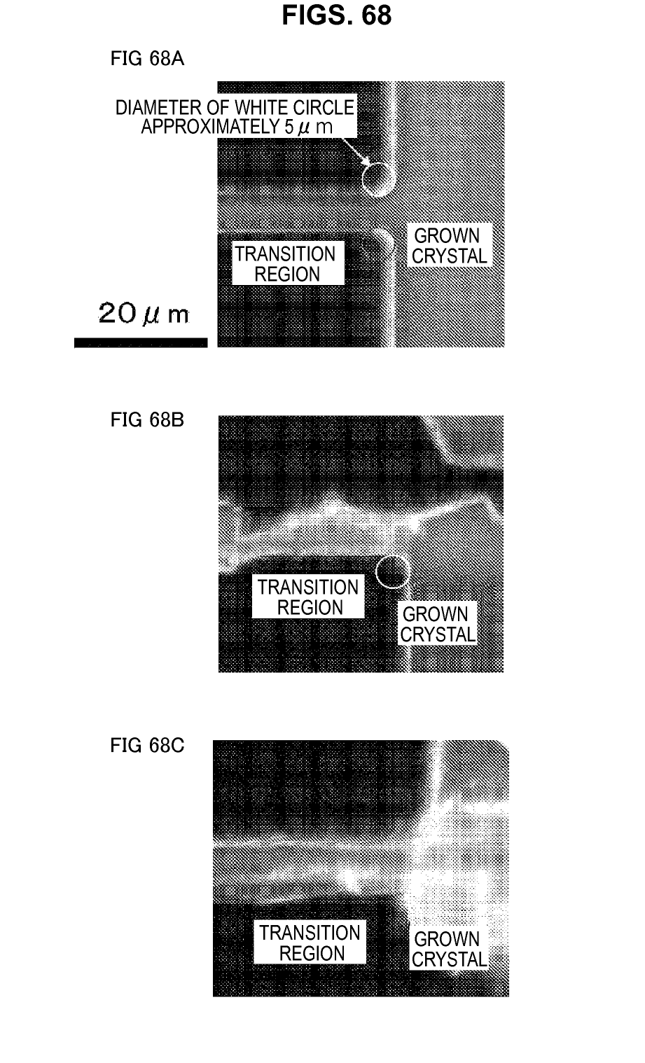

Next, the planar shape of the coupling part of the transition region and the grown crystal while the grown crystal is growing from the initial crystal via the transition region is described. FIG. 68A presents an optical microscope image of the coupling part of the transition region and the grown crystal when an excellent grown crystal is obtained. As illustrated in FIG. 68A, both sides of the coupling part of the transition region and the grown crystal have shapes bending into arc shapes. The curvature radius of the bending part is approximately 2.5 μm. FIG. 68B presents a bending shape bending into an arc shape only on one side of the coupling part of the transition region and the grown crystal. In this case, the part of the coupling part with the transition region which part has the arc shape out of the grown crystal has disorder in the crystal suppressed, this affording an excellent grown crystal in a single crystal. FIG. 68C presents no bending shapes bending in arc shapes on both sides of the coupling part of the transition region and the grown crystal. As illustrated in FIG. 68C, in this case, disorder in the crystal within the transition region leads down to the grown crystal, and as a result, the grown crystal is not excellently crystalline. The above observation results implies that growth of an excellently crystalline grown crystal desirably require at least one side of the coupling part of the transition region and the grown crystal, preferably, both sides thereof having bending shapes into arc shapes.

Next, based on the results of the above-mentioned electron microscope observation, a growth model of the grown crystal growing from the initial crystal via the transition region is considered and the result is described.

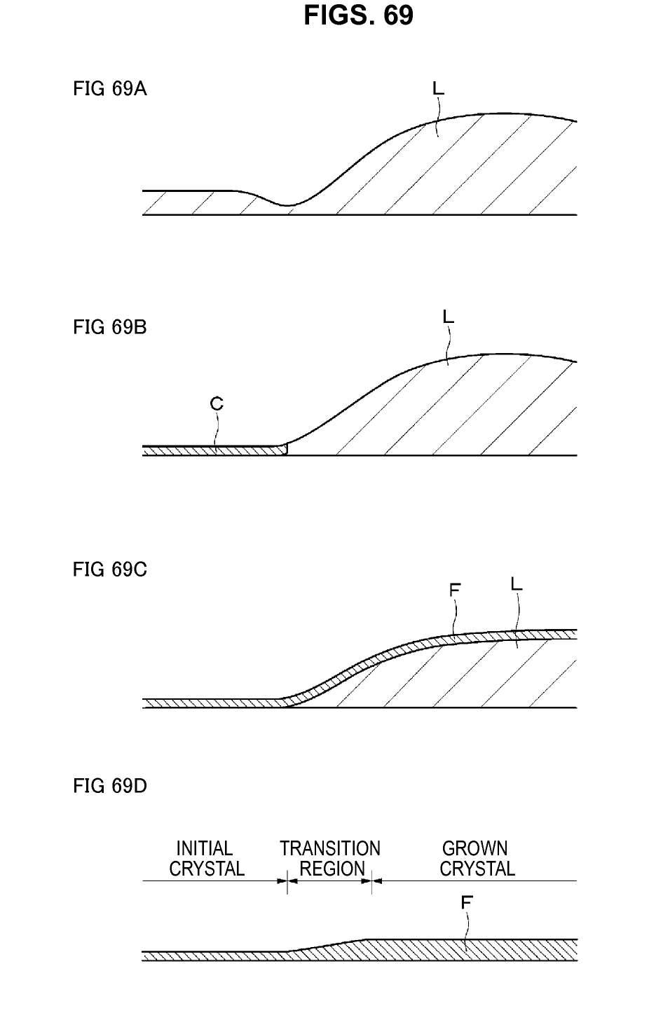

The organic solution is supplied onto the lyophilic surface S₁ of the comb-shape pattern P in FIG. 3. In this case, as illustrated in FIG. 4B, the organic solution L has a large bulge on the back part P₁ and spreads thin on the comb tooth part P₂ since the area of the comb tooth part P₂ is much smaller than the area of the back part P₁. At this stage, the organic solution L actually has a shape which is narrow in a portion on the comb tooth part P₂ side in the coupling part of the comb tooth part P₂ and the back part P₁ due to action of surface tension as illustrated in FIG. 69A. Meanwhile, as already mentioned, the evaporation of the organic solvent preferentially proceeds from the surface of the organic solution L on the comb tooth part P₂ during the growth as already mentioned and the growth of molecular layers starts from the surface of the organic solution L on the comb tooth part P₂. The evaporation of the organic solvent further proceeding, the growth of molecular layers in the thickness direction completes in the narrow portion between the comb tooth part P₂ and the back part P₁, which portion has the smallest thickness in the organic solution L. Thus, as illustrated in FIG. 69B, the crystal C has been eventually formed to contact with the comb tooth part P₂ and to close the base portion of the comb tooth part P₂ (refer to FIG. 3B). The organic solvent is hardly evaporated from the organic solution L on the back part P₁ during the growth of the crystal C, but after the growth of the crystal C, the evaporation of the organic solvent starts from the surface of the organic solution L on the back part P₁, allowing the growth of molecular layers to start from this surface of the organic solution L. As illustrated in FIG. 69C, at this stage, the molecular layers grow on the back part P₁ side, the crystal C being a seed, to form the grown crystal with the substantial same thickness as that of the crystal C, that is, to form the organic semiconductor single crystal thin film F on the surface of the organic solution L. The liquid surface of the organic solution L on the back part P₁ inclines to be an elevating slope from the comb tooth part P₂ toward the center part of the back part P₁ and the inclination gradually decreases along with the evaporation of the organic solvent proceeding. During the process, the organic solution L is gradually lacking in orientation from the comb tooth part P₂ to the center part of the back part P₁. Along with this, the molecular layers grow one by one on the lower surface of the crystal as the distance to this orientation increases. As a result, the thickness of the crystal, that is, the organic semiconductor single crystal thin film F gradually increases to this orientation. This is the reason that the number of the molecular layers in the transition region increases one molecular layer by one molecular layer from the comb tooth part P₂ to the center part of the back part P₁ as illustrated in FIG. 63B. The organic semiconductor single crystal thin film F thus having grown gradually descends along with the evaporation of the organic solvent from the organic solution L and eventually contacts with the back part P₁. As above, the organic semiconductor single crystal thin film F eventually grows as illustrated in FIG. 69D.

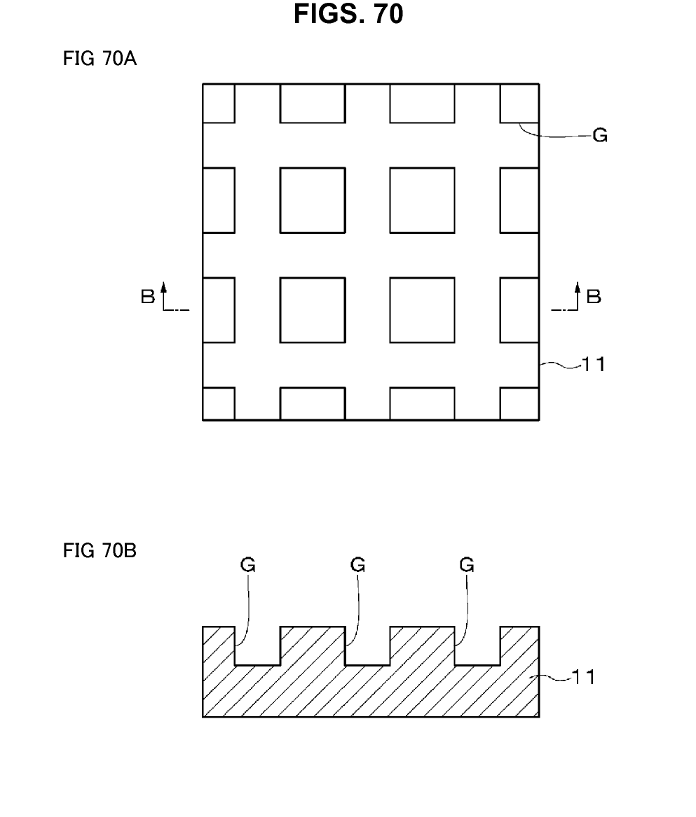

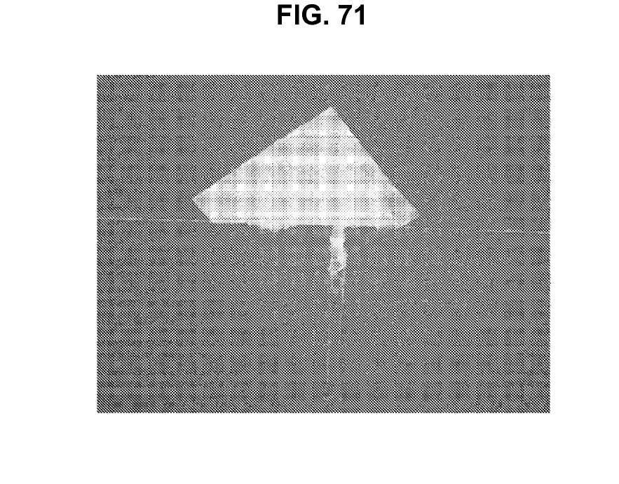

In the above process, the organic solution L remaining below the organic semiconductor single crystal thin film F may be forcibly removed, for example, since the further growth is not needed when the organic semiconductor single crystal thin film F with a desired thickness has grown on the surface of the organic solution L on the back part P₁. For this purpose, for example, providing grooves for draining below the back part P₁ on the substrate 11 is sufficient. All of the bottom surfaces and both of the lateral faces of the grooves are configured to be lyophilic surfaces. The cross-sectional shape of the grooves is not limited particularly and selected as needed, and is rectangular, semicircular, U-shaped, V-shaped or the like, for example. The planar shape of the grooves is not limited particularly and selected as needed, and is slit-shaped, grid-shaped or the like, for example. Typically, at least one end of the groove is configured to be exposed on the edge face of the substrate 11. By doing so, the organic solution L can be drained from the one exposed end of the groove to the outside of the substrate 11. FIG. 70A and FIG. 70B illustrate one example of grooves formed into a grid shape. Herein, FIG. 70A is a plan view thereof and FIG. 70B is a cross-sectional view taken along the B-B line in the FIG. 70A. As illustrated in FIG. 70A and FIG. 70B, in this example, grooves G each having a rectangular cross-sectional shape are formed on the principal plane of the substrate 11 to extend in the horizontal and vertical directions. The width of the grooves G and the width of the convex parts between the neighboring grooves G may be, for example, 50 μm or more and 100 μm or less and the depth of the grooves G may be, for example, 100 μm or more and 300 μm or less, whereas they are not limited to the above.

Next, a method for forming a layered structure composed of two organic semiconductor single crystal thin films whose crystal orientations are different each other using the organic solution obtained by dissolving the organic compound which is the raw material of the organic semiconductor single crystal thin films in the organic solvent is described.

For this purpose, the organic semiconductor single crystal thin film for the first layer is allowed to grow by the similar method to the above. Next, after the substrate 11 is allowed to incline such that the organic solution flow down again into the comb tooth part P₂ (nucleation control region), the organic semiconductor single crystal thin film for the second layer is allowed to grow by the similar method to the above again, holding the substrate 11 horizontally. Preferably, in order that the organic solution remains on the comb-shape pattern P, the widths of the back part P₁ and the comb tooth part P₂ are configured to be sufficiently large.

FIG. 71 exemplarily presents actual growth thereof. In this example, a C₂Ph-PXX thin film is allowed to grow. As illustrated in FIG. 71, it is apparent that two layers of C₂Ph-PXX thin films are allowed to grow in crystal orientations different from each other.

Next, methods for forming a hetero-structure composed of two or more layers of organic semiconductor single crystal thin films composed of semiconductors different from one another are described.

A first method includes formation of the hetero-structure as follows. First, two or more kinds of organic compounds which are raw materials of the organic semiconductor single crystal thin films and have different solubilities from one another are dissolved in the organic solvent. Next, the organic solution is supplied onto the comb-shape pattern P to evaporate the organic solvent of the organic solution, holding the growth temperature constant. This allows a crystal of the organic compound lowest in solubility to grow, succeedingly, a crystal of the organic compound second lowest in solubility to grow, and so on. The crystals are allowed to grow from the organic compound lower in solubility to the organic compound higher in solubility. The substrate 11 is allowed to incline such that the organic solution flows down again into the comb tooth part P₂ (nucleation control region) as needed as already mentioned. Thus, the hetero-structure in which the different organic semiconductor single crystal thin films from one another are allowed to make junction between them is formed.

A second method includes formation of the hetero-structure as follows. First, the organic semiconductor single crystal thin film for the first layer is allowed to grow by the above-mentioned method using a first organic solution obtained by dissolving a first organic compound which is the raw material of the organic semiconductor single crystal thin film in a first organic solvent. Next, the organic semiconductor single crystal thin film for the second layer is allowed to grow on the organic semiconductor single crystal thin film for the first layer by the above-mentioned method using a second organic solution obtained by dissolving a second organic compound different from the first organic compound in a second organic solvent. The second organic solvent employs an organic solvent in which the organic semiconductor single crystal thin film for the first layer is not dissolved or the solubility of the first organic compound is exceedingly low. The above processes are repeated required times. Thus, the hetero-structure in which the different organic semiconductor single crystal thin films from one another are allowed to make junction between them is formed.

As above, the embodiments and examples are specifically described, whereas the present disclosure is not limited to the above-mentioned embodiments and examples.

For example, the numerical values, structures, configurations, shapes, materials and the like presented in the above-mentioned embodiments and examples are simply exemplary and numerical values, structures, configurations, shapes, materials and the like different from these may be employed.

Additionally, the present technology may also be configured as below.

(1)

A manufacturing method of an organic semiconductor element, including: supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region; and allowing an organic semiconductor single crystal thin film composed of the organic compound to grow by evaporating the solvent of the organic solution.

(2)

The manufacturing method of an organic semiconductor element according to (1),

wherein a state of the organic solution is configured as a metastable region between a solubility curve and a supersolubility curve in a solubility-supersolubility diagram of the organic solution in the growth control region and the state of the organic solution is configured as an unstable region on a lower side of the supersolubility curve in the solubility-supersolubility diagram in the nucleation control region by evaporating the solvent of the organic solution.

(3)

The manufacturing method of an organic semiconductor element according to (1) or (2),

wherein only one crystal obtained by growth of a crystal nucleus formed due to nucleation from the organic solution in the nucleation control region closes the nucleation control region, and

wherein the crystal is allowed to grow on the growth control region.

(4)

The manufacturing method of an organic semiconductor element according to any one of (1) to (3),

wherein the organic solution is held at a constant temperature.

(5)

The manufacturing method of an organic semiconductor element according to any one of (1) to (4),

wherein the growth control region and the nucleation control region have lyophilic surfaces.

(6)

The manufacturing method of an organic semiconductor element according to any one of (1) to (5),

wherein the nucleation control region has a first part in a straight line shape which is coupled with the growth control region and inclines by 90°±10° relative to the one side of the growth control region.

(7)

The manufacturing method of an organic semiconductor element according to any one of (1) to (6),

wherein a width of the first part is not less than 0.1 μm and not more than 50 μm.

(8)

The manufacturing method of an organic semiconductor element according to any one of (1) to (7),

wherein the growth control region is a rectangle, and

wherein the first part of the nucleation control region is a rectangle which is provided on one long side of the growth control region to be perpendicular to the long side and is smaller than the growth control region.

(9)

The manufacturing method of an organic semiconductor element according to any one of (1) to (8),

wherein the nucleation control region has a second part in a straight line shape which is coupled with the first part and inclines relative to the one side.

(10)

The manufacturing method of an organic semiconductor element according to any one of (1) to (8),

wherein the nucleation control region has a third part in a triangular shape which is coupled with the growth control region and has a first side on the one side, and a fourth part in a straight line shape which is coupled with the third part and inclines relative to the one side.

(11)

The manufacturing method of an organic semiconductor element according to any one of (1) to (10),

wherein the organic semiconductor single crystal thin film has a π-electron stacking structure in a direction substantially parallel to the one principal plane of the base body.

(12)

The manufacturing method of an organic semiconductor element according to any one of (1) to (11),

wherein the organic semiconductor single crystal thin film has a triclinic, monoclinic, orthorhombic or tetragonal crystal structure and has the π-electron stacking structure in an a-axis direction or a b-axis direction.

(13)

The manufacturing method of an organic semiconductor element according to any one of (1) to (12),

wherein the organic semiconductor single crystal thin film on the growth control region has a tetragonal or pentagonal shape having a first vertex with a vertical angle of 82° and a second vertex with a vertical angle of 98°.

(14)

The manufacturing method of an organic semiconductor element according to any one of (1) to (13),

wherein a plurality of the growth control regions are provided on the one principal plane of the base body separately from one another, wherein at least two growth control regions of the growth control regions are provided to oppose each other, and

wherein a plurality of the nucleation control regions are provided on each of sides of the two growth control regions, the sides opposing each other, such that the nucleation control regions do not overlap with one another.

### REFERENCE SIGNS LIST

11 Substrate
30 Organic solution
31 Substrate
32 Growth control region
33 Nucleation control region
33a First part
33b Second part
33c Third part
33d Fourth part
36 Organic solution
39 Organic semiconductor single crystal thin film
40 Si wafer
P Comb-shape pattern
P₁ Back part
P₂ Comb tooth part
S₁ Lyophilic surface
S₂ Lyophobic surface
F Organic semiconductor single crystal thin film

1. A manufacturing method of an organic semiconductor element, comprising:
supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region; and
allowing an organic semiconductor single crystal thin film composed of the organic compound to grow by evaporating the solvent of the organic solution.

2. The manufacturing method of an organic semiconductor element according to claim 1,
wherein a state of the organic solution is configured as a metastable region between a solubility curve and a supersolubility curve in a solubility-supersolubility diagram of the organic solution in the growth control region and the state of the organic solution is configured as an unstable region on a lower side of the supersolubility curve in the solubility-supersolubility diagram in the nucleation control region by evaporating the solvent of the organic solution.

3. The manufacturing method of an organic semiconductor element according to claim 2,
wherein only one crystal obtained by growth of a crystal nucleus formed due to nucleation from the organic solution in the nucleation control region closes the nucleation control region, and
wherein the crystal is allowed to grow on the growth control region.

4. The manufacturing method of an organic semiconductor element according to claim 3,
wherein the organic solution is held at a constant temperature.

5. The manufacturing method of an organic semiconductor element according to claim 4,
wherein the growth control region and the nucleation control region have lyophilic surfaces.

6. The manufacturing method of an organic semiconductor element according to claim 5,
wherein the nucleation control region has a first part in a straight line shape which is coupled with the growth control region and inclines by 90°±10° relative to the one side of the growth control region.

7. The manufacturing method of an organic semiconductor element according to claim 6,
wherein a width of the first part is not less than 0.1 μm and not more than 50 μm.

8. The manufacturing method of an organic semiconductor element according to claim 7,
wherein the growth control region is a rectangle, and
wherein the first part of the nucleation control region is a rectangle which is provided on one long side of the growth control region to be perpendicular to the long side and is smaller than the growth control region.

9. The manufacturing method of an organic semiconductor element according to claim 6,
wherein the nucleation control region has a second part in a straight line shape which is coupled with the first part and inclines relative to the one side.

10. The manufacturing method of an organic semiconductor element according to claim 5,
wherein the nucleation control region has a third part in a triangular shape which is coupled with the growth control region and has a first side on the one side, and a fourth part in a straight line shape which is coupled with the third part and inclines relative to the one side.

11. The manufacturing method of an organic semiconductor element according to claim 1,
wherein the organic semiconductor single crystal thin film has a π-electron stacking structure in a direction substantially parallel to the one principal plane of the base body.

12. The manufacturing method of an organic semiconductor element according to claim 11,
wherein the organic semiconductor single crystal thin film has a triclinic, monoclinic, orthorhombic or tetragonal crystal structure and has the π-electron stacking structure in an a-axis direction or a b-axis direction.

13. The manufacturing method of an organic semiconductor element according to claim 12,
wherein the organic semiconductor single crystal thin film on the growth control region has a tetragonal or pentagonal shape having a first vertex with a vertical angle of 82° and a second vertex with a vertical angle of 98°.

14. The manufacturing method of an organic semiconductor element according to claim 1,
wherein a plurality of the growth control regions are provided on the one principal plane of the base body separately from one another,
wherein at least two growth control regions of the growth control regions are provided to oppose each other, and
wherein a plurality of the nucleation control regions are provided on each of sides of the two growth control regions, the sides opposing each other, such that the nucleation control regions do not overlap with one another.

15. An organic semiconductor element manufactured by:
supplying an unsaturated organic solution obtained by dissolving an organic semiconductor in a solvent to a growth control region and at least one nucleation control region of a base body having, on one principal plane, the growth control region and the nucleation control region which is provided on one side of the growth control region to be coupled with the growth control region; and
allowing an organic semiconductor single crystal thin film composed of the organic semiconductor to grow by evaporating the solvent of the organic solution.

16. An electronic device having an organic semiconductor element manufactured by:
supplying an unsaturated organic solution obtained by dissolving an organic semiconductor in a solvent to a growth control region and at least one nucleation control region of a base body having, on one principal plane, the growth control region and the nucleation control region which is provided on one side of the growth control region to be coupled with the growth control region; and
allowing an organic semiconductor single crystal thin film composed of the organic semiconductor to grow by evaporating the solvent of the organic solution.

17. A growth method of an organic single crystal thin film comprising:
supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region; and
allowing an organic single crystal thin film composed of the organic compound to grow by evaporating the solvent of the organic solution.

18. An organic single crystal thin film allowed to grow by:
supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region; and
allowing the organic single crystal thin film composed of the organic compound to grow by evaporating the solvent of the organic solution.

19. A growth method of an organic single crystal thin film comprising:
supplying an unsaturated organic solution obtained by dissolving an organic compound in a solvent to a growth control region and at least one nucleation control region of a base body having, on one principal plane, the growth control region and the nucleation control region which is provided on one side of the growth control region to be coupled with the growth control region; and
closing the nucleation control region with only one crystal obtained by growth of a crystal nucleus formed due to nucleation from the organic solution in the nucleation control region by evaporating the solvent of the organic solution to allow the crystal to grow on the growth control region, and thereby, allowing an organic single crystal thin film composed of the organic compound to grow.

20. An organic single crystal thin film group comprising
a plurality of organic single crystal thin films which are allowed to grow on one principal plane of a base body and composed of an organic compound,
wherein organic single crystal thin films not less than 17% and not more than 47% in terms of number among the organic single crystal thin film group have pentagonal shapes each having a first vertex with a vertical angle of 82° and a second vertex with a vertical angle of 98°, and
wherein organic single crystal thin films not less than 16% and not more than 41% in terms of number among the organic single crystal thin film group have tetragonal shapes each having the first vertex with the vertical angle of 82° and the second vertex with the vertical angle of 98°.
